(19) United States
(12) Patent Application Publication
(10) Pub. No.: US 2025/0107062 A1
(43) Pub. Date: Mar. 27, 2025

(54) STORAGE DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tatsuya ONUKI, Atsugi (JP); Kiyoshi KATO, Atsugi (JP); Hitoshi KUNITAKE, Machida (JP); Ryota HODO, Atsugi (JP)

(21) Appl. No.: 18/832,672

(22) PCT Filed: Jan. 23, 2023
(86) PCT No.: PCT/IB2023/050529

§ 371 Date: Jul. 24, 2024

(30) Foreign Application Priority Data
Feb. 4, 2022 (JP) 2022-016404
Feb. 4, 2022 (JP) 2022-016431

(51) Int. Cl. H10B 12/00; G11C 11/405; G11C 11/408

(52) U.S. Cl. CPC H10B 12/00; G11C 11/405; G11C 11/4085

(57) ABSTRACT

A semiconductor device that can be miniaturized or highly integrated is provided. The semiconductor device includes a first insulator, a second insulator over the first insulator, and a memory cell including a transistor and a capacitor. The transistor includes an oxide over the first insulator, a first conductor and a second conductor over the oxide, a third insulator over the oxide, and a third conductor over the third insulator. The third insulator and the third conductor are located in a first opening of the second insulator. The capacitor includes a fourth conductor in contact with a top surface of the second conductor, a fourth insulator over the fourth conductor, and a fifth conductor over the fourth insulator. The fourth conductor, the fourth insulator, and the fifth conductor are located in a second opening of the second insulator. A third opening is formed in the first insulator, the second insulator, and the first conductor. A sixth conductor is located in the third opening. The sixth conductor includes a region in contact with part of a top surface of the first conductor and part of a side surface of the first conductor in each of a plurality of layers.

### TECHNICAL FIELD

One embodiment of the present invention relates to a transistor, a semiconductor device, a storage device, and an electronic appliance. Another embodiment of the present invention relates to a method for manufacturing a semiconductor device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, the development of semiconductor devices has progressed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a characteristically low leakage current of the transistor using an oxide semiconductor. Furthermore, for example, Patent Document 2 discloses a storage device that can retain stored contents for a long time by utilizing a characteristically low leakage current of the transistor using an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated. Another object is to provide a semiconductor device with high operation speed. Another object is to provide a semiconductor device having favorable electrical characteristics. Another object is to provide a semiconductor device with a small variation in electrical characteristics of transistors. Another object is to provide a semiconductor device having favorable reliability. Another object is to provide a semiconductor device with a high on-state current. Another object is to provide a semiconductor device with low power consumption. Another object is to provide a novel semiconductor device. Another object is to provide a method for manufacturing a semiconductor device with a reduced number of steps. Another object is to provide a storage device including a novel semiconductor device.

Note that the description of these objects does not preclude the existence of other objects. Note that one embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a storage device that includes a first insulator, a second insulator over the first insulator, and a memory cell including a first transistor and a first capacitor. The first transistor includes an oxide over the first insulator, a first conductor and a second conductor over the oxide, a third insulator over the oxide, and a third conductor over the third insulator. The second insulator is located over the first conductor and the second conductor. The second insulator includes a first opening including a region overlapping with the oxide and a second opening including a region overlapping with the second conductor. The third insulator and the third conductor are located in the first opening. The first capacitor includes a fourth conductor in contact with a top surface of the second conductor, a fourth insulator over the fourth conductor, and a fifth conductor over the fourth insulator. The fourth conductor, the fourth insulator, and the fifth conductor are located in the second opening. A third opening is formed in the first insulator, the second insulator, and the first conductor. A sixth conductor is located in the third opening. The sixth conductor includes a region in contact with part of a top surface of the first conductor and part of a side surface of the first conductor.

Another embodiment of the present invention is a storage device that includes a plurality of layers each including a first insulator, a second insulator over the first insulator, and a memory cell including a first transistor and a first capacitor. The plurality of layers are stacked. The first transistor includes an oxide over the first insulator, a first conductor and a second conductor over the oxide, a third insulator over the oxide, and a third conductor over the third insulator. The second insulator is located over the first conductor and the second conductor. The second insulator includes a first opening including a region overlapping with the oxide and a second opening including a region overlapping with the second conductor. The third insulator and the third conductor are located in the first opening. The first capacitor includes a fourth conductor in contact with a top surface of the second conductor, a fourth insulator over the fourth conductor, and a fifth conductor over the fourth insulator. The fourth conductor, the fourth insulator, and the fifth conductor are located in the second opening. Third openings of the plurality of layers include a region in which the third openings overlap with each other. A sixth conductor is located in the third openings. The sixth conductor includes a region in contact with part of a top surface of the first conductor and part of a side surface of the first conductor in each of the plurality of layers.

In the above storage device, it is preferable that each of the plurality of layers further include a second transistor and a second capacitor, the second transistor have a structure similar to a structure of the first transistor, the first transistor and the second transistor be positioned line-symmetrically with respect to the sixth conductor as a symmetric axis, the second capacitor have a structure similar to a structure of the first capacitor, and the first capacitor and the second capacitor be positioned line-symmetrically with respect to the sixth conductor as a symmetric axis.

It is preferable that the above storage device include a driver circuit and the plurality of layers be provided over the driver circuit to overlap therewith. It is preferable that the above storage device include a wiring and a functional layer including a functional circuit, the functional layer be provided between a substrate provided with the driver circuit and the layer including the memory cell, the wiring have a function of electrically connecting the driver circuit to the functional circuit, and the functional circuit include a third transistor a gate of which is electrically connected to the sixth conductor electrically connected to the memory cell and have a function of transmitting, to the wiring, a signal corresponding to a potential of the sixth conductor.

In the above storage device, it is preferable that the third insulator include a region in contact with a top surface and a side surface of the oxide and a region in contact with a sidewall of the first opening of the second insulator.

In the above storage device, it is preferable that the first conductor and the second conductor be each in contact with a top surface and a side surface of the oxide.

In the above storage device, it is preferable that part of the fourth conductor, part of the fourth insulator, and part of the fifth conductor be located above a top surface of the third conductor.

In the above storage device, it is preferable that the fourth conductor include a region in contact with a sidewall of the second opening of the second insulator.

In the above storage device, it is preferable that the third opening be formed in the first insulator, the second insulator, and the first conductor, and in the third opening, the side surface of the first conductor protrude from a side surface of the first insulator and a side surface of the second insulator.

It is preferable that the above storage device include a seventh conductor between the sixth conductor and the third opening, the sixth conductor include tungsten, and the seventh conductor include titanium and nitrogen.

It is preferable that the above storage device include a fifth insulator in contact with a top surface of the second insulator and the top surface of the third conductor, the second opening be formed in the fifth insulator, and part of the fourth conductor and part of the fourth insulator be in contact with a top surface of the fifth insulator.

### Effect of the Invention

According to one embodiment of the present invention, a semiconductor device that can be miniaturized or highly integrated can be provided. Alternatively, a semiconductor device with high operation speed can be provided. Alternatively, a semiconductor device having favorable reliability can be provided. Alternatively, a semiconductor device with a small variation in electrical characteristics of transistors can be provided. Alternatively, a semiconductor device having favorable electrical characteristics can be provided. Alternatively, a semiconductor device with a high on-state current can be provided. Alternatively, a semiconductor device with low power consumption can be provided. Alternatively, a novel semiconductor device can be provided. Alternatively, a method for manufacturing a semiconductor device with a reduced number of steps can be provided. Alternatively, a storage device including a novel semiconductor device can be provided.

Note that the description of these effects does not preclude the existence of other effects. Note that one embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a top view of a semiconductor device of one embodiment of the present invention.

FIG. 1B to FIG. 1D are cross-sectional views of the semiconductor device of one embodiment of the present invention.

FIG. 2 is a circuit diagram illustrating a structure of a storage device of one embodiment of the present invention.

FIG. 3A to FIG. 3C are cross-sectional views of a semiconductor device of one embodiment of the present invention.

FIG. 4A and FIG. 4B are cross-sectional views of a semiconductor device of one embodiment of the present invention.

FIG. 5A and FIG. 5B are cross-sectional views of a semiconductor device of one embodiment of the present invention.

FIG. 6A to FIG. 6C are cross-sectional views of a semiconductor device of one embodiment of the present invention.

FIG. 7 is a cross-sectional view of a semiconductor device of one embodiment of the present invention.

FIG. 8A is a top view illustrating a method for manufacturing a semiconductor device of one embodiment of the present invention. FIG. 8B to FIG. 8D are cross-sectional views illustrating the method for manufacturing a semiconductor device of one embodiment of the present invention.

FIG. 9A is a top view illustrating a method for manufacturing a semiconductor device of one embodiment of the present invention. FIG. 9B to FIG. 9D are cross-sectional views illustrating the method for manufacturing a semiconductor device of one embodiment of the present invention.

FIG. 10A is a top view illustrating a method for manufacturing a semiconductor device of one embodiment of the present invention. FIG. 10B to FIG. 10D are cross-sectional views illustrating the method for manufacturing a semiconductor device of one embodiment of the present invention.

FIG. 11A is a top view illustrating a method for manufacturing a semiconductor device of one embodiment of the present invention. FIG. 11B to FIG. 11D are cross-sectional views illustrating the method for manufacturing a semiconductor device of one embodiment of the present invention.

FIG. 12A is a top view illustrating a method for manufacturing a semiconductor device of one embodiment of the present invention. FIG. 12B to FIG. 12D are cross-sectional views illustrating the method for manufacturing a semiconductor device of one embodiment of the present invention.

FIG. 13A is a top view illustrating a method for manufacturing a semiconductor device of one embodiment of the present invention. FIG. 13B to FIG. 13D are cross-sectional views illustrating the method for manufacturing a semiconductor device of one embodiment of the present invention.

FIG. 14A is a top view illustrating a method for manufacturing a semiconductor device of one embodiment of the present invention. FIG. 14B to FIG. 14D are cross-sectional views illustrating the method for manufacturing a semiconductor device of one embodiment of the present invention.

FIG. 15A is a top view illustrating a method for manufacturing a semiconductor device of one embodiment of the present invention. FIG. 15B to FIG. 15D are cross-sectional views illustrating the method for manufacturing a semiconductor device of one embodiment of the present invention.

FIG. 16A is a top view illustrating a method for manufacturing a semiconductor device of one embodiment of the present invention. FIG. 16B to FIG. 16D are cross-sectional views illustrating the method for manufacturing a semiconductor device of one embodiment of the present invention.

FIG. 17A is a top view illustrating a method for manufacturing a semiconductor device of one embodiment of the present invention. FIG. 17B to FIG. 17D are cross-sectional views illustrating the method for manufacturing a semiconductor device of one embodiment of the present invention.

FIG. 18A is a top view illustrating a method for manufacturing a semiconductor device of one embodiment of the present invention. FIG. 18B to FIG. 18D are cross-sectional views illustrating the method for manufacturing a semiconductor device of one embodiment of the present invention.

FIG. 19A is a top view illustrating a method for manufacturing a semiconductor device of one embodiment of the present invention. FIG. 19B to FIG. 19D are cross-sectional views illustrating the method for manufacturing a semiconductor device of one embodiment of the present invention.

FIG. 20A is a top view illustrating a method for manufacturing a semiconductor device of one embodiment of the present invention. FIG. 20B to FIG. 20D are cross-sectional views illustrating the method for manufacturing a semiconductor device of one embodiment of the present invention.

FIG. 21A is a top view illustrating a method for manufacturing a semiconductor device of one embodiment of the present invention. FIG. 21B to FIG. 21D are cross-sectional views illustrating the method for manufacturing a semiconductor device of one embodiment of the present invention.

FIG. 22A is a top view illustrating a method for manufacturing a semiconductor device of one embodiment of the present invention. FIG. 22B to FIG. 22D are cross-sectional views illustrating the method for manufacturing a semiconductor device of one embodiment of the present invention.

FIG. 23A is a top view illustrating a method for manufacturing a semiconductor device of one embodiment of the present invention. FIG. 23B to FIG. 23D are cross-sectional views illustrating the method for manufacturing a semiconductor device of one embodiment of the present invention.

FIG. 24A is a top view illustrating a method for manufacturing a semiconductor device of one embodiment of the present invention. FIG. 24B to FIG. 24D are cross-sectional views illustrating the method for manufacturing a semiconductor device of one embodiment of the present invention.

FIG. 25A is a top view illustrating a method for manufacturing a semiconductor device of one embodiment of the present invention. FIG. 25B to FIG. 25D are cross-sectional views illustrating the method for manufacturing a semiconductor device of one embodiment of the present invention.

FIG. 26 is a top view illustrating a microwave treatment apparatus of one embodiment of the present invention.

FIG. 27 is a cross-sectional view illustrating a microwave treatment apparatus of one embodiment of the present invention.

FIG. 28 is a cross-sectional view illustrating a microwave treatment apparatus of one embodiment of the present invention.

FIG. 29 is a cross-sectional view illustrating a microwave treatment apparatus of one embodiment of the present invention.

FIG. 30A is a top view of a semiconductor device of one embodiment of the present invention.

FIG. 30B to FIG. 30D are cross-sectional views of the semiconductor device of one embodiment of the present invention.

FIG. 31A and FIG. 31B are cross-sectional views of semiconductor devices of embodiments of the present invention.

FIG. 32 is a cross-sectional view of a semiconductor device of one embodiment of the present invention.

FIG. 33 is a block diagram illustrating a structure example of a storage device.

FIG. 34A and FIG. 34B are schematic views and a circuit diagram illustrating a structure example of a storage device.

FIG. 35A and FIG. 35B are schematic views each illustrating a structure example of a storage device.

FIG. 36 is a circuit diagram illustrating a structure example of a storage device.

FIG. 37 is a timing chart illustrating a structure example of a storage device.

FIG. 38A and FIG. 38B are circuit diagrams each illustrating a structure example of a storage device.

FIG. 39A and FIG. 39B are circuit diagrams each illustrating a structure example of a storage device.

FIG. 40A and FIG. 40B are layout diagrams each illustrating a structure of a storage device of one embodiment of the present invention.

FIG. 41 is a cross-sectional view illustrating a structure of a storage device of one embodiment of the present invention.

FIG. 42 is a cross-sectional view illustrating a structure of a storage device of one embodiment of the present invention.

FIG. 43 is a layout diagram illustrating a structure of a storage device of one embodiment of the present invention.

FIG. 44A and FIG. 44B are schematic views of a semiconductor device of one embodiment of the present invention.

FIG. 45A and FIG. 45B are diagrams illustrating examples of electronic components.

FIG. 46A to FIG. 46E are schematic views of storage devices of embodiments of the present invention.

FIG. 47A to FIG. 47H are diagrams illustrating electronic appliances of embodiments of the present invention.

FIG. 48 is a diagram illustrating an example of a device for space.

### MODE FOR CARRYING OUT THE INVENTION

Embodiments are described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is applied to portions having similar functions, and the portions are not especially denoted by reference numerals in some cases.

Furthermore, especially in a top view (also referred to as a “plan view”), a perspective view, or the like, the description of some components might be omitted for easy understanding of the invention. The description of some hidden lines and the like might also be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in this specification, the description can be changed appropriately depending on the situation.

In this specification and the like, for example, the expression “X and Y are connected” means the case where X and Y are electrically connected. Here, the expression “X and Y are electrically connected” means connection that enables electrical signal transmission between X and Y in the case where an object (that refers to an element such as a switch, a transistor element, or a diode, a circuit including the element and a wiring, or the like) is present between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of a current is changed in a circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where a current flows in a semiconductor when a transistor is in an on state) and a gate electrode overlap with each other or in a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where a current flows in a semiconductor when a transistor is in an on state) and a gate electrode overlap with each other or in a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an “effective channel width”) is different from a channel width shown in a top view of a transistor (hereinafter also referred to as an “apparent channel width”) in some cases. For example, when a gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is high in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that the value of a channel length, a channel width, an effective channel width, an apparent channel width, or the like can be determined, for example, by analyzing a cross-sectional TEM image.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as V_{O}) are formed in an oxide semiconductor in some cases by entry of impurities, for example.

Note that in this specification and the like, silicon oxynitride has a composition in which the oxygen content is higher than the nitrogen content. Silicon nitride oxide has a composition in which the nitrogen content is higher than the oxygen content. Aluminum oxynitride has a composition in which the oxygen content is higher than the nitrogen content. Aluminum nitride oxide has a composition in which the nitrogen content is higher than the oxygen content. Hafnium oxynitride has a composition in which the oxygen content is higher than the nitrogen content. Hafnium nitride oxide has a composition in which the nitrogen content is higher than the oxygen content.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “normally off” means that a drain current per micrometer of channel width flowing through a transistor when no potential is applied to a gate or the gate is supplied with a ground potential is lower than or equal to 1×10⁻²⁰ A at room temperature, lower than or equal to 1×10⁻¹⁸ A at 85° C., or lower than or equal to 1×10⁻¹⁶ A at 125° C.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change in the reference potential.

In this specification and the like, when a plurality of components are denoted with the same reference numeral, and in particular need to be distinguished from each other, an identification sign such as “_1”, “[n]”, or “[m,n]” is sometimes added to the reference numeral.

Note that in this specification and the like, the expression “level or substantially level” is used to describe a structure in which levels from a reference surface (e.g., a flat surface such as a substrate surface) are the same in a cross-sectional view. For example, in a manufacturing process of a semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that the plurality of layers are at different levels in some cases, depending on a treatment apparatus, a treatment method, or a material of the treated surfaces at the time when the CMP treatment is performed. This case is also described with the expression “level or substantially level” in this specification and the like. For example, the expression “level or substantially level” is also used to describe the case where layers having two levels with respect to the reference surface (here, given as a first layer and a second layer) are provided to have a difference less than or equal to 20 nm between the top-surface level of the first layer and the top-surface level of the second layer.

Note that in this specification and the like, the expression “end portions are aligned or substantially aligned” means that outlines of stacked layers at least partly overlap with each other in a top view. For example, the case of processing an upper layer and a lower layer with the use of the same mask pattern or mask patterns that are partly the same is included. Note that in some cases, the outlines do not exactly overlap with each other and the outline of the upper layer is located inward from the outline of the lower layer or the outline of the upper layer is located outward from the outline of the lower layer; such a case is also represented by the expression “end portions are aligned or substantially aligned”.

### Embodiment 1

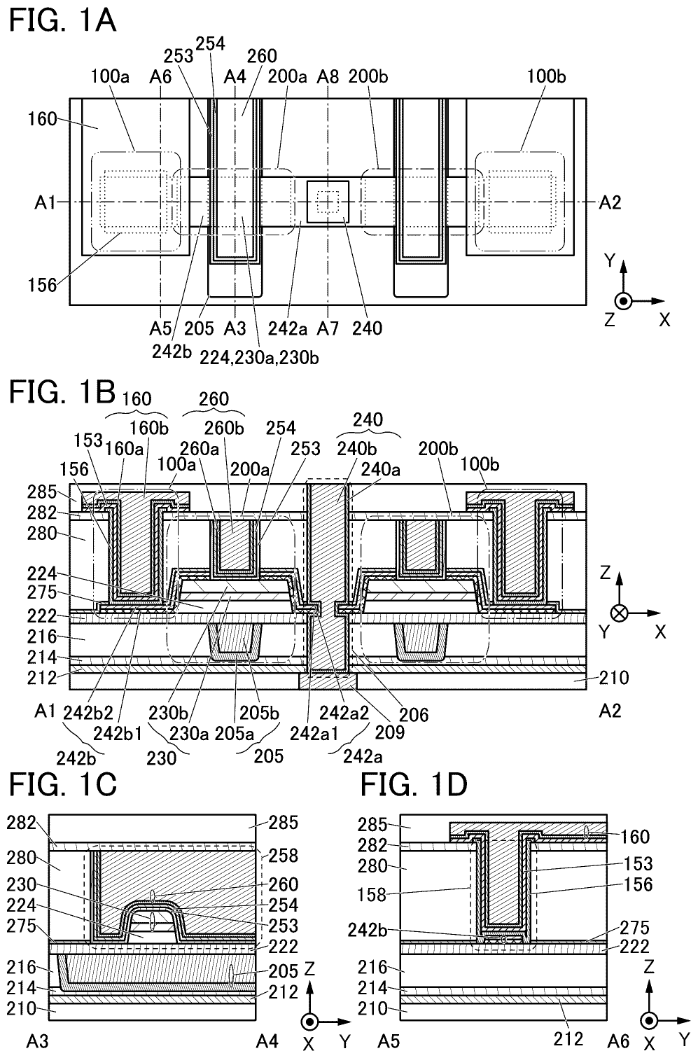

In this embodiment, an example of a semiconductor device of one embodiment of the present invention and a manufacturing method thereof are described with reference to FIG. 1A to FIG. 32. The semiconductor device of one embodiment of the present invention includes a transistor and a capacitor.

### <Structure Example of Semiconductor Device>

A structure of a semiconductor device including a transistor and a capacitor is described with reference to FIG. 1. FIG. 1A to FIG. 1D are a top view and cross-sectional views of a semiconductor device including a transistor 200a, a transistor 200b, a capacitor 100a, and a capacitor 100b. FIG. 1A is the top view of the semiconductor device. FIG. 1B to FIG. 1D are the cross-sectional views of the semiconductor device. Here, FIG. 1B is a cross-sectional view of a portion indicated by the dashed-dotted line A1-A2 in FIG. 1A and also is a cross-sectional view of the transistor 200a, the transistor 200b, the capacitor 100a, and the capacitor 100b in the channel length direction. FIG. 1C is a cross-sectional view of a portion indicated by the dashed-dotted line A3-A4 in FIG. 1A, and is a cross-sectional view of the transistor 200a in the channel width direction. FIG. 1D is a cross-sectional view of a portion indicated by the dashed-dotted line A5-A6 in FIG. 1A. Note that for clarity of the drawing, some components are omitted in the top view of FIG. 1A.

The X direction shown in FIG. 1A is parallel to the channel length direction of the transistor 200a and the channel length direction of the transistor 200b, the Y direction is perpendicular to the X direction, and the Z direction is perpendicular to the X direction and the Y direction. Note that the X direction, the Y direction, and the Z direction shown in FIG. 1A are also shown in FIG. 1B to FIG. 1D.

The semiconductor device of one embodiment of the present invention includes an insulator 214 over a substrate (not illustrated); the transistor 200a, the transistor 200b, the capacitor 100a, and the capacitor 100b over the insulator 214; an insulator 280 over an insulator 275 provided in the transistor 200a and the transistor 200b; an insulator 282 over the insulator 280; an insulator 285 over the capacitor 100a, the capacitor 100b, and the insulator 282; and a conductor 240 (a conductor 240a and a conductor 240b). The insulator 214, the insulator 280, the insulator 282, and the insulator 285 each function as an interlayer film. As illustrated in FIG. 1B, the transistor 200a, the transistor 200b, the capacitor 100a, and the capacitor 100b are provided to be at least partly embedded in the insulator 280.

Here, the transistor 200a and the transistor 200b each include an oxide 230 functioning as a semiconductor layer, a conductor 260 functioning as a first gate (also referred to as top gate) electrode, a conductor 205 functioning as a second gate (also referred to as back gate) electrode, a conductor 242a functioning as one of a source electrode and a drain electrode, and a conductor 242b functioning as the other of the source electrode and the drain electrode. An insulator 253 and an insulator 254 functioning as a first gate insulator are also included. An insulator 222 and an insulator 224 functioning as a second gate insulator are also included. Note that a gate insulator is also referred to as a gate insulating layer or a gate insulating film in some cases.

The transistor 200a and the transistor 200b have the same structure; thus, in the following description common to the transistor 200a and the transistor 200b, the alphabets are omitted from the reference numerals and the term “transistor 200” is used in some cases.

The first gate electrode and the first gate insulating film are located in an opening 258 formed in the insulator 280 and the insulator 275. That is, the conductor 260, the insulator 254, and the insulator 253 are located in the opening 258.

The capacitor 100a and the capacitor 100b each include a conductor 156 functioning as a lower electrode, an insulator 153 functioning as a dielectric, and a conductor 160 functioning as an upper electrode. In other words, the capacitor 100a and the capacitor 100b each form a MIM (Metal-Insulator-Metal) capacitor.

The capacitor 100a and the capacitor 100b have the same structure; thus, in the following description common to the capacitor 100a and the capacitor 100b, the alphabets are omitted from the reference numerals and the term “capacitor 100” is used in some cases.

The upper electrode, the dielectric, and part of the lower electrode of the capacitor 100 are located in an opening 158 formed in the insulator 282, the insulator 280, and the insulator 275. That is, the conductor 160, the insulator 153, and the conductor 156 are located in the opening 158.

The semiconductor device of one embodiment of the present invention also includes the conductor 240 (the conductor 240a and the conductor 240b) electrically connected to the transistor 200 and functioning as a plug (which can also be referred to as a connection electrode). The conductor 240 is located in an opening 206 formed in the insulator 280 and the like. The conductor 240 includes a region that is in contact with part of the top surface of the conductor 242a and part of a side surface of the conductor 242a.

The semiconductor device of one embodiment of the present invention includes an insulator 210 and a conductor 209 between the substrate (not illustrated) and the insulator 214. The conductor 209 is located to be embedded in the insulator 210. The conductor 209 includes a region that is in contact with the conductor 240.

The semiconductor device of one embodiment of the present invention may include an insulator 212 between the insulator 214 and each of the insulator 210 and the conductor 209.

The semiconductor device including the transistor 200 and the capacitor 100 and described in this embodiment can be used as a memory cell of a storage device. In that case, the conductor 240 is electrically connected to a sense amplifier in some cases and functions as a bit line. Here, as illustrated in FIG. 1A, at least part of the capacitor 100 is provided to overlap with the conductor 242b of the transistor 200. Thus, the capacitor 100 can be provided without a significant increase in footprint in a plan view, enabling miniaturization or high integration of the semiconductor device of this embodiment.

The semiconductor device described in this embodiment has a line-symmetric structure with respect to the dashed-dotted line A7-A8 in FIG. 1A. That is, it can be said that the transistor 200a and the transistor 200b are positioned line-symmetrically with respect to the conductor 240 as the symmetric axis. It can be said that the capacitor 100a and the capacitor 100b are positioned line-symmetrically with respect to the conductor 240 as the symmetric axis. Here, the conductor 242a serves as the one of the source electrode and the drain electrode of the transistor 200a and the one of the source electrode and the drain electrode of the transistor 200b. In each of the transistor 200a and the transistor 200b, the conductor 240 functions as the plug. With the above connection structure between the two transistors, the two capacitors, and the plug, a semiconductor device that can be miniaturized or highly integrated can be provided.

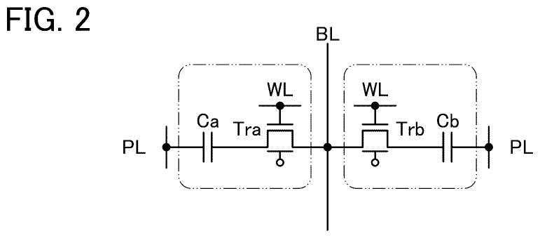

FIG. 2 is a circuit diagram illustrating the case where the semiconductor device described in this embodiment is used in a storage device. The semiconductor device including the transistor 200a and the capacitor 100a can be used as a memory cell of the storage device. The semiconductor device including the transistor 200b and the capacitor 100b can be used as a memory cell of the storage device.

The semiconductor device illustrated in FIG. 1A to FIG. 1D can also be referred to as a storage device composed of two memory cells as illustrated in FIG. 2. One memory cell includes a transistor Tra and a capacitor Ca. The other memory cell includes a transistor Trb and a capacitor Cb.

Here, the transistor Tra, the transistor Trb, the capacitor Ca, and the capacitor Cb correspond to the transistor 200a, the transistor 200b, the capacitor 100a, and the capacitor 100b, respectively.

In the one memory cell, one of a source and a drain of the transistor Tra is connected to a wiring BL. The other of the source and the drain of the transistor Tra is connected to one electrode of the capacitor Ca. A gate of the transistor Tra is connected to a wiring WL. The other electrode of the capacitor Ca is connected to a wiring PL.

In the other memory cell, one of a source and a drain of the transistor Trb is connected to the wiring BL. The other of the source and the drain of the transistor Trb is connected to one electrode of the capacitor Cb. A gate of the transistor Trb is connected to the wiring WL. The other electrode of the capacitor Cb is connected to the wiring PL.

Note that the memory cells will be described in detail in a later embodiment.

### [Transistor 200]

As illustrated in FIG. 1A to FIG. 1D, the transistor 200 includes an insulator 216 over the insulator 214; the conductor 205 (a conductor 205a and a conductor 205b) located to be embedded in the insulator 216; the insulator 222 over the insulator 216 and the conductor 205; the insulator 224 over the insulator 222; an oxide 230a over the insulator 224; an oxide 230b over the oxide 230a; the conductor 242a (a conductor 242al and a conductor 242a2) and the conductor 242b (a conductor 242b1 and a conductor 242b2) over the oxide 230b; the insulator 253 over the oxide 230b; the insulator 254 over the insulator 253; the conductor 260 (a conductor 260a and a conductor 260b) located over the insulator 254 and overlapping with part of the oxide 230b; and the insulator 275 located over the insulator 222, the insulator 224, the oxide 230a, the oxide 230b, the conductor 242a, and the conductor 242b.

In this specification and the like, the oxide 230a and the oxide 230b are collectively referred to as the oxide 230 in some cases. The conductor 242a and the conductor 242b are collectively referred to as a conductor 242 in some cases.

The opening 258 reaching the oxide 230b is provided in the insulator 280 and the insulator 275. In other words, the opening 258 includes a region overlapping with the oxide 230b. It can also be said that the insulator 275 includes the opening overlapping with the opening included in the insulator 280. That is, the opening 258 includes the opening included in the insulator 280 and the opening included in the insulator 275. The insulator 253, the insulator 254, and the conductor 260 are located in the opening 258. That is, the conductor 260 includes a region overlapping with the oxide 230b with the insulator 253 and the insulator 254 therebetween. Furthermore, in the channel length direction of the transistor 200, the conductor 260, the insulator 253, and the insulator 254 are provided between the conductor 242a and the conductor 242b. The insulator 254 includes a region in contact with the side surface of the conductor 260 and a region in contact with the bottom surface of the conductor 260. As illustrated in FIG. 1C, the opening 258 reaches the insulator 222 in a region not overlapping with the oxide 230.

The oxide 230 preferably includes the oxide 230a located over the insulator 224 and the oxide 230b located over the oxide 230a. With the oxide 230a located under the oxide 230b, diffusion of impurities from components formed below the oxide 230a into the oxide 230b can be inhibited.

Although a structure in which two layers, the oxide 230a and the oxide 230b, are stacked as the oxide 230 in the transistor 200 is described, the present invention is not limited thereto. For example, only the oxide 230b may be provided as the oxide 230, a stacked-layer structure of three or more layers may be provided as the oxide 230, or the oxide 230a and the oxide 230b may each have a stacked-layer structure.

The conductor 260 functions as the first gate electrode and the conductor 205 functions as the second gate electrode. The insulator 253 and the insulator 254 function as the first gate insulator, and the insulator 222 and the insulator 224 function as the second gate insulator. The conductor 242a functions as the one of the source electrode and the drain electrode, and the conductor 242b functions as the other of the source electrode and the drain electrode. At least part of a region of the oxide 230 overlapping with the conductor 260 functions as a channel formation region.

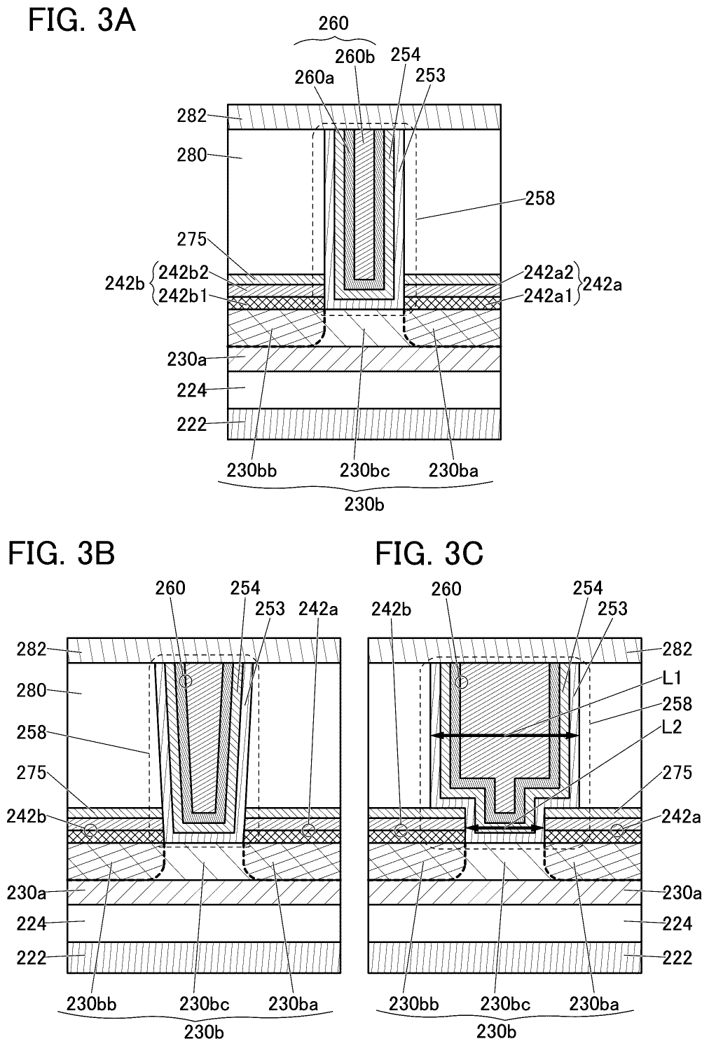

Here, FIG. 3A is an enlarged view of the vicinity of the channel formation region in FIG. 1B. As illustrated in FIG. 3A and FIG. 1C, the opening 258 can also be regarded as having a shape in which part of a structure body including the insulator 224 and the oxide 230 protrudes in an opening having the insulator 222 as its bottom surface and the insulator 280 and the insulator 275 as its side surface.

As illustrated in FIG. 3A and FIG. 1C, the insulator 253 is provided in contact with the bottom surface and the inner wall (also referred to as sidewall) of the opening 258. Accordingly, the insulator 253 is in contact with at least part of each of the top surface of the insulator 222, the side surface of the insulator 224, the side surface of the oxide 230a, the top surface and the side surface of the metal oxide 230b, side surfaces of the conductor 242a and the conductor 242b, the side surface of the insulator 275, the side surface of the insulator 280, and the bottom surface of the insulator 254.

As illustrated in FIG. 3A, the width of the opening 258 in the channel length direction is substantially equal to the distance between the conductor 242a and the conductor 242b. Thus, the channel formation region is formed in a region of the oxide 230b that overlaps with the width of the opening 258 in the channel length direction. Here, the distance between the conductor 242a and the conductor 242b is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm, for example. When the channel formation region of the transistor 200 is extremely minute as described above, the transistor 200 can have a higher on-state current and improved frequency characteristics. In addition, a plurality of the transistors 200 can be provided with high density in a small area. Note that without limitation to the above, the distance between the conductor 242a and the conductor 242b can be greater than or equal to 60 nm.

Miniaturization of the transistor 200 can improve the high frequency characteristics. Specifically, the cutoff frequency can be improved. When the gate length is within any of the above ranges, the cutoff frequency of the transistor can be greater than or equal to 50 GHz or greater than or equal to 100 GHz at room temperature, for example.

Although FIG. 3A illustrates a structure in which the sidewall of the opening 258 is substantially perpendicular to the top surface of the insulator 222, the present invention is not limited thereto. As illustrated in FIG. 3B, the sidewall of the opening 258 may have a tapered shape. When the sidewall of the opening 258 has a tapered shape, the coverage with the insulator 253 and the like can be improved in a later step, so that defects such as a void can be reduced.

Note that in this specification and the like, a tapered shape refers to a shape such that at least part of a side surface of a component is inclined to a substrate surface. Preferably, there is a region where the angle formed between the inclined side surface and the substrate surface (hereinafter, the angle is sometimes referred to as a taper angle) is less than 90°, for example. Note that the side surface of the component and the substrate surface are not necessarily completely flat and may be substantially flat with a slight curvature or substantially flat with slight unevenness.

As illustrated in FIG. 3C, a distance L2 between the conductor 242a and the conductor 242b may be smaller than the width of the opening 258 in the cross-sectional view of the transistor 200 in the channel length direction. Here, the width of the opening 258 corresponds to a distance L1 between an interface between the insulator 280 and the insulator 253 on the conductor 242a side and an interface between the insulator 280 and the insulator 253 on the conductor 242b side, which is illustrated in FIG. 3C. With such a structure, the distance L2 between the conductor 242a and the conductor 242b can be extremely small (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Since the conductor 260 includes a region having the distance L1 larger than the distance L2, an increase in the resistance of the conductor 260 located in the region having the distance L1 can be inhibited and the conductor 260 can function as a wiring.

As illustrated in FIG. 3C, in the opening 258 seen in the cross-sectional view of the transistor 200 in the channel length direction, the width of the opening included in the insulator 280 is equal to the distance L1, and the width of the opening included in the insulator 275 is equal to the distance L2.

As illustrated in FIG. 3C and FIG. 1C, the opening 258 can also be regarded as having a shape in which part of a structure body including the insulator 224, the oxide 230, the conductor 242, and the insulator 275 protrudes in an opening having the insulator 222 as its bottom surface and the insulator 280 as its side surface. Furthermore, a region of the oxide 230 sandwiched between the conductor 242a and the conductor 242b can be regarded as being exposed in the structure body including the insulator 224, the oxide 230, the conductor 242, and the insulator 275.

As illustrated in FIG. 3C and FIG. 1C, the insulator 253 is provided in contact with the bottom surface and the inner wall (also referred to as sidewall) of the opening 258. Accordingly, the insulator 253 is in contact with at least part of each of the top surface of the insulator 222, the side surface of the insulator 224, the side surface of the oxide 230a, the top surface and the side surface of the metal oxide 230b, the side surfaces of the conductor 242a and the conductor 242b, the side surface of the insulator 275, the side surface of the insulator 280, and the bottom surface of the insulator 254. The insulator 254 and the conductor 260 are stacked over the insulator 253. Thus, the insulator 253, the insulator 254, and the conductor 260 are provided to cover the parts of the conductor 242 and the insulator 275 that protrude in the opening 258.

The channel formation region is formed in a region of the oxide 230b corresponding to the distance L2. Thus, the channel formation region of the transistor 200 is extremely minute. Accordingly, the transistor 200 can have a higher on-state current and improved frequency characteristics.

As illustrated in FIG. 3A, the oxide 230b includes a region 230bc functioning as the channel formation region of the transistor 200 and a region 230ba and a region 230bb that are provided to sandwich the region 230bc and function as a source region and a drain region. At least part of the region 230bc overlaps with the conductor 260. In other words, the region 230bc is provided in a region between the conductor 242a and the conductor 242b. The region 230ba is provided to overlap with the conductor 242a, and the region 230bb is provided to overlap with the conductor 242b.

The region 230bc functioning as the channel formation region has a smaller amount of oxygen vacancies or a lower impurity concentration than the region 230ba and the region 230bb, and thus is a high-resistance region with a low carrier concentration. Thus, the region 230bc can be regarded as being i-type (intrinsic) or substantially i-type.

The region 230ba and the region 230bb functioning as the source region and the drain region have a large amount of oxygen vacancies or a high concentration of an impurity such as hydrogen, nitrogen, or a metal element, and thus are each a low-resistance region with an increased carrier concentration. In other words, the region 230ba and the region 230bb are each an n-type region having a higher carrier concentration and lower resistance than the region 230bc.

Here, as illustrated in FIG. 3A, the side surfaces of the conductor 242a and the conductor 242b that face each other are preferably substantially perpendicular to the top surface of the oxide 230b. Such a structure can inhibit excessive recession of a side end portion of the region 230ba on the region 230bc side that is formed under the conductor 242a from a side end portion of the conductor 242a on the region 230bc side. Similarly, such a structure can inhibit excessive recession of a side end portion of the region 230bb on the region 230bc side that is formed under the conductor 242b from a side end portion of the conductor 242b on the region 230bc side. This can inhibit formation of what is called a Loff region between the region 230ba and the region 230bc and between the region 230bb and the region 230bc. Here, the recession of the side end portion of the region 230ba on the region 230bc side indicates that the side end portion of the region 230ba is located closer to the conductor 240 than the side surface of the conductor 242a on the region 230bc side is. The recession of the side end portion of the region 230bb on the region 230bc side indicates that the side end portion of the region 230bb is located closer to the conductor 160 than the side surface of the conductor 242b on the region 230bc side is.

Accordingly, the frequency characteristics of the transistor 200 can be improved, and the operation speed of the semiconductor device of one embodiment of the present invention can be improved. For example, in the case where the semiconductor device of one embodiment of the present invention is used as a memory cell of a storage device, the writing speed and the reading speed can be improved.

The carrier concentration of the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, and yet still further preferably lower than 1×10¹² cm⁻³. Note that the lower limit of the carrier concentration of the region 230bc functioning as the channel formation region is not particularly limited and can be, for example, 1×10⁻⁹ cm⁻³.

Between the region 230bc and the region 230ba or the region 230bb, a region having a carrier concentration that is lower than or substantially equal to the carrier concentrations of the region 230ba and the region 230bb and higher than or substantially equal to the carrier concentration of the region 230bc may be formed. That is, the region functions as a junction region between the region 230bc and the region 230ba or the region 230bb. The junction region has a hydrogen concentration lower than or substantially equal to the hydrogen concentrations of the region 230ba and the region 230bb and higher than or substantially equal to the hydrogen concentration of the region 230bc in some cases. The amount of oxygen vacancies in the junction region is smaller than or substantially equal to the amounts of oxygen vacancies in the region 230ba and the region 230bb and larger than or substantially equal to the amount of oxygen vacancies in the region 230bc in some cases.

Although FIG. 3A illustrates an example where the region 230ba, the region 230bb, and the region 230bc are formed in the oxide 230b, the present invention is not limited thereto. For example, the above regions may be formed not only in the oxide 230b but also in the oxide 230a.

In the oxide 230, the boundaries between the regions are difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region has lower concentrations of a metal element and an impurity element such as hydrogen or nitrogen.

In the transistor 200, a metal oxide functioning as a semiconductor (hereinafter also referred to as an oxide semiconductor) is preferably used for the oxide 230 (the oxide 230a and the oxide 230b) including the channel formation region.

The metal oxide functioning as a semiconductor preferably has a band gap wider than or equal to 2 eV, further preferably wider than or equal to 2.5 eV. With use of a metal oxide having a wide band gap, the off-state current of the transistor can be reduced.

As the oxide 230, a metal oxide such as indium oxide, gallium oxide, or zinc oxide is preferably used, for example. Alternatively, as the oxide 230, a metal oxide containing two or three selected from indium, an element M, and zinc is preferably used, for example. The element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more selected from aluminum, gallium, yttrium, and tin. Note that a metal oxide containing indium, the element M, and zinc is referred to as an In-M-Zn oxide in some cases.

The oxide 230 preferably has a stacked-layer structure of a plurality of oxide layers with different chemical compositions. For example, the atomic ratio of the element M to a metal element that is a main component in the metal oxide used as the oxide 230a is preferably higher than the atomic ratio of the element M to a metal element that is a main component in the metal oxide used as the oxide 230b. Moreover, the atomic ratio of the element M to In in the metal oxide used as the oxide 230a is preferably higher than the atomic ratio of the element M to In in the metal oxide used as the oxide 230b. With this structure, impurities and oxygen can be inhibited from diffusing into the oxide 230b from the components formed below the oxide 230a.

Furthermore, the atomic ratio of In to the element M in the metal oxide used as the oxide 230b is preferably higher than the atomic ratio of In to the element M in the metal oxide used as the oxide 230a. With this structure, the transistor 200 can have a high on-state current and high frequency characteristics.

When the oxide 230a and the oxide 230b include a common element as the main component besides oxygen, the density of defect states at the interface between the oxide 230a and the oxide 230b can be reduced. Thus, the influence of interface scattering on carrier conduction is small, and the transistor 200 can have a high on-state current and high frequency characteristics.

Specifically, as the oxide 230a, a metal oxide with a composition of In:M:Zn=1:3:4 [atomic ratio] or in the neighborhood thereof, a composition of In:M:Zn=1:3:2 [atomic ratio] or in the neighborhood thereof, or a composition of In:M:Zn=1:1:0.5 [atomic ratio] or in the neighborhood thereof is used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is used. Note that a composition in the neighborhood includes the range of +30% of an intended atomic ratio. Gallium is preferably used as the element M. In the case where only the oxide 230b is provided as the oxide 230, a metal oxide that can be used as the oxide 230a may be used as the oxide 230b.

When a film of the metal oxide is formed by a sputtering method, the above atomic ratio is not limited to the atomic ratio of the formed film of the metal oxide and may be the atomic ratio of a sputtering target used for forming the film of the metal oxide.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in the manufacturing process (what is called thermal budget).

A transistor using an oxide semiconductor is likely to have its electrical characteristics changed by impurities and oxygen vacancies in a region of the oxide semiconductor where a channel is formed, which might degrade the reliability. In some cases, hydrogen in the vicinity of an oxygen vacancy forms a defect that is an oxygen vacancy into which hydrogen enters (hereinafter, sometimes referred to as V_{O}H), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and a current flows through the transistor).

Therefore, impurities, oxygen vacancies, and V_{O}H are preferably reduced as much as possible in the region of the oxide semiconductor where a channel is formed. In other words, it is preferable that the region of the oxide semiconductor where a channel is formed have a reduced carrier concentration and be of i-type (intrinsic) or substantially i-type.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Therefore, the region 230bc functioning as the channel formation region in the oxide semiconductor is preferably an i-type or substantially i-type region with a reduced carrier concentration, whereas the region 230ba and the region 230bb functioning as the source region and the drain region are preferably n-type regions with high carrier concentrations. That is, the amounts of oxygen vacancies and V_{O}H in the region 230bc of the oxide semiconductor are preferably reduced. Furthermore, it is preferable that the region 230ba and the region 230bb not be supplied with an excessive amount of oxygen and the amount of V_{O}H in the region 230ba and the region 230bb not be excessively reduced. Furthermore, a reduction in conductivity of the conductor 260, the conductor 242a, the conductor 242b, and the like is preferably inhibited. For example, oxidation of the conductor 260, the conductor 242a, the conductor 242b, and the like is preferably inhibited. Note that hydrogen in an oxide semiconductor can form V_{O}H; thus, the hydrogen concentration needs to be reduced in order to reduce the amount of V_{O}H.

In view of this, the semiconductor device of this embodiment has a structure in which the hydrogen concentration of the region 230bc is reduced, oxidation of the conductor 242a, the conductor 242b, and the conductor 260 is inhibited, and the hydrogen concentrations in the region 230ba and the region 230bb are inhibited from being reduced.

In order to reduce the hydrogen concentration of the region 230bc, the insulator 253 preferably has a function of capturing and fixing hydrogen. As illustrated in FIG. 3(A) and the like, the insulator 253 includes a region in contact with the region 230bc of the oxide 230b. With this structure, the hydrogen concentration in the region 230bc of the oxide 230b can be reduced. Thus, the amount of V_{O}H in the region 230bc can be reduced, whereby the region 230bc can be an i-type or substantially i-type region.

An example of the insulator having a function of capturing and fixing hydrogen is a metal oxide having an amorphous structure. For example, a metal oxide, such as magnesium oxide or an oxide containing one or both of aluminum and hafnium, is preferably used. In such a metal oxide having an amorphous structure, an oxygen atom has a dangling bond and sometimes has a property of capturing or fixing hydrogen with the dangling bond. In other words, the metal oxide having an amorphous structure has high capability of capturing or fixing hydrogen.

Specifically, as the insulator 253, an oxide containing one or both of aluminum and hafnium is preferably used, more preferably, an oxide containing one or both of aluminum and hafnium and having an amorphous structure is used, and further preferably, hafnium oxide having an amorphous structure is used. In this embodiment, hafnium oxide is used as the insulator 253. In this case, the insulator 253 includes at least oxygen and hafnium. The hafnium oxide has an amorphous structure. In this case, the insulator 253 has an amorphous structure.

Note that an insulator that can be used as the insulator 253 is not limited to the above barrier insulator against hydrogen. An insulator having a thermally stable structure, such as silicon oxide or silicon oxynitride, can also be used. For example, a stacked-layer film including an aluminum oxide film and a silicon oxide film or a silicon oxynitride film over the aluminum oxide film may be used as the insulator 253. Alternatively, for example, a stacked-layer film including an aluminum oxide film, a silicon oxide film or a silicon oxynitride film over the aluminum oxide film, and a hafnium oxide film over the silicon oxide film or the silicon oxynitride film may be used as the insulator 253.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing and fixing (also referred to as gettering) a targeted substance.

Examples of a barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 may be a single layer or stacked layers of the above barrier insulator against oxygen.

The insulator 253 preferably has a barrier property against oxygen. Note that the insulator 253 is less permeable to oxygen than at least the insulator 280. The insulator 253 includes a region in contact with the side surface of the conductor 242a and the side surface of the conductor 242b. When the insulator 253 has a barrier property against oxygen, oxidation of the side surfaces of the conductor 242a and the conductor 242b, which forms oxide films on the side surfaces, can be inhibited. Accordingly, a decrease in the on-state current or field-effect mobility of the transistor 200 can be inhibited.

The insulator 253 is provided in contact with the top surface and the side surface of the oxide 230b, the side surface of the oxide 230a, the side surface of the insulator 224, and the top surface of the insulator 222. When the insulator 253 has a barrier property against oxygen, release of oxygen from the region 230bc of the oxide 230b caused by heat treatment or the like can be inhibited. This can inhibit formation of oxygen vacancies in the oxide 230a and the oxide 230b.

Even when an excess amount of oxygen is contained in the insulator 280, the oxygen can be inhibited from being excessively supplied to the oxide 230a and the oxide 230b. This can inhibit excessive oxidation of the region 230ba and the region 230bb, thereby inhibiting a reduction in the on-state current or field-effect mobility of the transistor 200.

An oxide containing one or both of aluminum and hafnium has a barrier property against oxygen and thus can be suitably used as the insulator 253.

The insulator 254 preferably has a barrier property against oxygen. The insulator 254 is provided between the conductor 260 and the region 230bc of the oxide 230b and between the insulator 280 and the conductor 260. This structure can inhibit oxygen contained in the region 230bc of the oxide 230b from diffusing into the conductor 260 and thus can inhibit formation of oxygen vacancies in the region 230bc of the oxide 230b. Oxygen contained in the oxide 230b and oxygen contained in the insulator 280 can be inhibited from diffusing into the conductor 260 and oxidizing the conductor 260. Note that the insulator 254 is less permeable to oxygen than at least the insulator 280. For example, silicon nitride is preferably used as the insulator 254. In that case, the insulator 254 includes at least nitrogen and silicon.

The insulator 275 preferably has a barrier property against oxygen. The insulator 275 is provided between the insulator 280 and each of the conductor 242a and the conductor 242b. This structure can inhibit diffusion of oxygen contained in the insulator 280 into the conductor 242a and the conductor 242b. Thus, the conductor 242a and the conductor 242b can be inhibited from being oxidized by oxygen included in the insulator 280, so that an increase in resistivity and a reduction in on-state current of the transistor 200 can be inhibited. Note that the insulator 275 is less permeable to oxygen than at least the insulator 280. For example, silicon nitride is preferably used as the insulator 275. In that case, the insulator 275 includes at least nitrogen and silicon.

In order to inhibit a reduction in the hydrogen concentrations in the region 230ba and the region 230bb, a barrier insulator against hydrogen is preferably provided in the vicinity of each of the region 230ba and the region 230bb. In the semiconductor device described in this embodiment, the barrier insulator against hydrogen corresponds to, for example, the insulator 275.

Examples of the barrier insulator against hydrogen include an oxide such as aluminum oxide, hafnium oxide, or tantalum oxide and a nitride such as silicon nitride. For example, the insulator 275 may be a single layer or stacked layers of the barrier insulator against hydrogen.

The insulator 275 preferably has a barrier property against hydrogen. The insulator 275 is located in contact with the side surface of the region 230ba in the oxide 230b and the side surface of the region 230bb in the oxide 230b. Providing the insulator 275 as described above can inhibit hydrogen in the region 230ba and the region 230bb from diffusing to the outside, so that a reduction in the hydrogen concentrations of the region 230ba and the region 230bb can be inhibited. Accordingly, the region 230ba and the region 230bb can be n-type regions.

With the above structure, the region 230bc functioning as the channel formation region can be an i-type or substantially i-type region, the region 230ba and the region 230bb functioning as the source region and the drain region can be n-type regions, and thus, a semiconductor device with favorable electrical characteristics can be provided. The semiconductor device with the above structure can have favorable electrical characteristics even when miniaturized or highly integrated.

The insulator 253 functions as part of the gate insulator. As illustrated in FIG. 1B, the insulator 253 is provided in contact with the side surface of the insulator 275 and the side surface of the insulator 280.

The insulator 253 needs to be provided in the opening formed in the insulator 280 and the like, together with the insulator 254 and the conductor 260. The thickness of the insulator 253 is preferably small for miniaturization of the transistor 200. The thickness of the insulator 253 is greater than or equal to 0.1 nm and less than or equal to 5.0 nm, preferably greater than or equal to 0.5 nm and less than or equal to 5.0 nm, further preferably greater than or equal to 1.0 nm and less than 5.0 nm, still further preferably greater than or equal to 1.0 nm and less than or equal to 3.0 nm. In this case, at least part of the insulator 253 includes a region having a thickness like the above-described thickness.

To form the insulator 253 having a small thickness as described above, an atomic layer deposition (ALD) method is preferably used for film formation. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because film formation at a lower temperature is possible.

An ALD method, which enables an atomic layer to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 253 can be formed on the side surface of the opening formed in the insulator 280 and the like, the side end portion of the conductor 242, and the like, with a small thickness like the above-described thickness and favorable coverage.

Note that some of precursors usable in an ALD method contain carbon or the like. Thus, in some cases, a film provided by an ALD method includes impurities such as carbon in a larger amount than a film provided by another film formation method. Note that impurities can be quantified by secondary ion mass spectrometry (SIMS), X-ray photoelectron spectroscopy (XPS), or auger electron spectroscopy (AES).

Note that the insulator 253 does not necessarily have the above thickness. For example, the thickness of the insulator 253 is appropriately set to be within the range of approximately 0.1 nm to 30 nm, considering the case where the insulator 253 has a stacked-layer structure of an aluminum oxide film, a silicon oxide film over the aluminum oxide film, and a hafnium oxide film over the silicon oxide film, for example.

The insulator 254 functions as part of the gate insulator. The insulator 254 preferably has a barrier property against hydrogen. In that case, diffusion of impurities included in the conductor 260, such as hydrogen, into the oxide 230b can be prevented.

The insulator 254 needs to be provided in the opening formed in the insulator 280 and the like, together with the insulator 253 and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 includes a region having a thickness like the above-described thickness.

As the insulator 254, a film of silicon nitride formed by a PEALD method is used, for example.

When an insulator having a function of inhibiting the passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

The insulator 275 is provided to cover the insulator 222, the insulator 224, the oxide 230a, the oxide 230b, and the conductor 242. Specifically, the insulator 275 includes a region in contact with the top surface of the insulator 222, a region in contact with the side surface of the insulator 224, a region in contact with the side surface of the oxide 230a, a region in contact with the side surface of the oxide 230b, a region in contact with the top surface and a side surface of the conductor 242a, and a region in contact with the top surface and a side surface of the conductor 242b.

A conductive material that is less likely to be oxidized, a conductive material having a function of inhibiting diffusion of oxygen, or the like is preferably used for the conductor 242a, the conductor 242b, and the conductor 260. Examples of the conductive material include a conductive material containing nitrogen, a conductive material containing oxygen, and the like. This can inhibit a reduction in the conductivity of the conductor 242a, the conductor 242b, and the conductor 260. In the case where a conductive material containing a metal and nitrogen is used for the conductor 242a, the conductor 242b, and the conductor 260, the conductor 242a, the conductor 242b, and the conductor 260 include at least the metal and nitrogen.

One or both of the conductor 242 and the conductor 260 may have a stacked-layer structure. For example, as illustrated in FIG. 1B, the conductor 242a and the conductor 242b may each have a stacked-layer structure of two layers. In that case, a conductive material that is not easily oxidized, a conductive material having a function of inhibiting diffusion of oxygen, or the like is preferably used for the layers (the conductor 242al and the conductor 242b1) that are in contact with the oxide 230b. For example, in the case where the conductor 260 has a stacked-layer structure of the conductor 260a and the conductor 260b as illustrated in FIG. 1B, a conductive material that is less likely to be oxidized, a conductive material having a function of inhibiting diffusion of oxygen, or the like is preferably used for the conductor 260a.

To inhibit a reduction in the conductivity of the conductor 242, an oxide having crystallinity, such as a CAAC-OS, is preferably used as the oxide 230b. As the oxide, a metal oxide that can be used as the oxide 230 described above is preferably used. In particular, a metal oxide containing indium, zinc, and one or more selected from gallium, aluminum, and tin is preferably used. The CAAC-OS is an oxide including a crystal, and the c-axis of the crystal is substantially perpendicular to the surface of the oxide or a formation surface. This can inhibit the conductor 242a or the conductor 242b from extracting oxygen from the oxide 230b. Furthermore, it is possible to inhibit a reduction in the conductivity of the conductor 242a and the conductor 242b.

In this embodiment, microwave treatment is performed in an atmosphere containing oxygen in a state where the conductor 242a and the conductor 242b are provided over the oxide 230b so that oxygen vacancies and V_{O}H in the region 230bc can be reduced. Here, the microwave treatment refers to, for example, treatment using an apparatus including a power source that generates high-density plasma with the use of a microwave.

The microwave treatment performed in an oxygen-containing atmosphere can convert an oxygen gas into plasma using a high-frequency wave such as a microwave or RF and activate the oxygen plasma. At this time, the region 230bc can also be irradiated with the high-frequency wave such as a microwave or RF. By the effect of the plasma, the microwave, or the like, V_{O}H in the region 230bc can be divided into an oxygen vacancy and hydrogen; the hydrogen can be removed from the region 230bc and the oxygen vacancy can be compensated for. As a result, the hydrogen concentration, oxygen vacancies, and V_{O}H in the region 230bc can be reduced to lower the carrier concentration.

In the microwave treatment in an oxygen-containing atmosphere, the effect of the high-frequency wave such as a microwave or RF, the oxygen plasma, or the like is blocked by the conductor 242a and the conductor 242b and does not affect the region 230ba or the region 230bb. In addition, the effect of the oxygen plasma can be reduced by the insulator 275 and the insulator 280 that are provided to cover the oxide 230b and the conductor 242. Hence, a reduction in V_{O}H and supply of an excess amount of oxygen do not occur in the region 230ba or the region 230bb in the microwave treatment, preventing a decrease in carrier concentration.

Microwave treatment is preferably performed in an oxygen-containing atmosphere after an insulating film to be the insulator 253 is formed. In the case of the insulator 253 having a stacked-layer structure, the microwave treatment may be performed in a state where part of the insulator 253 is formed. For example, in the case where the insulator 253 includes a silicon oxide film or a silicon oxynitride film, the microwave treatment may be performed at the time when the silicon oxide film or the silicon oxynitride film is formed.

By performing the microwave treatment in an oxygen-containing atmosphere through the insulator 253 in such a manner, oxygen can be efficiently implanted into the region 230bc. In addition, the insulator 253 is located to be in contact with the side surface of the conductor 242 and a surface of the region 230bc, thereby inhibiting more than a necessary amount of oxygen from being implanted into the region 230bc and inhibiting the side surface of the conductor 242 from being oxidized.

The oxygen implanted into the region 230bc is in any of a variety of forms such as an oxygen atom, an oxygen molecule, an oxygen ion, and an oxygen radical (also referred to as O radical, which is an atom, a molecule, or an ion having an unpaired electron). Note that the oxygen implanted into the region 230bc is in any one or more of the above forms, and is particularly suitably an oxygen radical. Furthermore, the film quality of the insulator 253 can be improved, leading to higher reliability of the transistor 200.

In this manner, oxygen vacancies and V_{O}H can be selectively removed from the region 230bc in the oxide semiconductor, whereby the region 230bc can be an i-type or substantially i-type region. Furthermore, supply of an excess amount of oxygen to the region 230ba and the region 230bb functioning as the source region and the drain region can be inhibited, and the state of the n-type regions before the microwave treatment is performed can be maintained. Thus, a change in the electrical characteristics of the transistor 200 can be inhibited, and thus a variation in the electrical characteristics of the transistors 200 in the substrate plane can be inhibited.

With the above structure, a semiconductor device with a small variation in transistor characteristics can be provided. A semiconductor device with favorable frequency characteristics can be provided. A semiconductor device with high operation speed can be provided. A semiconductor device with favorable reliability can be provided. A semiconductor device having favorable electrical characteristics can be provided. A semiconductor device that can be miniaturized or highly integrated can be provided.

As illustrated in FIG. 1C, a curved surface may be provided between the side surface of the oxide 230b and the top surface of the oxide 230b in the cross-sectional view of the transistor 200 in the channel width direction. That is, an end portion of the side surface and an end portion of the top surface may be curved (hereinafter also referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 253, the insulator 254, and the conductor 260.

In the manufacturing process of the transistor 200, heat treatment is preferably performed with a surface of the oxide 230 exposed. The heat treatment is performed at higher than or equal to 100° C. and lower than or equal to 600° C., preferably higher than or equal to 350° C. and lower than or equal to 550° C., for example. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 230 to reduce oxygen vacancies. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere. Alternatively, the heat treatment may be performed in a nitrogen gas or inert gas atmosphere successively after heat treatment is performed in an atmosphere containing an oxidizing gas at higher than or equal to 10 ppm, higher than or equal to 1%, or higher than or equal to 10%.

Note that by oxygen adding treatment performed on the oxide 230, oxygen vacancies in the oxide 230 can be repaired with supplied oxygen. Furthermore, hydrogen remaining in the oxide 230 reacts with supplied oxygen, so that the hydrogen can be removed as H₂O (dehydration).

This can inhibit recombination of hydrogen remaining in the oxide 230 with oxygen vacancies and formation of V_{O}H.

As illustrated in FIG. 1C and the like, the insulator 253 is provided in contact with the top surface and the side surface of the oxide 230, whereby indium included in the oxide 230 is unevenly distributed, in some cases, at the interface between the oxide 230 and the insulator 253 and in its vicinity. Accordingly, the vicinity of the surface of the oxide 230 has an atomic ratio close to that of indium oxide or that of In—Zn oxide. Such an increase in the atomic ratio of indium in the vicinity of the surface of the oxide 230, especially the oxide 230b, can increase the field-effect mobility of the transistor 200.

In addition to the above structure, the semiconductor device of this embodiment preferably has a structure in which hydrogen is inhibited from entering the transistor 200. For example, an insulator having a function of inhibiting diffusion of hydrogen is preferably provided to cover the transistor 200. In the semiconductor device described in this embodiment, the insulator corresponds to the insulator 212, for example.

As the insulator 212, an insulator having a function of inhibiting diffusion of hydrogen is preferably used. This can inhibit diffusion of hydrogen into the transistor 200 from below the insulator 212. As the insulator 212, an insulator that can be used as the insulator 275 described above may be used.

At least one of the insulator 212, the insulator 214, the insulator 282, and the insulator 285 preferably functions as a barrier insulating film that inhibits diffusion of impurities such as water and hydrogen into the transistor 200 from the substrate side or from above the transistor 200. Thus, for at least one of the insulator 212, the insulator 214, the insulator 282, and the insulator 285, it is preferable to use an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom (an insulating material that is less permeable to the impurities). Alternatively, it is preferable to use an insulating material having a function of inhibiting diffusion of oxygen (e.g., at least one of an oxygen atom, an oxygen molecule, and the like) (an insulating material that is less permeable to the oxygen).

An insulator having a function of inhibiting diffusion of oxygen and impurities such as water and hydrogen is preferably used for the insulator 212, the insulator 214, the insulator 282, and the insulator 285; for example, aluminum oxide, magnesium oxide, hafnium oxide, gallium oxide, indium gallium zinc oxide, silicon nitride, silicon nitride oxide, or the like can be used. For example, silicon nitride or the like, which has a higher hydrogen barrier property, is preferably used for the insulator 212. For example, aluminum oxide, magnesium oxide, or the like, which has a function of capturing and fixing hydrogen well, is preferably used for the insulator 214, the insulator 282, and the insulator 285. In that case, impurities such as water and hydrogen can be inhibited from diffusing to the transistor 200 side from the substrate side through the insulator 212 and the insulator 214. Alternatively, impurities such as water and hydrogen can be inhibited from diffusing to the transistor 200 side from an interlayer insulating film and the like that are located outside the insulator 285. Alternatively, oxygen included in the insulator 224 and the like can be inhibited from diffusing to the substrate side through the insulator 212 and the insulator 214. Alternatively, oxygen included in the insulator 280 and the like can be inhibited from diffusing to above the transistor 200 through the insulator 282 and the like. In this manner, it is preferable that the transistor 200 be surrounded by the insulator 212, the insulator 214, the insulator 282, and the insulator 285, which have a function of inhibiting diffusion of oxygen and impurities such as water and hydrogen.

Here, an oxide having an amorphous structure is preferably used for the insulator 212, the insulator 214, the insulator 282, and the insulator 285. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as a component of the transistor 200 or provided around the transistor 200, hydrogen included in the transistor 200 or hydrogen around the transistor 200 can be captured or fixed. In particular, hydrogen included in the channel formation region of the transistor 200 is preferably captured or fixed. When the metal oxide having an amorphous structure is used as a component of the transistor 200 or provided around the transistor 200, the transistor 200 and the semiconductor device that have favorable characteristics and high reliability can be manufactured.

Although the insulator 212, the insulator 214, the insulator 282, and the insulator 285 preferably have an amorphous structure, a region having a polycrystalline structure may be partly formed. The insulator 212, the insulator 214, the insulator 282, and the insulator 285 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

The insulator 212, the insulator 214, the insulator 282, and the insulator 285 are formed by a sputtering method, for example. Since a sputtering method does not need to use a molecule containing hydrogen as a film formation gas, the hydrogen concentrations of the insulator 212, the insulator 214, the insulator 282, and the insulator 285 can be reduced. Note that the film formation method is not limited to a sputtering method, and a chemical vapor deposition (CVD) method, a molecular beam epitaxy (MBE) method, a pulsed laser deposition (PLD) method, an ALD method, or the like may be used as appropriate.

The resistivity of the insulator 212 is preferably low in some cases. For example, by setting the resistivity of the insulator 212 to approximately 1×10¹³ Ωcm, the insulator 212 can sometimes reduce charge up of the conductor 205, the conductor 242, the conductor 260, or the conductor 240 in treatment using plasma or the like in the manufacturing process of the semiconductor device. The resistivity of the insulator 212 is preferably higher than or equal to 1×10¹⁰ Ωcm and lower than or equal to 1×10¹⁵ Ωcm.

The insulator 216, the insulator 280, and the insulator 285 each preferably have a lower permittivity than the insulator 214. When a material with a low permittivity is used for the interlayer film, parasitic capacitance generated between wirings can be reduced. For the insulator 216, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example. The conductor 205 is located to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the opening. The conductor 205b is provided to be embedded in a depressed portion defined by the conductor 205a. Here, the top surface of the conductor 205b is level or substantially level with the top surface of the conductor 205a and the top surface of the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When a conductive material having a function of inhibiting diffusion of hydrogen is used for the conductor 205a, impurities such as hydrogen included in the conductor 205b can be prevented from diffusing into the oxide 230 through the insulator 216, the insulator 224, and the like. When a conductive material having a function of inhibiting diffusion of oxygen is used for the conductor 205a, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, a single layer or a stacked layer of the above conductive material may be used for the conductor 205a. For example, titanium nitride may be used for the conductor 205a.

A conductive material containing tungsten, copper, or aluminum as its main component is preferably used for the conductor 205b. For example, tungsten is used for the conductor 205b.

The conductor 205 sometimes functions as the second gate electrode. In that case, by changing the potential applied to the conductor 205 not in conjunction with but independently of the potential applied to the conductor 260, the threshold voltage (Vth) of the transistor 200 can be controlled. In particular, by applying a negative potential to the conductor 205, Vth of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is set in accordance with the electrical resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen included in the insulator 216 can be reduced, inhibiting diffusion of the impurities into the oxide 230.

As illustrated in FIG. 1A, the conductor 205 is preferably provided to be larger than a region of the oxide 230 that does not overlap with the conductor 242a or the conductor 242b. As illustrated in FIG. 1C, it is particularly preferable that the conductor 205 extend to a region outside end portions of the oxide 230a and the oxide 230b in the channel width direction. That is, the conductor 205 and the conductor 260 preferably overlap with each other with the insulators therebetween outside the side surface of the oxide 230 in the channel width direction. With this structure, the channel formation region of the oxide 230 can be electrically surrounded by the electric field of the conductor 260 functioning as the first gate electrode and the electric field of the conductor 205 functioning as the second gate electrode.

In this specification and the like, a transistor structure in which a channel formation region is electrically surrounded by at least the electric field of a first gate electrode is referred to as a surrounded channel (S-channel) structure. The S-channel structure disclosed in this specification and the like has a structure different from a Fin-type structure and a planar structure. Meanwhile, the S-channel structure disclosed in this specification and the like can also be regarded as a kind of the Fin-type structure. In this specification and the like, the Fin-type structure refers to a structure where at least two surfaces (specifically, two surfaces, three surfaces, four surfaces, or the like) of a channel are covered with a gate electrode. With the Fin-type structure and the S-channel structure, resistance to a short-channel effect can be enhanced; that is, a transistor in which a short-channel effect is less likely to occur can be provided.

When the transistor 200 has the above-described S-channel structure, the channel formation region can be electrically surrounded. Since the S-channel structure is a structure with the electrically surrounded channel formation region, the S-channel structure can be regarded as being substantially equivalent to a GAA (Gate All Around) structure or a LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can be formed in the entire bulk of the oxide 230. Accordingly, the density of current flowing in the transistor can be improved, which can be expected to improve the on-state current of the transistor or increase the field-effect mobility of the transistor.

Although FIG. 1B illustrates a transistor with the S-channel structure as an example of the transistor 200, the semiconductor device of one embodiment of the present invention is not limited thereto. For example, a transistor structure that can be used in one embodiment of the present invention may be one or more selected from the planar structure, the Fin-type structure, and the GAA structure.

Furthermore, as illustrated in FIG. 1C, the conductor 205 is extended to function as a wiring as well. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is described, the present invention is not limited thereto. For example, the conductor 205 may be provided to have a single-layer structure or a stacked-layer structure of three or more layers.

The insulator 222 and the insulator 224 function as the second gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. As the insulator, aluminum oxide, hafnium oxide, an oxide containing aluminum and hafnium (hafnium aluminate), or the like is preferably used. Alternatively, an oxide containing hafnium and zirconium, e.g., hafnium zirconium oxide, is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen into the transistor 200 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of the insulator and any of silicon oxide, silicon oxynitride, and silicon nitride may be used for the insulator 222.

For example, a single layer or stacked layers of an insulator(s) containing what is called a high-k material such as aluminum oxide, hafnium oxide, tantalum oxide, zirconium oxide, or hafnium zirconium oxide may be used for the insulator 222. As miniaturization and high integration of transistors progress, a problem such as a leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) can be used for the insulator 222 in some cases.

Silicon oxide or silicon oxynitride, for example, is used as appropriate for the insulator 224 that is in contact with the oxide 230.

Note that the insulator 222 and the insulator 224 may each have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a as illustrated in FIG. 1B and the like. In that case, the insulator 275 is in contact with the side surface of the insulator 224 and the top surface of the insulator 222. Note that in this specification and the like, the term “island shape” refers to a state where two or more layers formed using the same material in the same step are physically separated from each other.

The conductor 242a and the conductor 242b are provided in contact with the top surface and the side surface of the oxide 230b, the side surface of the oxide 230a, and the side surface of the insulator 224. Here, a structure can also be employed in which the conductor 242a and the conductor 242b are in contact with the side surfaces of the insulator 224, the oxide 230a, and the oxide 230b in the channel length direction and are not in contact with the side surfaces of the insulator 224, the oxide 230a, and the oxide 230b in the channel width direction. Part of the conductor 242a and part of the conductor 242b are provided in contact with the top surface of the insulator 222. Each of the conductor 242a and the conductor 242b functions as the source electrode or the drain electrode of the transistor 200.

As the conductor 242 (the conductor 242a and the conductor 242b), for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, an oxide containing lanthanum and nickel, or the like may be used. These materials are preferable because they are each a conductive material that is less likely to be oxidized or a material that maintains the conductivity even after absorbing oxygen.

Note that hydrogen included in the oxide 230b or the like diffuses into the conductor 242a or the conductor 242b in some cases. In particular, when a nitride containing tantalum is used for the conductor 242a and the conductor 242b, hydrogen included in the oxide 230b or the like is likely to diffuse into the conductor 242a or the conductor 242b, and the diffused hydrogen is bonded to nitrogen included in the conductor 242a or the conductor 242b in some cases. That is, hydrogen included in the oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 1D. When the conductor 242 has a large cross-sectional area, the resistance of the conductor 242 can be reduced and the on-state current of the transistor 200 can be increased.

As illustrated in FIG. 1A, the conductor 242a includes an opening in a region between the transistor 200a and the transistor 200b. The conductor 240 is located to overlap with the opening. Note that in the top view of the transistor 200, the size of the opening is preferably smaller than the size of the conductor 240. With this structure, a region where the conductor 242a and the conductor 240 are in contact with each other can be provided. Thus, the conductor 242a and the conductor 240 are electrically connected to each other.

Although the memory cell illustrated in FIG. 1A has a structure in which the conductor 242a of the transistor 200a and the conductor 242a of the transistor 200b are integrated, the present invention is not limited thereto. For example, the conductor 242a of the transistor 200a and the conductor 242a of the transistor 200b may be separated from each other. With such a structure, the width of the conductor 242 in the Y direction can be set to the minimum line width, so that the semiconductor device can be highly integrated. In the above case, part of the top surface and part of the side surface of the conductor 242a of the transistor 200a are in contact with the conductor 240, and part of the top surface and part of a side surface of the conductor 242a of the transistor 200b are in contact with the conductor 240. With such a structure, the conductor 240 functioning as a plug is electrically connected to the transistor 200a and the transistor 200b.

When heat treatment is performed in the state where the conductor 242a (the conductor 242b) and the oxide 230b are in contact with each other, the sheet resistance of the oxide 230b in the region overlapping with the conductor 242a (the conductor 242b) decreases in some cases. Furthermore, the carrier concentration sometimes increases. Thus, the resistance of the oxide 230b in the region overlapping with the conductor 242a (the conductor 242b) can be lowered in a self-aligned manner.

The conductor 242a and the conductor 242b are preferably formed using a conductive film having compressive stress. This can form distortion extended in the tensile direction (hereinafter, such distortion is sometimes referred to as tensile distortion) in the region 230ba and the region 230bb. When V_{O}H is stably formed by the tensile distortion, the region 230ba and the region 230bb can be stable n-type regions. Note that the compressive stress of the conductor 242a refers to stress for relaxing the compressive shape of the conductor 242a that has a vector in a direction from a center portion to an end portion of the conductor 242a. The same applies to the compressive stress of the conductor 242b.

The level of the compressive stress of the conductor 242a is, for example, higher than or equal to 500 MPa, preferably higher than or equal to 1000 MPa, further preferably higher than or equal to 1500 MPa, still further preferably higher than or equal to 2000 MPa. Note that the level of the stress of the conductor 242a may be determined from the measured stress of a sample fabricated by forming a conductive film to be used for the conductor 242a on a substrate. The same applies to the level of the compressive stress of the conductor 242b. An example of a conductor having the above level of compressive stress is a nitride containing tantalum.

Due to the action of the compressive stress in the conductor 242a and the conductor 242b, distortion is formed in each of the region 230ba and the region 230bb. The distortion is distortion (tensile distortion) extended in the tensile direction by the action of the compressive stress in the conductor 242a and the conductor 242b. In the case where the region 230ba and the region 230bb have a CAAC structure, the distortion corresponds to extension in the direction perpendicular to the c-axis of the CAAC structure. When the CAAC structure is extended in the direction perpendicular to the c-axis of the CAAC structure, oxygen vacancies are likely to be formed in the distortion. Furthermore, hydrogen is likely to be taken in the distortion, so that V_{O}H is likely to be formed. Thus, oxygen vacancies and V_{O}H are likely to be formed in the distortion and likely to have a stable structure. Thus, the region 230ba and the region 230bb can be stable n-type regions with high carrier concentrations.

Note that although the distortion formed in the oxide 230b is described above, the present invention is not limited thereto. In some cases, a similar distortion is formed in the oxide 230a.

In the semiconductor device illustrated in FIG. 1A to FIG. 1D, the conductor 242 has a stacked-layer structure of two layers. Specifically, the conductor 242a includes the conductor 242al and the conductor 242a2 over the conductor 242a1. Similarly, the conductor 242b includes the conductor 242b1 and the conductor 242b2 over the conductor 242b1. In that case, the conductor 242al and the conductor 242b1 are located on the side in contact with the oxide 230b.

Although described later in detail, the conductor 242al and the conductor 242a2 can be formed using the same material and the same process as the conductor 242b1 and the conductor 242b2, respectively. Thus, the conductor 242al preferably includes the same conductive material as the conductor 242b1. Furthermore, the conductor 242a2 preferably includes the same conductive material as the conductor 242b2.

Hereinafter, the conductor 242al and the conductor 242b1 are collectively referred to as a lower layer of the conductor 242 in some cases. The conductor 242a2 and the conductor 242b2 are collectively referred to as an upper layer of the conductor 242 in some cases.

The lower layer (the conductor 242al and the conductor 242b1) of the conductor 242 is preferably formed using a conductive material having a property of being less likely to be oxidized. This can inhibit oxidation of the lower layer of the conductor 242 and a reduction in the conductivity of the conductor 242. Note that the lower layer of the conductor 242 may have a property of being likely to absorb (extract) hydrogen. Accordingly, hydrogen in the oxide 230 is diffused into the lower layer of the conductor 242, so that the hydrogen concentration of the oxide 230 can be reduced. Thus, the transistor 200 can have stable electrical characteristics. The lower layer of the conductor 242 preferably has high compressive stress as described above, and preferably has higher compressive stress than the upper layer of the conductor 242. In that case, as described above, the region 230ba and the region 230bb that are in contact with the lower layer of the conductor 242 can be stable n-type regions with high carrier concentrations.

The upper layer (the conductor 242a2 and the conductor 242b2) of the conductor 242 preferably has higher conductivity than the lower layer (the conductor 242al and the conductor 242b1) of the conductor 242. For example, the thickness of the upper layer of the conductor 242 is set to be larger than the thickness of the lower layer of the conductor 242. At least part of the upper layer of the conductor 242 includes a region having higher conductivity than the lower layer of the conductor 242. Alternatively, the upper layer of the conductor 242 is preferably formed using a conductive material having lower resistivity than the lower layer of the conductor 242. Accordingly, a semiconductor device with reduced wiring delay can be manufactured.

Note that the upper layer of the conductor 242 may have a property of being likely to absorb hydrogen. Accordingly, hydrogen absorbed by the lower layer of the conductor 242 is also diffused into the upper layer of the conductor 242, so that the hydrogen concentration in the oxide 230 can be further reduced. Thus, the transistor 200 can have stable electrical characteristics.

In the case where the conductor 242 has a stacked-layer structure of two layers, one or more selected from the constituent elements, chemical composition, and film formation conditions may be different between the lower layer of the conductor 242 and the upper layer of the conductor 242.

For example, tantalum nitride or titanium nitride can be used for the lower layer (the conductor 242al and the conductor 242b1) of the conductor 242, and tungsten can be used for the upper layer (the conductor 242a2 and the conductor 242b2) of the conductor 242. In this case, the conductor 242al and the conductor 242b1 include tantalum or titanium and nitrogen. This structure can inhibit oxidation of the lower layer of the conductor 242 and a reduction in the conductivity of the conductor 242. With this structure, the conductor 242a2 can be surrounded by the insulator 275 having a barrier property against oxygen and the conductor 242al having a property of being less likely to be oxidized, and the conductor 242b2 can be surrounded by the insulator 275 having a barrier property against oxygen and the conductor 242b1 having a property of being less likely to be oxidized. Thus, a semiconductor device in which oxidation of the conductor 242a2 and the conductor 242b2 and wiring delay are inhibited can be manufactured. When tungsten is used for the upper layer of the conductor 242, the conductor 242 can function as a wiring.

Alternatively, for example, a nitride containing tantalum (e.g., tantalum nitride) may be used for the lower layer of the conductor 242, and a nitride containing titanium (e.g., titanium nitride) may be used for the upper layer of the conductor 242. Titanium nitride, which can have higher conductivity than tantalum nitride, enables the upper layer of the conductor 242 to have higher conductivity than the lower layer of the conductor 242. Thus, the contact resistance with the conductor 240 provided in contact with the top surface of the conductor 242 can be reduced, so that a semiconductor device with reduced wiring delay can be manufactured.

Although the lower layer of the conductor 242 and the upper layer of the conductor 242 are formed using different conductive materials in the above-described example, the present invention is not limited thereto.

For the lower layer of the conductor 242 and the upper layer of the conductor 242, conductive materials containing the same constituent elements and having different chemical compositions may be used. In that case, the lower layer of the conductor 242 and the upper layer of the conductor 242 can be formed successively without being exposed to an atmospheric environment. By the formation without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

In addition, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, a nitride containing tantalum with an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, for example, a nitride containing tantalum with an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. Accordingly, a semiconductor device with reduced wiring delay can be manufactured.

Note that the boundary between the upper layer and the lower layer of the conductor 242 is difficult to detect clearly in some cases. In the case where a nitride containing tantalum is used for the conductor 242, the tantalum concentration and the nitrogen concentration detected in each layer may gradually change within each layer or may change continuously (or in a gradation manner) in a region between the upper layer and the lower layer. That is, the atomic ratio of nitrogen to tantalum is higher in the region of the conductor 242 that is closer to the oxide 230. Thus, the atomic ratio of nitrogen to tantalum in a lower region of the conductor 242 is preferably higher than the atomic ratio of nitrogen to tantalum in an upper region of the conductor 242.

Although the transistor 200 having a structure in which the conductor 242 has a stacked-layer structure of two layers is described, the present invention is not limited thereto. For example, the conductor 242 may be provided to have a single-layer structure or a stacked-layer structure of three or more layers. In the case where a component has a stacked-layer structure, layers may be distinguished by ordinal numbers corresponding to the formation order.

The top surface of the conductor 260 is located to be level or substantially level with the uppermost portion of the insulator 254, the uppermost portion of the insulator 253, and the top surface of the insulator 280.

The conductor 260 functions as the first gate electrode of the transistor 200. The conductor 260 preferably includes the conductor 260a and the conductor 260b located over the conductor 260a. For example, the conductor 260a is preferably located to cover the bottom surface and the side surface of the conductor 260b. Although the conductor 260 has a two-layer structure of the conductor 260a and the conductor 260b in FIG. 1B and FIG. 1C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen included in the insulator 280 and the like. As the conductive material having a function of inhibiting diffusion of oxygen, for example, titanium, titanium nitride, tantalum, tantalum nitride, ruthenium, or ruthenium oxide is preferably used.

The conductor 260 is formed to fill the opening 258 that is provided to extend in the channel width direction, and the conductor 260 is also provided to extend in the channel width direction. Thus, in the case where the plurality of transistors 200 are provided, the conductor 260 can also function as a wiring. In this case, the insulator 253 and the insulator 254 are also provided to extend together with the conductor 260.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening 258 formed in the insulator 280 and the like. The formation of the conductor 260 in this manner allows the conductor 260 to be located properly in a region between the conductor 242a and the conductor 242b without alignment.

As illustrated in FIG. 1C, in the channel width direction of the transistor 200, with reference to the bottom surface of the insulator 222, the level of the bottom surface of the conductor 260 in a region where the conductor 260 and the oxide 230b do not overlap with each other is preferably lower than the level of the bottom surface of the oxide 230b. When the conductor 260 functioning as the gate electrode covers the side surface and the top surface of the channel formation region of the oxide 230b with the insulator 253 and the like therebetween, the electric field of the conductor 260 is likely to act on the entire channel formation region of the oxide 230b. Thus, the on-state current of the transistor 200 can be increased, and the frequency characteristics of the transistor 200 can be improved. With reference to the bottom surface of the insulator 222, the difference between the level of the bottom surface of the conductor 260 in a region where the conductor 260 do not overlap with the oxide 230a or the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275, and the opening 258 is formed in a region where the insulator 253, the insulator 254, and the conductor 260 are to be provided. The top surface of the insulator 280 may be planarized.

The insulator 280 functioning as the interlayer film preferably has a low permittivity. When a material with a low permittivity is used for the interlayer film, parasitic capacitance generated between wirings can be reduced. The insulator 280 is preferably provided using a material similar to that for the insulator 216, for example. In particular, silicon oxide and silicon oxynitride, which are thermally stable, are preferable. A material such as silicon oxide, silicon oxynitride, or porous silicon oxide is preferably used, in which case a region including oxygen to be released by heating can be easily formed.

The concentration of impurities such as water and hydrogen in the insulator 280 is preferably reduced. An oxide containing silicon such as silicon oxide, silicon oxynitride, or the like is used as appropriate for the insulator 280, for example.

The insulator 282 is located to be in contact with at least part of each of the top surfaces of the conductor 260, the insulator 253, the insulator 254, and the insulator 280.

The insulator 282 preferably functions as a barrier insulating film that inhibits impurities such as water and hydrogen from diffusing into the insulator 280 from above and preferably has a function of capturing impurities such as hydrogen. The insulator 282 preferably functions as a barrier insulating film that inhibits passage of oxygen. For the insulator 282, an insulator such as a metal oxide having an amorphous structure, e.g., aluminum oxide, may be used. In that case, the insulator 282 includes at least oxygen and aluminum. When the insulator 282, which has a function of capturing impurities such as hydrogen, is provided in contact with the insulator 280, impurities such as hydrogen included in the insulator 280 and the like can be captured. Aluminum oxide having an amorphous structure is particularly preferably used for the insulator 282, in which case hydrogen can sometimes be captured or fixed more effectively. Accordingly, the transistor 200 and the semiconductor device which have favorable characteristics and high reliability can be manufactured.

As the insulator 282, a film of aluminum oxide is preferably formed by a sputtering method, and a film of aluminum oxide is further preferably formed by a pulsed DC sputtering method using an aluminum target in an atmosphere containing an oxygen gas. The use of a pulsed DC sputtering method can achieve more uniform film thickness and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases.

The RF power is higher than or equal to 0 W/cm² and lower than or equal to 1.86 W/cm², for example. In other words, the amount of oxygen to be implanted can be changed to be appropriate for the characteristics of the transistor, with the RF power used at the time of forming the insulator 282. Accordingly, an appropriate amount of oxygen for improving the reliability of the transistor can be implanted. An RF power of 0 W/cm² means that no RF power is applied to the substrate.

The RF frequency is preferably higher than or equal to 10 MHz. The typical frequency is 13.56 MHz. The higher the RF frequency is, the less damage the substrate receives.

Although FIG. 1A to FIG. 1D and the like illustrate a single-layer structure of the insulator 282, the present invention is not limited to this structure, and a stacked-layer structure of two or more layers may be employed. For example, the insulator 282 may have a stacked-layer structure of two layers.

The upper layer and the lower layer of the insulator 282 are preferably formed using the same material by different methods. For example, when a film of aluminum oxide is formed as the insulator 282 by a pulsed DC sputtering method using an aluminum target in an atmosphere containing an oxygen gas, RF power applied to the substrate in the formation of the lower layer of the insulator 282 and RF power applied to the substrate in the formation of the upper layer of the insulator 282 are preferably different from each other, and the RF power applied to the substrate in the formation of the lower layer of the insulator 282 is preferably lower than the RF power applied to the substrate in the formation of the upper layer of the insulator 282. Specifically, the lower layer of the insulator 282 is formed with the RF power applied to the substrate being higher than or equal to 0 W/cm² and lower than or equal to 0.62 W/cm², and the upper layer of the insulator 282 is formed with the RF power applied to the substrate being lower than or equal to 1.86 W/cm². More specifically, the lower layer of the insulator 282 is formed with the RF power applied to the substrate being 0 W/cm², and the upper layer of the insulator 282 is formed with the RF power applied to the substrate being 0.31 W/cm². With this structure, the insulator 282 can have an amorphous structure, and the amount of oxygen supplied to the insulator 280 can be adjusted.

Note that the RF power applied to the substrate in the formation of the lower layer of the insulator 282 may be higher than the RF power applied to the substrate in the formation of the upper layer of the insulator 282. Specifically, the lower layer of the insulator 282 is formed with the RF power applied to the substrate being lower than or equal to 1.86 W/cm², and the upper layer of the insulator 282 is formed with the RF power applied to the substrate being higher than or equal to 0 W/cm² and lower than or equal to 0.62 W/cm². More specifically, the lower layer of the insulator 282 is formed with the RF power applied to the substrate being 1.86 W/cm², and the upper layer of the insulator 282 is formed with the RF power applied to the substrate being 0.62 W/cm². With this structure, the amount of oxygen supplied to the insulator 280 can be increased.

The thickness of the lower layer of the insulator 282 is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With this structure, the lower layer of the insulator 282 can have an amorphous structure regardless of the RF power. When the lower layer of the insulator 282 has an amorphous structure, the upper layer of the insulator 282 is likely to have an amorphous structure, so that the insulator 282 can have an amorphous structure.

Although the lower layer of the insulator 282 and the upper layer of the insulator 282 described above form the stacked-layer structure of the same material, the present invention is not limited thereto. The lower layer of the insulator 282 and the upper layer of the insulator 282 may form a stacked-layer structure of different materials.

The above is the description of the transistor 200.

### [Capacitor 100]

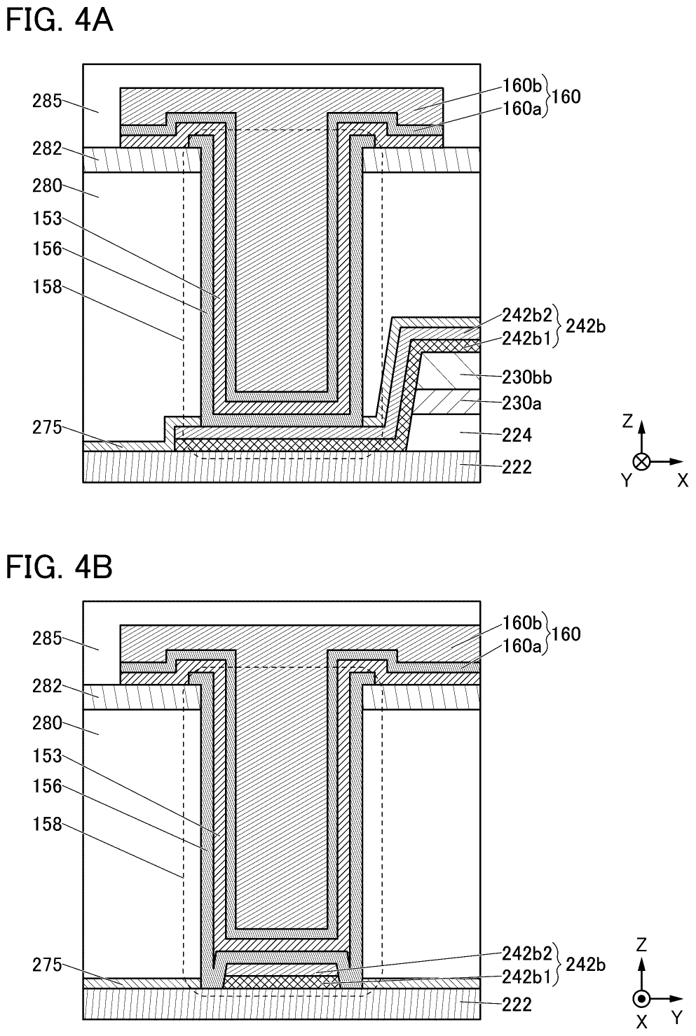

FIG. 4A is an enlarged view illustrating the capacitor 100 in FIG. 1B and the vicinity thereof, and FIG. 4B is an enlarged view illustrating the capacitor 100 in FIG. 1D and the vicinity thereof.

The capacitor 100 includes the conductor 156, the insulator 153, and the conductor 160 (a conductor 160a and a conductor 160b). The conductor 156 functions as one of a pair of electrodes of the capacitor 100 (also referred to as a lower electrode), the conductor 160 functions as the other of the pair of electrodes of the capacitor 100 (also referred to as an upper electrode), and the insulator 153 functions as a dielectric of the capacitor 100.

The conductor 156, the insulator 153, the conductor 160a, and the conductor 160b are at least partly located in the opening 158 provided in the insulator 275, the insulator 280, and the insulator 282. The conductor 156 is provided over the conductor 242b, the insulator 153 is provided over the conductor 156, the conductor 160a is provided over the insulator 153, and the conductor 160b is provided over the conductor 160a.

The conductor 156 is located along the opening 158 formed in the insulator 275, the insulator 280, and the insulator 282. The level of part of the top surface of the conductor 156 is preferably higher than the level of the top surface of the insulator 282. The top surface of the conductor 242b is in contact with the bottom surface of the conductor 156. The conductor 156 is preferably formed by a film formation method that enables favorable coverage, such as an ALD method or a CVD method, and a conductor that can be used as the conductor 205, the conductor 260, or the conductor 242 may be used. When the same conductive material as the conductor 242b is used for the conductor 156, for example, the contact resistance between the conductor 156 and the conductor 242b can be reduced. A film of titanium nitride or tantalum nitride formed by an ALD method can be used for the conductor 156, for example.

The insulator 153 is located to cover the conductor 156 and part of the insulator 282. For the insulator 153, a high-permittivity (high-k) material (a material with a high relative permittivity) is preferably used. The insulator 153 is preferably formed by a film formation method that enables favorable coverage, such as an ALD method or a CVD method.

As an insulator of a high-permittivity (high-k) material, an oxide, an oxynitride, a nitride oxide, or a nitride containing one or more metal elements selected from aluminum, hafnium, zirconium, gallium, and the like can be used. The above-described oxide, oxynitride, nitride oxide, and nitride may contain silicon. Insulating layers each formed of any of the above-described materials can be stacked to be used.

As the insulator of the high-permittivity (high-k) material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. The use of such a high-k material allows the insulator 153 to be thick enough to inhibit a leakage current and a sufficiently high capacitance of the capacitor 100 to be ensured.

It is preferable to use stacked insulating layers each formed of any of the above-described materials. A stacked-layer structure using a high-permittivity (high-k) material and a material having higher dielectric strength than the high-permittivity (high-k) material is preferably used. As the insulator 153, an insulating film in which zirconium oxide, aluminum oxide, and zirconium oxide are stacked in this order can be used, for example. An insulating film in which zirconium oxide, aluminum oxide, zirconium oxide, and aluminum oxide are stacked in this order can be used, for example. An insulating film in which hafnium zirconium oxide, aluminum oxide, hafnium zirconium oxide, and aluminum oxide are stacked in this order can be used, for example. The stacking of an insulator having relatively high dielectric strength, such as aluminum oxide, can increase the dielectric strength and inhibit electrostatic breakdown of the capacitor 100.

The conductor 160 is located to fill the opening 158 formed in the insulator 275, the insulator 280, and the insulator 282. The conductor 160 is preferably formed by an ALD method, a CVD method, or the like, and a conductor that can be used as the conductor 205 or the conductor 260 may be used. For example, a film of titanium nitride formed by an ALD method can be used as the conductor 160a, and a film of tungsten formed by a CVD method can be used as the conductor 160b. Note that in the case where the adhesion of tungsten to the insulator 153 is sufficiently high, a single-layer film of tungsten formed by a CVD method may be used as the conductor 160.

The opening 158 is provided to reach the conductor 242b. In other words, the opening 158 includes a region overlapping with the conductor 242b. The conductor 242b is the other of the source electrode and the drain electrode of the transistor 200 and is in contact with the bottom surface of the conductor 156 provided in the opening 158 to electrically connect the transistor 200 and the capacitor 100 to each other.

In the plan view, the distance between the opening 158 and the oxide 230 is preferably short. Such a structure can reduce the footprint of the memory cell including the capacitor 100 and the transistor 200. In the plan view, the shape of the opening 158 may be a quadrangular shape, a polygonal shape other than a quadrangular shape, a polygonal shape with rounded corners, or a circular shape including an elliptical shape.

As illustrated in FIG. 4A and FIG. 4B, the conductor 156 is provided in contact with the bottom surface and the inner wall of the opening 158. Thus, the conductor 156 is in contact with the side surfaces of the insulator 275, the insulator 280, and the insulator 282, the side surface of the conductor 242b1, the side surface and the top surface of the conductor 242b2, and the top surface of the insulator 222. The insulator 153 is provided in contact with the top surface of the conductor 156, the conductor 160a is provided in contact with the top surface of the insulator 153, and the conductor 160b is provided in contact with the top surface of the conductor 160a.

When the capacitor 100 has the above structure, it is possible to form the capacitor 100 in which the conductor 156 and the conductor 160 are located to face each other with the insulator 153 therebetween on the bottom surface and the side surface of the opening 158, as illustrated in FIG. 4A and FIG. 4B. Thus, the larger the depth of the opening 158 (which can also be referred to as the thickness of the insulator 280) is, the higher the capacitance of the capacitor 100 can be. Increasing the capacitance per unit area of the capacitor 100 in this manner can make the reading operation of the storage device stable.

As illustrated in FIG. 4A, part of the conductor 156, part of the insulator 153, and part of the conductor 160 are provided to be exposed from the opening 158. In other words, part of the conductor 156, part of the insulator 153, and part of the conductor 160 are formed above the top surface of the conductor 260 or the top surface of the insulator 282.

Part of the conductor 156 and part of the insulator 153 are in contact with the top surface of the insulator 282. That is, a side end portion of the conductor 156 is covered with the insulator 153. Furthermore, the conductor 160 preferably includes a region overlapping with the insulator 282 with the insulator 153 therebetween. Here, as illustrated in FIG. 4A, a side end portion of the conductor 160 and a side end portion of the insulator 153 are substantially aligned with each other. With such a structure, the conductor 160 and the conductor 156 can be separated by the insulator 153; thus, a short circuit between the conductor 160 and the conductor 156 can be inhibited.

A portion of the conductor 160 above the insulator 282 may be extended and formed in the form of a wiring. For example, as illustrated in FIG. 1D, the conductor 160 can be provided to extend in the channel width direction of the transistor 200. Thus, in the case where the plurality of transistors 200 and a plurality of the capacitors 100 are provided, the conductor 160 can also function as a wiring. In this case, the insulator 153 can also be provided to extend together with the conductor 160.

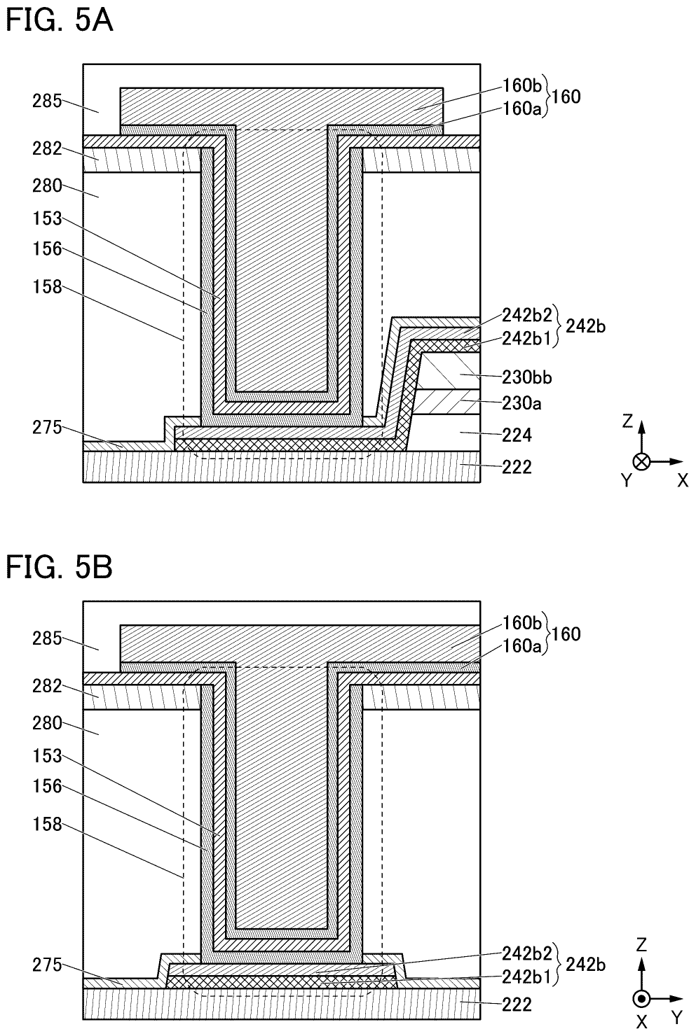

The capacitor 100 may have a structure as illustrated in FIG. 5A and FIG. 5B. Here, FIG. 5A is an enlarged view corresponding to the capacitor 100 in FIG. 1B, and FIG. 5B is an enlarged view corresponding to the capacitor 100 in FIG. 1D.

As illustrated in FIG. 5A and FIG. 5B, the uppermost portion of the conductor 156 of the capacitor 100 may be substantially level with the top surface of the insulator 282.

As illustrated in FIG. 5A and FIG. 5B, part of the insulator 153 may be exposed from the conductor 160 in the capacitor 100.

As illustrated in FIG. 5B, part of the conductor 242b may be exposed from the conductor 156 of the capacitor 100 in a cross-sectional view in the channel width direction.

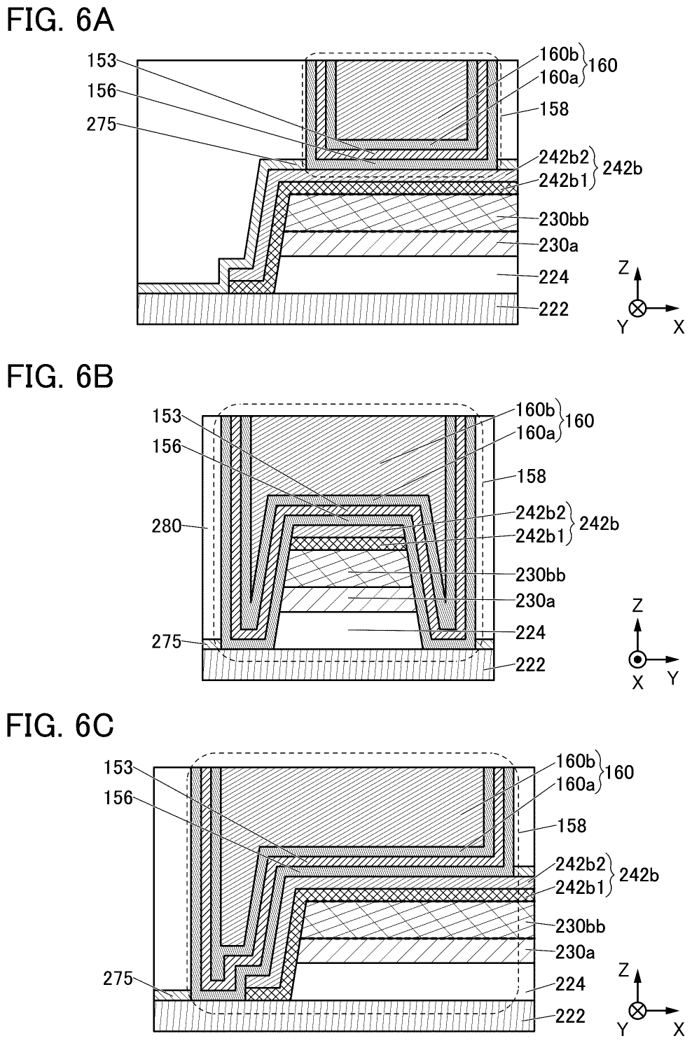

The capacitor 100 may have a structure illustrated in FIG. 6A and FIG. 6B. Here, FIG. 6A is an enlarged view corresponding to the capacitor 100 in FIG. 1B, and FIG. 6B is an enlarged view corresponding to the capacitor 100 in FIG. 1D.

As illustrated in FIG. 6A, the insulator 224, the oxide 230a, and the oxide 230b may be formed under the conductor 242b in the opening 158 in the capacitor 100. In that case, as illustrated in FIG. 6B, the conductor 156 is preferably provided in contact with the side surface of the insulator 224, the side surface of the oxide 230a, the side surface of the oxide 230b, and the side surface of the conductor 242. This allows the capacitor 100 to be formed along the side surface of the insulator 224, the side surface of the oxide 230a, the side surface of the oxide 230b, and the side surface of the conductor 242; thus, the capacitance of the capacitor 100 can be increased.

Alternatively, the capacitor 100 may have a shape illustrated in FIG. 6C, for example. Specifically, part of the opening 158 overlaps with only the conductor 242b as in the structure illustrated in FIG. 5A, and another part of the opening 158 overlaps with the conductor 242b, the oxide 230b, the oxide 230a, and the insulator 224 as in the structure illustrated in FIG. 6A.

Although FIG. 4A to FIG. 6C each illustrate a structure in which the sidewall of the opening 158 is substantially perpendicular to the top surface of the insulator 222, the present invention is not limited thereto. The sidewall of the opening 158 may have a tapered shape. When the sidewall of the opening 158 has a tapered shape, the coverage with the insulator 153 and the like can be improved in a later step, so that defects such as a void can be reduced.

The above is the description of the capacitor 100.

The conductor 240 is provided in contact with the inner wall of the opening 206 formed in the insulator 285, the insulator 282, the insulator 280, the insulator 275, the conductor 242a, the insulator 222, the insulator 216, the insulator 214, and the insulator 212. The conductor 240 includes a region in contact with the top surface of the conductor 209.

The conductor 240 functions as a plug or a wiring for electrically connecting the transistor 200 to a circuit element such as a switch, a transistor, a capacitor, an inductor, a resistor, or a diode, a wiring, an electrode, or a terminal.

The conductor 240 preferably has a stacked-layer structure of the conductor 240a and the conductor 240b. For example, as illustrated in FIG. 1B, the conductor 240 can have a structure in which the conductor 240a is provided in contact with the inner wall of the above opening and the conductor 240b is provided inside the conductor 240a. That is, the conductor 240a is located in the vicinity of the insulator 285, the insulator 282, the insulator 280, the insulator 275, the conductor 242a, the insulator 222, the insulator 216, the insulator 214, and the insulator 212.

Here, the conductor 240a is preferably formed by a film formation method that enables favorable coverage, such as an ALD method. When the conductor 240a is formed in this manner, the rough shape of the conductor 240a is substantially the same as the shape formed by the inner wall of the opening 206. The conductor 240a is illustrated to have a uniform thickness in FIG. 1B and the like; however, in a portion shaded by the conductor 242a, for example, the conductor 240a may have a small thickness or is not necessarily formed.

A conductive material having a function of inhibiting passage of impurities such as water and hydrogen is preferably used for the conductor 240a. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen included in a layer above the insulator 282 can be inhibited from entering the oxide 230 through the conductor 240.

The conductor 240 also functions as a wiring and thus is preferably formed using a conductor having high conductivity. For example, a conductive material containing tungsten, copper, or aluminum as its main component can be used for the conductor 240b.

For example, it is preferable to use titanium nitride for the conductor 240a and tungsten for the conductor 240b. In that case, the conductor 240a is a conductor that contains titanium and nitrogen, and the conductor 240b is a conductor that contains tungsten.

Although the transistor 200 having a structure in which the conductor 240 is a stack of the conductor 240a and the conductor 240b is described, the present invention is not limited thereto. For example, the conductor 240 may be provided to have a single-layer structure or a stacked-layer structure of three or more layers. In the case where a component has a stacked-layer structure, layers may be distinguished by ordinal numbers corresponding to the formation order. Although not illustrated in FIG. 1B, the level of the top surface of the conductor 240 is higher than the level of the top surface of the insulator 285 in some cases.

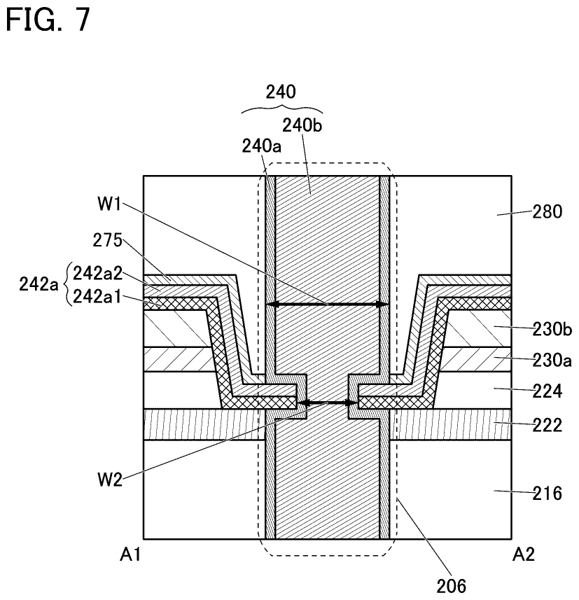

FIG. 7 is an enlarged view of a region where the conductor 240 and the conductor 242a are in contact with each other and the vicinity of the region. In the A1-A2 direction, the conductor 240 includes a region with a width W1 and a region with a width W2 as illustrated in FIG. 7. The width W1 corresponds to, for example, the distance from the interface between the insulator 280 and the conductor 240a on the transistor 200a side to the interface between the insulator 280 and the conductor 240a on the transistor 200b side. The width W2 corresponds to the width of the opening included in the conductor 242a. In the case where the conductor 242a on the transistor 200a side and the conductor 242a on the transistor 200b side are provided to be separated from each other as described above, the width W2 corresponds to the distance from the conductor 242a on the transistor 200a side to the conductor 242a on the transistor 200b side.

As illustrated in FIG. 7, the width W1 is preferably larger than the width W2. In this structure, the conductor 240 is in contact with, at least, part of the top surface and part of the side surface of the conductor 242a. Accordingly, the area of the region where the conductor 240 and the conductor 242a are in contact with each other can be increased. Here, as illustrated in FIG. 7, the side surface of the conductor 242a protrudes from the side surfaces of the insulator 280 and the insulator 275 in the opening 206. Note that in this specification and the like, the contact between the conductor 240 and the conductor 242a is referred to as a top side contact in some cases.

As illustrated in FIG. 7, the conductor 240 may be in contact with part of the bottom surface of the conductor 242a. With this structure, the area of the region where the conductor 240 and the conductor 242a are in contact with each other can be further increased. Here, as illustrated in FIG. 7, the side surface of the conductor 242a protrudes from the side surfaces of the insulator 222 and the insulator 216 in the opening 206.

When the contact area between the conductor 240 and the conductor 242 is increased as described above, the contact resistance can be reduced. As a result, the storage device of the present invention can have increased operation speed and reduced power consumption.

The conductor 209 functions as part of a circuit element such as a switch, a transistor, a capacitor, an inductor, a resistor, or a diode, a wiring, an electrode, or a terminal.

The insulator 210 functions as an interlayer film. As the insulator 210, an insulator that can be used as the insulator 214, the insulator 216, or the like described above may be used.

### <Component Material of Semiconductor Device>

Component materials that can be used for the semiconductor device are described below.

### <<Substrate>>

As the substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative permittivity is used for the insulator functioning as an interlayer film, parasitic capacitance generated between wirings can be reduced. Thus, a material is preferably selected depending on the function of the insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>>

The oxide 230 is preferably formed using a metal oxide (an oxide semiconductor) functioning as a semiconductor. A metal oxide that can be used for the oxide 230 according to the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one or more selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, or tin. Other elements that can be used as the element M include boron, titanium, iron, nickel, germanium, zirconium, molybdenum, lanthanum, cerium, neodymium, hafnium, tantalum, tungsten, magnesium, and cobalt. Note that two or more of the above elements may be used in combination as the element M in some cases. In particular, the element M is preferably one or more selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also generally termed as a metal oxide in some cases. A metal oxide containing nitrogen may be referred to as a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of an In—Ga—Zn oxide film having a crystal structure has a bilaterally asymmetrical shape. The bilaterally asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

The crystal structure of a film or a substrate can be evaluated with a diffraction pattern observed by a nanobeam electron diffraction (NBED) method (such a pattern is also referred to as a nanobeam electron diffraction pattern). For example, a halo pattern is observed in the diffraction pattern of a quartz glass substrate, which indicates that quartz glass is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter less than 10 nm). In the case where the crystal region is formed of one minute crystal, the maximum diameter of the crystal region is less than nm. In the case where the crystal region is formed of a large number of minute crystals, the maximum diameter of the crystal region may be approximately several tens of nanometers.

In the case of In—Ga—Zn oxide, the CAAC-OS tends to have a layered crystal structure (also referred to as a layered structure) in which a layer including indium (In) and oxygen (hereinafter, an In layer) and a layer including gallium (Ga), zinc (Zn), and oxygen (hereinafter, a (Ga,Zn) layer) are stacked. Note that indium and gallium can be replaced with each other. Therefore, indium may be included in the (Ga,Zn) layer. In addition, gallium may be included in the In layer. Note that zinc may be included in the In layer. The layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably included to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be reduced by entry of impurities, formation of defects, or the like, the CAAC-OS can also be regarded as an oxide semiconductor that has small amounts of impurities and defects (e.g., oxygen vacancies). Thus, the physical properties of an oxide semiconductor including the CAAC-OS are stable. Therefore, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the transistor including a metal oxide in its channel formation region (referred to as an OS transistor in some cases) can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region including indium oxide, indium zinc oxide, or the like as its main component. The second region is a region including gallium oxide, gallium zinc oxide, or the like as its main component. That is, the first region can be rephrased as a region including In as its main component. The second region can be rephrased as a region including Ga as its main component.

Note that a clear boundary between the first region and the second region cannot be observed in some cases.

In a material composition of a CAC-OS in In—Ga—Zn oxide that includes In, Ga, Zn, and O, there are regions including Ga as a main component in part of the CAC-OS and regions including In as a main component in another part of the CAC-OS. These regions are randomly present to form a mosaic pattern. Thus, it is suggested that the CAC-OS has a structure where metal elements are unevenly distributed.

The CAC-OS can be formed by a sputtering method under a condition where a substrate is not heated, for example. In the case of forming the CAC-OS by a sputtering method, one or more selected from an inert gas (typically, argon), an oxygen gas, and a nitrogen gas are used as a film formation gas. The proportion of the flow rate of an oxygen gas in the total flow rate of the film formation gas during film formation is preferably as low as possible. For example, the proportion of the flow rate of an oxygen gas in the total flow rate of the film formation gas during film formation is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region including In as its main component (the first region) and the region including Ga as its main component (the second region) are unevenly distributed and mixed.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, a leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (μ), and favorable switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor with high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, nitrogen, an alkali metal, an alkaline earth metal, iron, nickel, and silicon. Note that an impurity in an oxide semiconductor refers to, for example, an element other than the main components of the oxide semiconductor. For example, an element with a concentration lower than 0.1 atomic % can be regarded as an impurity.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the oxide semiconductor is set lower than or equal to 2×10¹⁸ atoms/cm³, preferably lower than or equal to 2×10¹⁷ atoms/cm³

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, the transistor can have stable electrical characteristics.

### <<Other Semiconductor Materials>>

A semiconductor material that can be used for the oxide 230 is not limited to the above metal oxides. A semiconductor material that has a band gap (a semiconductor material that is not a zero-gap semiconductor) may be used for the oxide 230. For example, a single element semiconductor such as silicon, a compound semiconductor such as gallium arsenide, or a layered substance functioning as a semiconductor (also referred to as an atomic layer substance, a two-dimensional material, or the like) is preferably used as a semiconductor material. In particular, a layered substance functioning as a semiconductor is favorably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substance include graphene, silicene, and chalcogenide. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For the oxide 230, transition metal chalcogenide functioning as a semiconductor is preferably used, for example. Specific examples of the transition metal chalcogenide that can be used for the oxide 230 include molybdenum sulfide (typically MoS₂), molybdenum selenide (typically MoSe₂), molybdenum telluride (typically MoTez), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). When the transition metal chalcogenide is used for the oxide 230, a semiconductor device with a high on-state current can be provided.

### <Example of Method for Manufacturing Semiconductor Device>

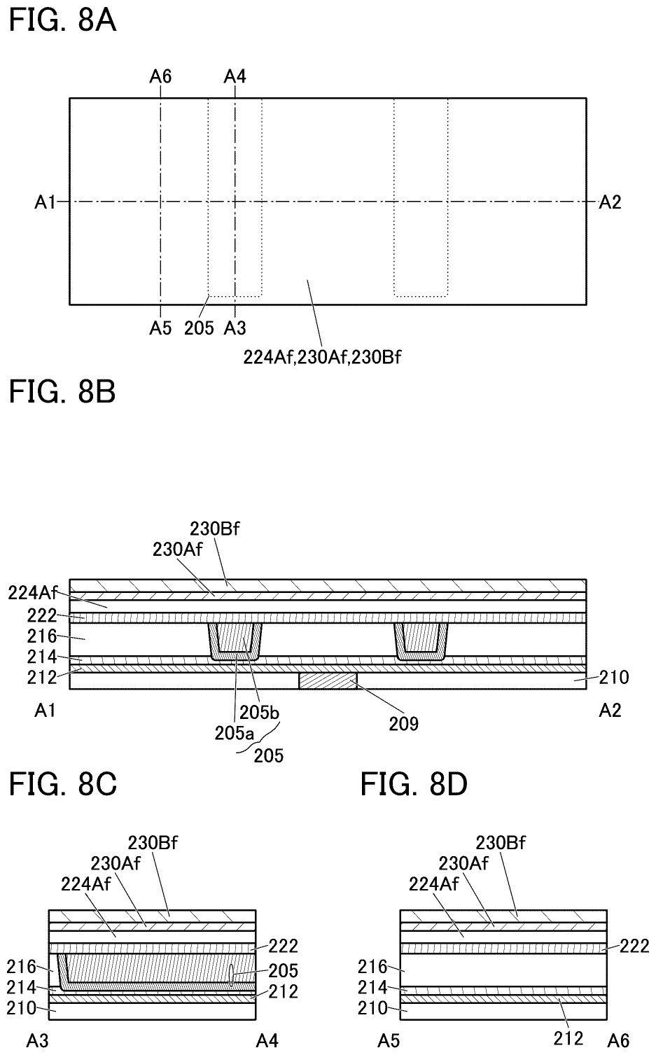

Next, a method for manufacturing the semiconductor device of one embodiment of the present invention illustrated in FIG. 1A to FIG. 1D is described with reference to FIG. 8A to FIG. 25D.

Note that A of each drawing is a top view. Moreover, B of each drawing is a cross-sectional view corresponding to a portion indicated by the dashed-dotted line A1-A2 in A of each drawing, and is also a cross-sectional view of the transistor 200 in the channel length direction. Furthermore, C of each drawing is a cross-sectional view corresponding to a portion indicated by the dashed-dotted line A3-A4 in A of each drawing, and is also a cross-sectional view of the transistor 200 in the channel width direction. Furthermore, D of each drawing is a cross-sectional view of a portion indicated by the dashed-dotted line A5-A6 in A of each drawing. Note that for clarity of the drawing, some components are omitted in the top view of A of each drawing.

Hereinafter, a film of an insulating material for forming an insulator, a film of a conductive material for forming a conductor, or a film of a semiconductor material for forming a semiconductor can be formed by a sputtering method, a CVD method, an MBE method, a PLD method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving charge from plasma. In that case, accumulated charge may break the wiring, the electrode, the element, or the like included in the semiconductor device. In contrast, such plasma damage is not caused in the case of a thermal CVD method, which does use plasma, and thus the yield of the semiconductor device can be increased. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gases. For example, by a CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a freely selected composition can be formed by concurrently introducing different kinds of precursors. In the case where different kinds of precursors are introduced, a film with a freely selected composition can be formed by controlling the number of cycles for each of the precursors.

First, a substrate (not illustrated) is prepared, and the insulator 210 and the conductor 209 are formed over the substrate (see FIG. 8A to FIG. 8D).

Next, the insulator 212 is formed over the insulator 210 and the conductor 209 (see FIG. 8A to FIG. 8D). The insulator 212 is preferably formed by a sputtering method. By using a sputtering method that does not need to use a molecule containing hydrogen as a film formation gas, the hydrogen concentration in the insulator 212 can be reduced. Without limitation to a sputtering method, the insulator 212 may be formed by a CVD method, an MBE method, a PLD method, an ALD method, or the like as appropriate.

In this embodiment, as the insulator 212, a film of silicon nitride is formed by a pulsed DC sputtering method using a silicon target in an atmosphere containing a nitrogen gas. The use of a pulsed DC sputtering method can inhibit generation of particles due to arcing on the target surface, achieving more uniform film thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator that is less permeable to impurities such as water and hydrogen, e.g., silicon nitride, can inhibit diffusion of impurities such as water and hydrogen included in a layer below the insulator 212. When an insulator that is less permeable to copper, such as silicon nitride, is used for the insulator 212, even in the case where a metal that is likely to diffuse, such as copper, is used for a conductor (not illustrated) in a layer below the insulator 212, upward diffusion of the metal through the insulator 212 can be inhibited.

Next, the insulator 214 is formed over the insulator 212 (see FIG. 8A to FIG. 8D). The insulator 214 is preferably formed by a sputtering method. By using a sputtering method that does not need to use a molecule containing hydrogen as a film formation gas, the hydrogen concentration in the insulator 214 can be reduced. Without limitation to a sputtering method, the insulator 214 may be formed by a CVD method, an MBE method, a PLD method, an ALD method, or the like as appropriate.

In this embodiment, as the insulator 214, a film of aluminum oxide is formed by a pulsed DC sputtering method using an aluminum target in an atmosphere containing an oxygen gas. The use of a pulsed DC sputtering method can achieve more uniform film thickness and improve the sputtering rate and film quality. Here, RF power may be applied to the substrate. The amount of oxygen implanted into a layer below the insulator 214 can be controlled depending on the amount of the RF power applied to the substrate. The RF power is higher than or equal to 0 W/cm² and lower than or equal to 1.86 W/cm². In other words, the amount of oxygen to be implanted can be changed to be appropriate for the characteristics of the transistor, with the RF power used at the time of forming the insulator 214. Accordingly, an appropriate amount of oxygen for improving the reliability of the transistor can be implanted. The RF frequency is preferably higher than or equal to 10 MHz. The typical frequency is 13.56 MHz. The higher the RF frequency is, the less damage the substrate receives.

A metal oxide having an amorphous structure and a function of capturing and fixing hydrogen well, such as aluminum oxide, is preferably used for the insulator 214. In this case, the insulator 214 captures or fixes hydrogen included in the insulator 216 and the like and prevents the hydrogen from diffusing into the oxide 230. Aluminum oxide having an amorphous structure or amorphous aluminum oxide is particularly preferably used for the insulator 214, in which case hydrogen can sometimes be captured or fixed more effectively. Accordingly, the transistor 200 and the semiconductor device which have favorable characteristics and high reliability can be manufactured.

Next, the insulator 216 is formed over the insulator 214. The insulator 216 is preferably formed by a sputtering method. By using a sputtering method that does not need to use a molecule containing hydrogen as a film formation gas, the hydrogen concentration in the insulator 216 can be reduced. Without limitation to a sputtering method, the insulator 216 may be formed by a CVD method, an MBE method, a PLD method, an ALD method, or the like as appropriate.

In this embodiment, as the insulator 216, a film of silicon oxide is formed by a pulsed DC sputtering method using a silicon target in an atmosphere containing an oxygen gas. The use of a pulsed DC sputtering method can achieve more uniform film thickness and improve the sputtering rate and film quality.

The insulator 212, the insulator 214, and the insulator 216 are preferably successively formed without exposure to the air. For example, a multi-chamber film formation apparatus is used. As a result, the amounts of hydrogen in the formed insulator 212, the insulator 214, and the insulator 216 can be reduced, and furthermore, entry of hydrogen into the films in intervals between film formation steps can be inhibited.

Then, an opening reaching the insulator 214 is formed in the insulator 216. Examples of the opening include a groove and a slit. A region where an opening is formed is referred to as an opening portion in some cases. Wet etching may be used for the formation of the opening; however, dry etching is preferably used for microfabrication. As the insulator 214, it is preferable to select an insulator that functions as an etching stopper film in forming the groove by etching the insulator 216. For example, in the case where silicon oxide or silicon oxynitride is used for the insulator 216 in which the groove is to be formed, silicon nitride, aluminum oxide, or hafnium oxide is preferably used for the insulator 214.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

After the formation of the opening, a conductive film to be the conductor 205a is formed. The conductive film to be the conductor 205a desirably includes a conductor having a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used. The conductive film to be the conductor 205a can be formed by a sputtering method, a CVD method, an MBE method, a PLD method, an ALD method, or the like.

In this embodiment, a film of titanium nitride is formed as the conductive film to be the conductor 205a. When such a metal nitride is used for a layer below the conductor 205b, oxidation of the conductor 205b by the insulator 216 or the like can be inhibited. Furthermore, even when a metal that is likely to diffuse, such as copper, is used for the conductor 205b, the metal can be prevented from diffusing to the outside through the conductor 205a.

Next, a conductive film to be the conductor 205b is formed. Tantalum, tungsten, titanium, molybdenum, aluminum, copper, a molybdenum-tungsten alloy, or the like can be used for the conductive film to be the conductor 205b. The conductive film can be formed by a plating method, a sputtering method, a CVD method, an MBE method, a PLD method, an ALD method, or the like. In this embodiment, a film of tungsten is formed as the conductive film to be the conductor 205b.

Next, by performing CMP treatment, the conductive film to be the conductor 205a and the conductive film to be the conductor 205b are partly removed to expose the insulator 216 (see FIG. 8A to FIG. 8D). As a result, the conductor 205a and the conductor 205b remain only in the opening portion. Note that the insulator 216 is partly removed by the CMP treatment in some cases.

Next, the insulator 222 is formed over the insulator 216 and the conductor 205 (see FIG. 8A to FIG. 8D). A film of an insulator containing an oxide of one or both of aluminum and hafnium is preferably formed as the insulator 222. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium zirconium oxide is preferably used. The insulator containing an oxide of one or both of aluminum and hafnium has a barrier property against oxygen, hydrogen, and water. When the insulator 222 has a barrier property against hydrogen and water, hydrogen and water included in components provided around the transistor 200 are inhibited from diffusing into the transistor 200 through the insulator 222, and generation of oxygen vacancies in the oxide 230 can be inhibited.

The insulator 222 can be formed by a sputtering method, a CVD method, an MBE method, a PLD method, an ALD method, or the like. In this embodiment, as the insulator 222, a film of hafnium oxide is formed by an ALD method. It is particularly preferable to use a method for forming hafnium oxide with a reduced hydrogen concentration, which is one embodiment of the present invention.

Subsequently, heat treatment is preferably performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment performed using a highly purified gas can prevent entry of moisture or the like into the insulator 222 and the like as much as possible.

In this embodiment, as the heat treatment, treatment is performed at 400° C. for one hour with a flow rate ratio of a nitrogen gas to an oxygen gas being 4:1 after the formation of the insulator 222. Through the heat treatment, impurities such as water and hydrogen included in the insulator 222 can be removed, for example. In the case where an oxide containing hafnium is used for the insulator 222, the insulator 222 is partly crystallized by the heat treatment in some cases. The heat treatment can also be performed after the formation of the insulator 224, for example.

Next, an insulating film 224Af is formed over the insulator 222 (see FIG. 8A to FIG. 8D). The insulating film 224Af can be formed by a sputtering method, a CVD method, an MBE method, a PLD method, an ALD method, or the like. In this embodiment, for the insulating film 224Af, a film of silicon oxide is formed by a sputtering method. By using a sputtering method that does not need to use a molecule containing hydrogen as a film formation gas, the hydrogen concentration in the insulating film 224Af can be reduced. The hydrogen concentration in the insulating film 224Af is preferably reduced in this manner because the insulating film 224Af is in contact with the oxide 230a in a later step.

Next, an oxide film 230Af and an oxide film 230Bf are formed in this order over the insulating film 224Af (see FIG. 8A to FIG. 8D). Note that the oxide film 230Af and the oxide film 230Bf are preferably formed successively without being exposed to an atmospheric environment. By the film formation without exposure to the atmosphere, impurities or moisture from the atmospheric environment can be prevented from being attached onto the oxide film 230Af and the oxide film 230Bf, so that the vicinity of the interface between the oxide film 230Af and the oxide film 230Bf can be kept clean.

The oxide film 230Af and the oxide film 230Bf can be formed by a sputtering method, a CVD method, an MBE method, a PLD method, an ALD method, or the like. In this embodiment, the oxide film 230Af and the oxide film 230Bf are formed by a sputtering method.

For example, in the case where the oxide film 230Af and the oxide film 230Bf are formed by a sputtering method, oxygen or a mixed gas of oxygen and a noble gas is used as a sputtering gas. Increasing the proportion of oxygen contained in the sputtering gas can increase the amount of excess oxygen in the formed oxide films. In the case where the oxide films are formed by a sputtering method, the above In-M-Zn oxide target or the like can be used.

In particular, when the oxide film 230Af is formed, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the oxide film 230Bf is formed by a sputtering method and the proportion of oxygen contained in the sputtering gas for film formation is higher than 30% and lower than or equal to 100%, preferably higher than or equal to 70% and lower than or equal to 100%, an oxygen-excess oxide semiconductor is formed. A transistor including an oxygen-excess oxide semiconductor in its channel formation region can have relatively high reliability. Note that one embodiment of the present invention is not limited thereto. In the case where the oxide film 230Bf is formed by a sputtering method and the proportion of oxygen contained in the sputtering gas for film formation is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in its channel formation region can have relatively high field-effect mobility. Furthermore, when the film formation is performed while the substrate is being heated, the crystallinity of the oxide film can be improved.

In this embodiment, the oxide film 230Af is formed by a sputtering method using an oxide target with In:Ga:Zn=1:3:4 [atomic ratio]. In addition, the oxide film 230Bf is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 230a and the oxide 230b by selecting the film formation conditions and the atomic ratios as appropriate.

Note that the insulating film 224Af, the oxide film 230Af, and the oxide film 230Bf are preferably formed by a sputtering method without exposure to the air. For example, a multi-chamber film formation apparatus is used. As a result, entry of hydrogen into the insulating film 224Af, the oxide film 230Af, and the oxide film 230Bf in intervals between film formation steps can be inhibited.

The oxide film 230Af and the oxide film 230Bf may be formed by an ALD method. When an ALD method is employed for the formation of the oxide film 230Af and the oxide film 230Bf, a film with a uniform thickness can be formed even in a groove or an opening portion having a high aspect ratio. When a PEALD method is employed, the oxide film 230Af and the oxide film 230Bf can be formed at a lower temperature than when a thermal ALD method is employed.

Next, heat treatment is preferably performed. The heat treatment is performed in a temperature range where the oxide film 230Af and the oxide film 230Bf do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at higher than or equal to 10 ppm, higher than or equal to 1%, or higher than or equal to 10% in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment performed using a highly purified gas can prevent entry of moisture or the like into the oxide film 230Af, the oxide film 230Bf, and the like as much as possible.

In this embodiment, as the heat treatment, treatment is performed at 400° C. for one hour with a flow rate ratio of a nitrogen gas to an oxygen gas being 4:1. Through such heat treatment using the oxygen gas, impurities such as carbon, water, and hydrogen in the oxide film 230Af and the oxide film 230Bf can be reduced. The reduction of impurities in the films in this manner improves the crystallinity of the oxide film 230Bf, thereby offering a dense structure with a higher density. Thus, crystalline regions in the oxide film 230Af and the oxide film 230Bf are expanded, so that in-plane variations of the crystalline regions in the oxide film 230Af and the oxide film 230Bf can be reduced. Accordingly, an in-plane variation of electrical characteristics of the transistor 200 can be reduced.

By performing the heat treatment, hydrogen in the insulator 216, the insulating film 224Af, the oxide film 230Af, and the oxide film 230Bf moves into the insulator 222 and is absorbed by the insulator 222. In other words, hydrogen in the insulator 216, the insulating film 224Af, the oxide film 230Af, and the oxide film 230Bf diffuses into the insulator 222. Accordingly, the hydrogen concentration of the insulator 222 increases, while the hydrogen concentrations in the insulator 216, the insulating film 224Af, the oxide film 230Af, and the oxide film 230Bf decrease.

In particular, the insulating film 224Af functions as the second gate insulator of the transistor 200, and the oxide film 230Af and the oxide film 230Bf function as the channel formation region of the transistor 200. Thus, the transistor 200 preferably includes the insulating film 224Af, the oxide film 230Af, and the oxide film 230Bf with reduced hydrogen concentrations to have favorable reliability.

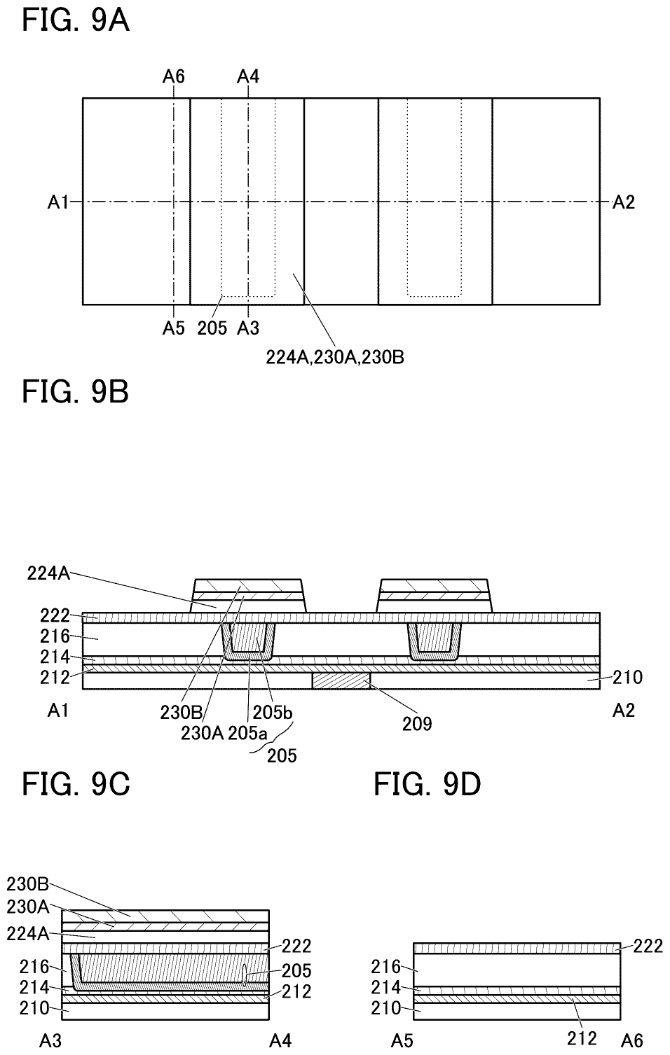

Next, the insulating film 224Af, the oxide film 230Af, and the oxide film 230Bf are processed into band shapes by a lithography method to form an insulating layer 224A, an oxide layer 230A, and an oxide layer 230B (see FIG. 9A to FIG. 9D). Here, the insulating layer 224A, the oxide layer 230A, and the oxide layer 230B are formed to extend in a direction parallel to the dashed-dotted line A3-A4 (the channel width direction of the transistor 200 or the Y direction shown in FIG. 1A). The insulating layer 224A, the oxide layer 230A, and the oxide layer 230B are formed to at least partly overlap with the conductor 205. A dry etching method or a wet etching method can be used for the processing. Processing by a dry etching method is suitable for microfabrication. The insulating film 224Af, the oxide film 230Af, and the oxide film 230Bf may be processed under different conditions.

Note that in a lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the oxide film 230Bf, a resist mask is formed thereover, and then the hard mask material is etched. The etching of the oxide film 230Bf and the like may be performed after removing the resist mask or with the resist mask remaining. In the latter case, the resist mask sometimes disappears during the etching. The hard mask may be removed by etching after the etching of the oxide film 230Bf and the like. Meanwhile, the hard mask is not necessarily removed when the hard mask material does not affect later steps or can be utilized in later steps.

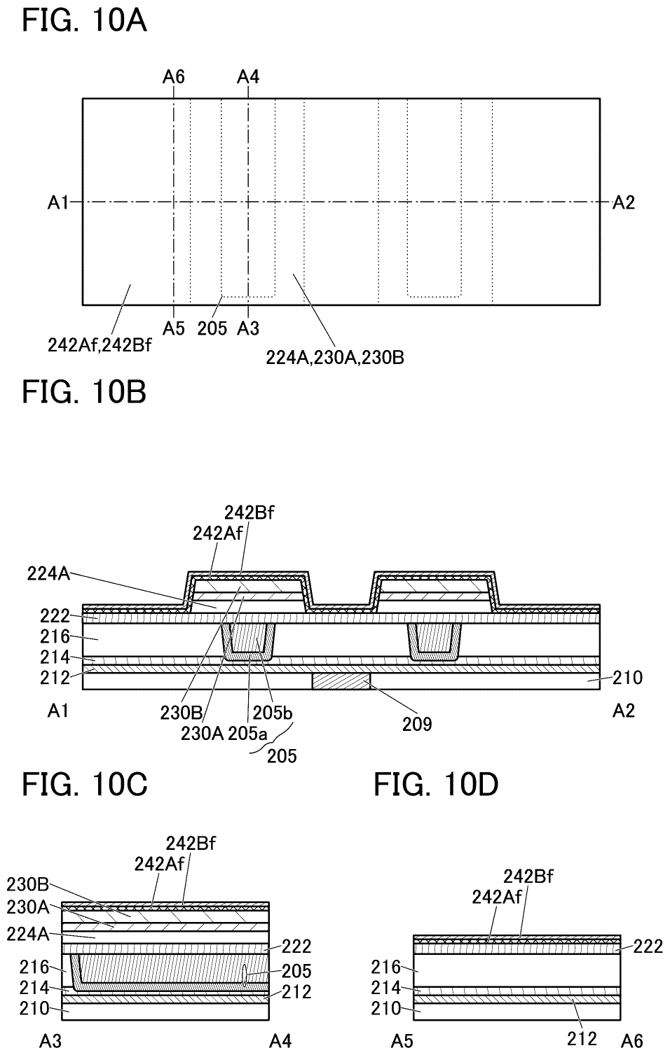

Next, a conductive film 242Af and a conductive film 242Bf are formed in this order over the insulator 222 and the oxide layer 230B (see FIG. 10A to FIG. 10D). The conductive film 242Af and the conductive film 242Bf can be formed by a sputtering method, a CVD method, an MBE method, a PLD method, an ALD method, or the like. For example, a film of tantalum nitride may be formed by a sputtering method as the conductive film 242Af, and a film of tungsten may be formed as the conductive film 242Bf. Note that heat treatment may be performed before the formation of the conductive film 242Af. This heat treatment may be performed under reduced pressure, and the conductive film 242Af may be successively formed without exposure to the air. Such treatment can remove moisture and hydrogen adsorbed onto the surface of the oxide layer 230B, and further can reduce the moisture concentrations and the hydrogen concentrations in the oxide layer 230A and the oxide layer 230B. The heat treatment is preferably performed at a temperature higher than or equal to 100° C. and lower than or equal to 400° C. In this embodiment, the heat treatment is performed at 200° C.

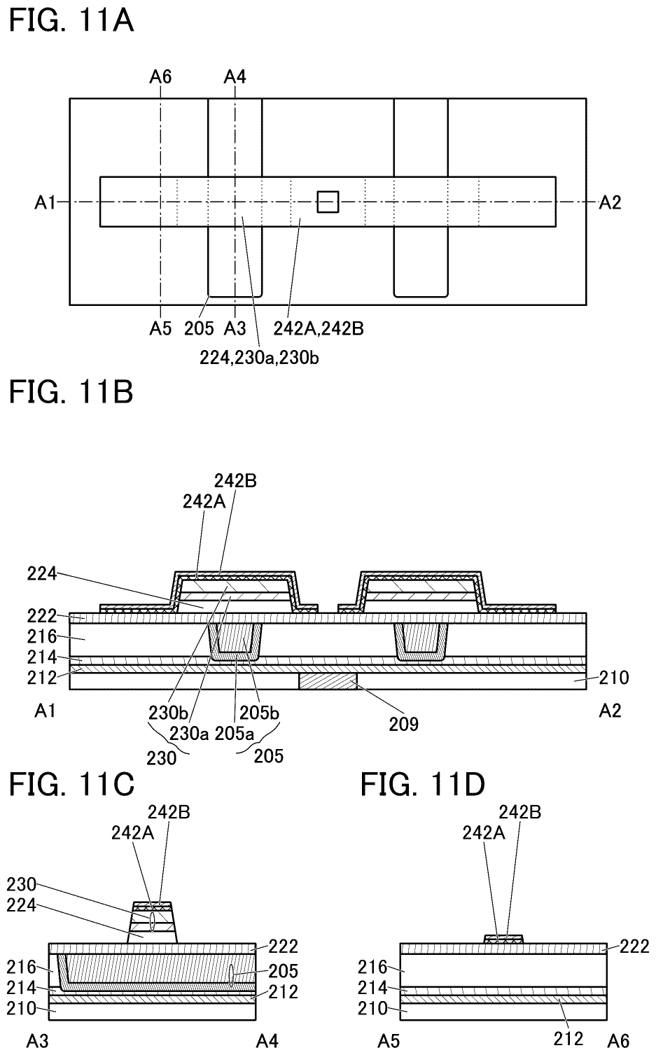

Next, the insulating layer 224A, the oxide layer 230A, the oxide layer 230B, the conductive film 242Af, and the conductive film 242Bf are processed by a lithography method to form the insulator 224, the oxide 230a, and the oxide 230b each having an island shape and a conductive layer 242A and a conductive layer 242B each having an island shape and including an opening (see FIG. 11A to FIG. 11D). For example, the insulating layer 224A, the oxide layer 230A, the oxide layer 230B, the conductive film 242Af, and the conductive film 242Bf are processed to form the insulator 224, the oxide 230a, and the oxide 230b each having an island shape and the conductive layer 242A and the conductive layer 242B extending in a direction parallel to the dashed-dotted line A1-A2 (the channel length direction of the transistor 200 or the X direction shown in FIG. 1A), and then, the conductive layer 242A and the conductive layer 242B are processed to form the conductive layer 242A and the conductive layer 242B each having an island shape and including an opening. Alternatively, for example, the insulating layer 224A, the oxide layer 230A, the oxide layer 230B, the conductive film 242Af, and the conductive film 242Bf may be processed into island shapes to form the insulator 224, the oxide 230a, the oxide 230b, the conductive layer 242A, and the conductive layer 242B, and then, an opening may be formed in the conductive layer 242A and the conductive layer 242B.

Here, the insulator 224, the oxide 230a, the oxide 230b, the conductive layer 242A, and the conductive layer 242B are formed to at least partly overlap with the conductor 205. The opening provided in the conductive layer 242A and the conductive layer 242B is formed in a position not overlapping with the oxide 230b. A dry etching method or a wet etching method can be used for the processing. Processing by a dry etching method is suitable for microfabrication. The insulating layer 224A, the oxide layer 230A, the oxide layer 230B, the conductive film 242Af, and the conductive film 242Bf may be processed under different conditions.

Furthermore, as illustrated in FIG. 11B to FIG. 11D, the side surfaces of the insulator 224, the oxide 230a, and the oxide 230b may have tapered shapes. Each of the insulator 224, the oxide 230a, and the oxide 230b may have a taper angle greater than or equal to 60° and less than 90°, for example. With such tapered shapes of the side surfaces, the coverage with the insulator 275 and the like can be improved in a later step, so that defects such as a void can be reduced.

Not being limited to the above, the insulator 224, the oxide 230a, and the oxide 230b may have side surfaces that are substantially perpendicular to the top surface of the insulator 222. With such a structure, the plurality of transistors 200 can be provided with high density in a small area.

A by-product generated in the above etching step is sometimes formed in a layered manner on the side surfaces of the insulator 224, the oxide 230a, the oxide 230b, the conductive layer 242A, and the conductive layer 242B. In this case, the layered by-product is formed between the insulator 275 and each of the insulator 224, the oxide 230a, the oxide 230b, the conductive layer 242A, and the conductive layer 242B. Hence, the layered by-product formed in contact with the top surface of the insulator 222 is preferably removed.

Although the structure is described in which the opening is provided at the center of the conductive layer 242A and the conductive layer 242B in the above etching step, the present invention is not limited thereto. For example, the conductive layer 242A and the conductive layer 242B on the transistor 200a side may be provided to be separated from the conductive layer 242A and the conductive layer 242B on the transistor 200b side.

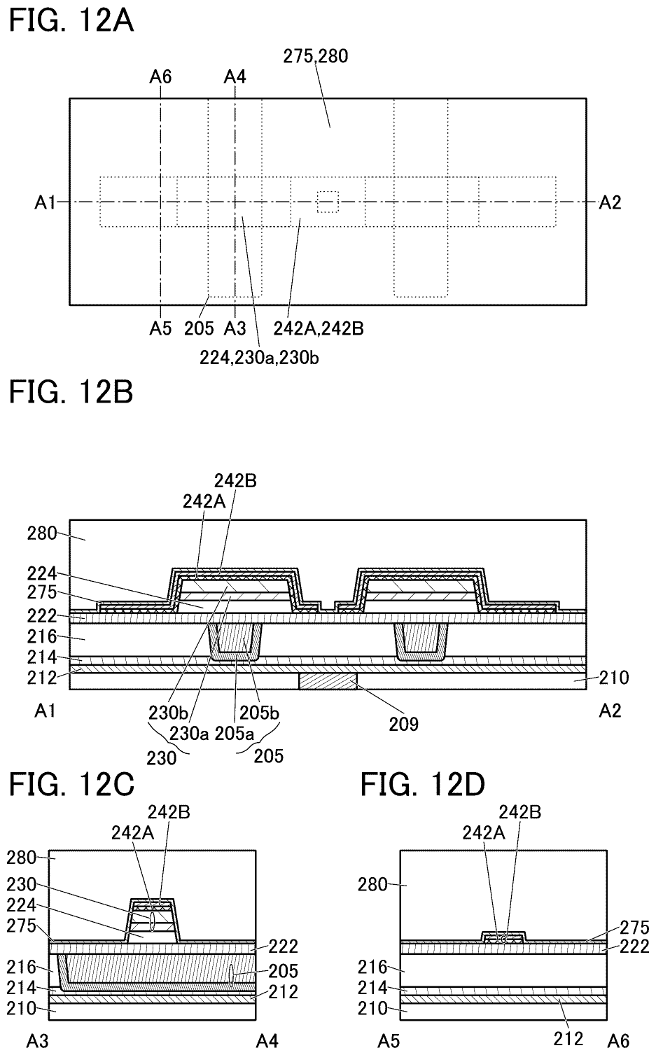

Next, the insulator 275 is formed to cover the insulator 224, the oxide 230a, the oxide 230b, the conductive layer 242A, and the conductive layer 242B (see FIG. 12A to FIG. 12D). Here, it is preferable that the insulator 275 be in contact with the top surface of the insulator 222 and the side surface of the insulator 224. The insulator 275 can be formed by a sputtering method, a CVD method, an MBE method, a PLD method, an ALD method, or the like. As the insulator 275, an insulating film having a function of inhibiting passage of oxygen is preferably used. For example, a film of silicon nitride is formed as the insulator 275 by an ALD method. Alternatively, as the insulator 275, a film of aluminum oxide is formed by a sputtering method, and a film of silicon nitride is formed thereover by a PEALD method. When the insulator 275 has such a stacked-layer structure, the function of inhibiting diffusion of oxygen and impurities such as water and hydrogen is improved in some cases.

In this manner, the oxide 230a, the oxide 230b, the conductive layer 242A, and the conductive layer 242B can be covered with the insulator 275, which has a function of inhibiting diffusion of oxygen. This can reduce direct diffusion of oxygen from the insulator 280 and the like into the insulator 224, the oxide 230a, the oxide 230b, the conductive layer 242A, and the conductive layer 242B in a later step.

Next, an insulating film to be the insulator 280 is formed over the insulator 275. The insulating film can be formed by a sputtering method, a CVD method, an MBE method, a PLD method, an ALD method, or the like. A silicon oxide film is formed by a sputtering method as the insulating film, for example. When the insulating film is formed by a sputtering method in an oxygen-containing atmosphere, the insulator 280 including excess oxygen can be formed. By using a sputtering method that does not need to use a molecule containing hydrogen as a film formation gas, the hydrogen concentration in the insulator 280 can be reduced. Note that heat treatment may be performed before the formation of the insulating film. The heat treatment may be performed under reduced pressure, and the insulating film may be successively formed without exposure to the air. Such treatment can remove moisture and hydrogen adsorbed onto the surface of the insulator 275 and the like, and further can reduce the moisture concentrations and the hydrogen concentrations in the oxide 230a, the oxide 230b, and the insulator 224. For the heat treatment, the above heat treatment conditions can be used.

Next, the insulating film to be the insulator 280 is subjected to CMP treatment, so that the insulator 280 with a flat top surface is formed (see FIG. 12A to FIG. 12D). Note that, for example, a film of silicon nitride may be formed over the insulator 280 by a sputtering method and CMP treatment may be performed on the silicon nitride until the insulator 280 is reached.

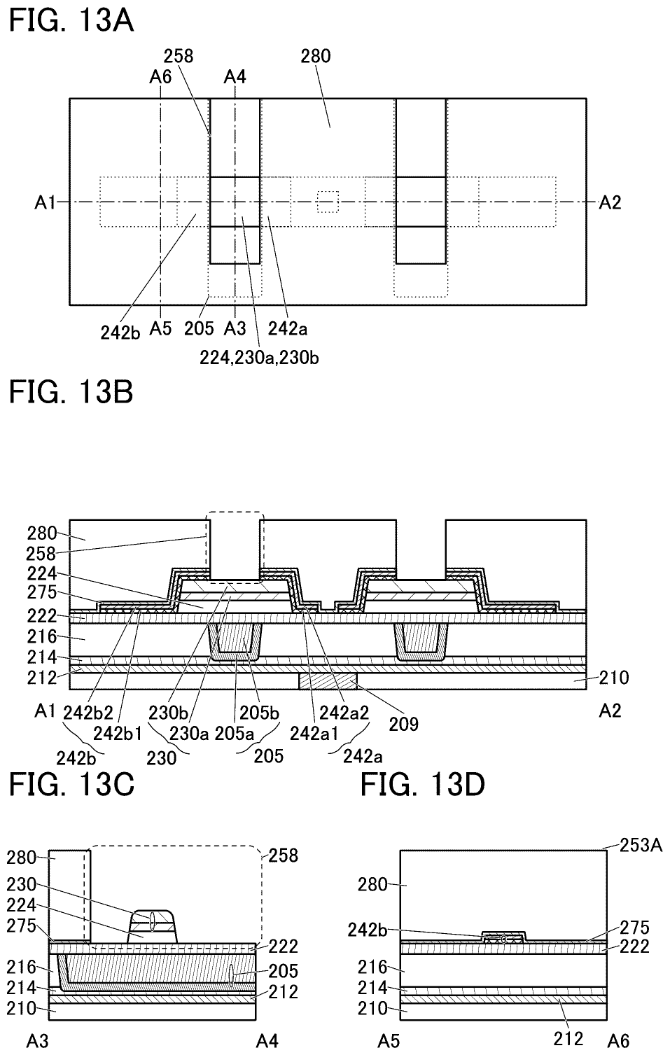

Then, part of the insulator 280, part of the insulator 275, part of the conductive layer 242A, and part of the conductive layer 242B are processed to form the opening 258 reaching the oxide 230b. Through the formation of the opening 258, the conductor 242al and the conductor 242b1 can be formed from the conductive layer 242A, and the conductor 242a2 and the conductor 242b2 can be formed from the conductive layer 242B (see FIG. 13A to FIG. 13D).

The part of the insulator 280, the part of the insulator 275, the part of the conductive layer 242A, and the part of the conductive layer 242B can be processed by a dry etching method or a wet etching method. Processing by a dry etching method is suitable for microfabrication. The processing may be performed under different conditions. For example, the part of the insulator 280 may be processed by a dry etching method, the part of the insulator 275 may be processed by a wet etching method, and the part of the conductive layer 242A and the part of the conductive layer 242B may be processed by a dry etching method.

As illustrated in FIG. 13A, the opening 258 is preferably formed to extend in a direction parallel to the dashed-dotted line A3-A4 (the channel width direction of the transistor or the Y direction shown in FIG. 1A). When the opening 258 is formed in this manner, the conductor 260, which is formed later, can be provided to extend in the above direction and can function as a wiring. The opening 258 is preferably formed to overlap with the conductor 205.

The channel length of the transistor 200 reflects the width of the opening 258 in the X direction, and thus, the width is preferably small. For example, the width of the opening 258 in the X direction is preferably less than or equal to 60 nm, less than or equal to 50 nm, less than or equal to 40 nm, less than or equal to 30 nm, less than or equal to 20 nm, or less than or equal to nm, and greater than or equal to 1 nm or greater than or equal to 5 nm. In order to process the opening 258 such minutely, a lithography method using an electron beam or short-wavelength light such as EUV light is preferably employed.

In the case where the opening 258 is processed minutely, the part of the insulator 280, the part of the insulator 275, the part of the conductive layer 242B, and the part of the conductive layer 242A are preferably processed by anisotropic etching. Processing by a dry etching method is particularly preferable because it is suitable for microfabrication. The processing may be performed under different conditions.

When the insulator 280, the insulator 275, the conductive layer 242B, and the conductive layer 242A are processed by anisotropic etching, the side surfaces of the conductor 242a and the conductor 242b that face each other can be formed to be substantially perpendicular to the top surface of the oxide 230b. Such a structure can inhibit formation of what is called a Loff region between the region 230ba and the region 230bc and between the region 230bb and the region 230bc. Accordingly, the frequency characteristics of the transistor 200 can be improved, and the operation speed of the semiconductor device of one embodiment of the present invention can be improved.

However, without limitation to the above, the side surfaces of the insulator 280, the insulator 275, and the conductor 242 may have tapered shapes as illustrated in FIG. 3B. The taper angle of the insulator 280 is larger than that of the conductor 242 in some cases. An upper portion of the oxide 230b is removed in some cases when the opening 258 is formed.

By the above etching treatment, impurities are attached onto the side surface of the oxide 230a, the top surface and the side surface of the oxide 230b, the side surface of the conductor 242, the side surface of the insulator 280, and the like or the impurities are diffused thereinto in some cases. A step of removing such impurities may be performed. In addition, a damaged region might be formed on the surface of the oxide 230b by the above dry etching. Such a damaged region may be removed. The impurities come from components included in the insulator 280, the insulator 275, the conductive layer 242B, and the conductive layer 242A; components included in a member of an apparatus used to form the opening; and components contained in a gas or a liquid used for etching, for instance. Examples of the impurities include hafnium, aluminum, silicon, tantalum, fluorine, and chlorine.

In particular, impurities such as aluminum and silicon might reduce the crystallinity of the oxide 230b. Thus, it is preferable that impurities such as aluminum and silicon be removed from the surface of the oxide 230b and the vicinity thereof. The concentration of the impurities is preferably reduced. For example, the concentration of aluminum atoms at the surface of the oxide 230b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet still further preferably lower than 0.3 atomic %.

Note that since the density of a crystal structure is reduced in a low-crystallinity region of the oxide 230b due to impurities such as aluminum and silicon, a large amount of V_{O}H is formed; thus, the transistor is likely to be normally on. Hence, the low-crystallinity region of the oxide 230b is preferably reduced or removed.

In contrast, the oxide 230b preferably has a layered CAAC structure. In particular, the CAAC structure preferably reaches a lower end portion of a drain in the oxide 230b. Here, in the transistor 200, the conductor 242a or the conductor 242b, and its vicinity function as a drain. In other words, the oxide 230b in the vicinity of a lower end portion of the conductor 242a (the conductor 242b) preferably has a CAAC structure. In this manner, the low-crystallinity region of the oxide 230b is removed and the CAAC structure is formed also in the end portion of the drain, which significantly affects the drain breakdown voltage, so that a variation in electrical characteristics of the transistor 200 can be further suppressed. In addition, the reliability of the transistor 200 can be improved.

In order to remove impurities and the like attached to the surface of the oxide 230b in the above etching step, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Furthermore, the crystallinity of the oxide 230b can be increased.

After the etching or the cleaning, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 230a and the oxide 230b to reduce oxygen vacancies. In addition, the crystallinity of the oxide 230b can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

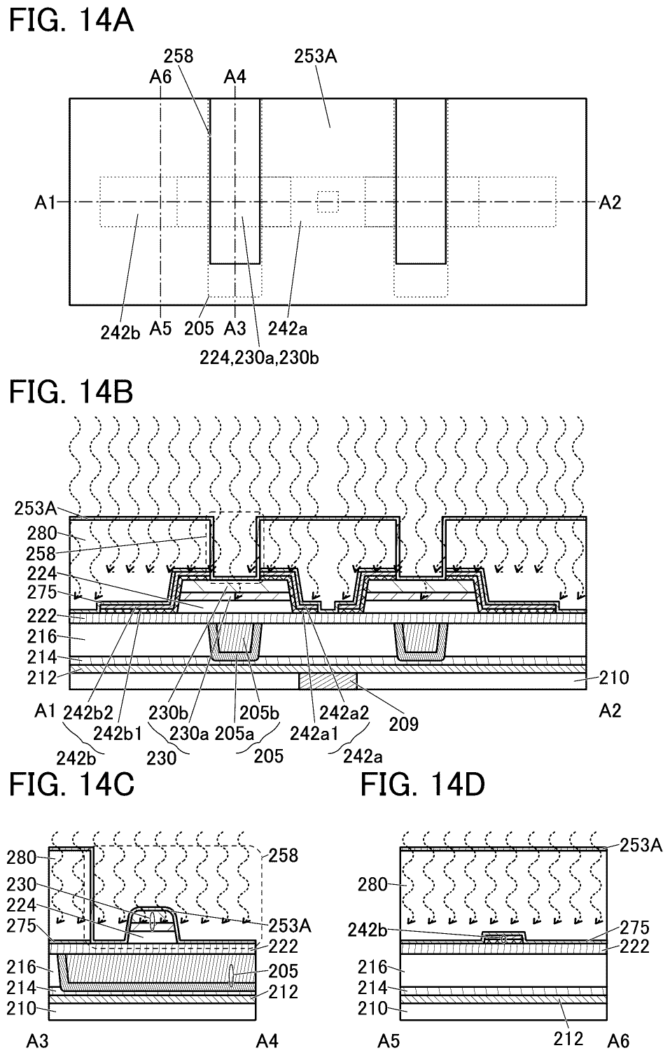

Next, an insulating film 253A is formed (see FIG. 14A to FIG. 14D). The insulating film 253A is an insulating film to be the insulator 253 in a later step. The insulating film 253A can be formed by a sputtering method, a CVD method, an MBE method, a PLD method, an ALD method, or the like. The insulating film 253A is preferably formed by an ALD method. As described above, it is preferable to form the insulating film 253A to have a small thickness, and a variation in the film thickness needs to be reduced. Since an ALD method is a film formation method in which a precursor and a reactant (e.g., oxidizer) are alternately introduced and the film thickness can be adjusted with the number of repetition times of the cycle, accurate control of the film thickness is possible. As illustrated in FIG. 14B and FIG. 14C, the insulating film 253A needs to be formed on the bottom surface and the side surface of the opening 258 with good coverage. In the opening 258, the insulating film 253A is preferably formed on the top surface and the side surface of the oxide 230 with good coverage. Using an ALD method enables an atomic layer to be deposited one by one on the bottom surface and the side surface of the opening 258, whereby the insulating film 253A can be formed in the opening with good coverage.

When the insulating film 253A is formed by an ALD method, ozone (O₃), oxygen (O₂), water (H₂O), or the like can be used as the oxidizer. When an oxidizer without hydrogen, such as ozone (O₃) or oxygen (O₂), is used, the amount of hydrogen diffusing into the oxide 230b can be reduced.

In this embodiment, a film of hafnium oxide is formed as the insulating film 253A by a thermal ALD method.

Next, it is preferable to perform microwave treatment in an atmosphere containing oxygen (see FIG. 14A to FIG. 14D). Here, the microwave treatment refers to, for example, treatment using an apparatus including a power source that generates high-density plasma with the use of a microwave. In this specification and the like, a microwave refers to an electromagnetic wave having a frequency higher than or equal to 300 MHz and lower than or equal to 300 GHz. In the case of the insulating film 253A having a stacked-layer structure, the microwave treatment may be performed at the time when part of the insulating film 253A is formed. For example, in the case where the insulating film 253A includes a silicon oxide film or a silicon oxynitride film, the microwave treatment may be performed at the time when the silicon oxide film or the silicon oxynitride film is formed.

Dotted arrows in FIG. 14B to FIG. 14D indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to higher than or equal to 300 MHz and lower than or equal to 300 GHz, preferably higher than or equal to 2.4 GHz and lower than or equal to 2.5 GHZ, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently.

The microwave treatment is preferably performed under reduced pressure, and the pressure is set to higher than or equal to 10 Pa and lower than or equal to 1000 Pa, preferably higher than or equal to 300 Pa and lower than or equal to 700 Pa. The treatment temperature is set to lower than or equal to 750° C., preferably lower than or equal to 500° C., and is approximately 250° C., for example. The oxygen plasma treatment may be followed successively by heat treatment without exposure to air. For example, the temperature is set to higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%. The carrier concentration in the region 230bc can be reduced by thus performing the microwave treatment in an atmosphere containing oxygen. In addition, the carrier concentrations in the region 230ba and the region 230bb can be prevented from being excessively reduced by preventing an excess amount of oxygen from being introduced into the chamber in the microwave treatment.

As illustrated in FIG. 14B to FIG. 14D, the microwave treatment performed in an oxygen-containing atmosphere can convert an oxygen gas into plasma using a high-frequency wave such as a microwave or RF, and make the oxygen plasma act on a region of the oxide 230b which is between the conductor 242a and the conductor 242b. At this time, the region 230bc can also be irradiated with the high-frequency wave such as a microwave or RF. In other words, the high-frequency wave such as a microwave or RF, the oxygen plasma, or the like can act on the region 230bc illustrated in FIG. 3A. The effect of the plasma, the microwave, or the like enables V_{O}H in the region 230bc to be cut, and hydrogen to be removed from the region 230bc. That is, V_{O}H included in the region 230bc can be reduced. Accordingly, oxygen vacancies and V_{O}H in the region 230bc can be reduced to lower the carrier concentration. In addition, oxygen radicals generated by the oxygen plasma can be supplied to oxygen vacancies formed in the region 230bc, thereby further reducing oxygen vacancies and lowering the carrier concentration in the region 230bc.

Meanwhile, the conductor 242a and the conductor 242b are provided over the region 230ba and the region 230bb illustrated in FIG. 3A. Here, the conductor 242 preferably functions as a blocking film preventing the effect caused by the high-frequency wave such as a microwave or RF, the oxygen plasma, or the like in the microwave treatment in an atmosphere containing oxygen. Therefore, the conductor 242 preferably has a function of blocking an electromagnetic wave of higher than or equal to 300 MHz and lower than or equal to 300 GHz, for example, higher than or equal to 2.4 GHz and lower than or equal to 2.5 GHz.

As illustrated in FIG. 14B to FIG. 14D, the effects of the high-frequency wave such as a microwave or RF, the oxygen plasma, and the like are blocked by the conductor 242a and the conductor 242b, and thus do not reach the region 230ba or the region 230bb. Hence, a reduction in V_{O}H and supply of an excess amount of oxygen due to the microwave treatment do not occur in the region 230ba or the region 230bb, preventing a decrease in carrier concentration.

Furthermore, the insulating film 253A having a barrier property against oxygen is provided in contact with the side surfaces of the conductor 242a and the conductor 242b. Thus, formation of oxide films on the side surfaces of the conductor 242a and the conductor 242b by the microwave treatment can be inhibited.

Furthermore, the film quality of the insulating film 253A can be improved, leading to higher reliability of the transistor 200.

In the above manner, oxygen vacancies and V_{O}H can be selectively removed from the region 230bc in the oxide semiconductor, whereby the region 230bc can be an i-type or substantially i-type region. Furthermore, supply of an excess amount of oxygen to the region 230ba and the region 230bb functioning as the source region and the drain region can be inhibited, and the conductivity can be maintained. As a result, a change in the electrical characteristics of the transistor 200 can be inhibited, and thus a variation in the electrical characteristics of the transistors 200 in the substrate plane can be inhibited.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is included in the oxide 230b, it is probable that the thermal energy is transmitted to the hydrogen in the oxide 230b and the hydrogen activated by the energy is released from the oxide 230b.

Microwave treatment may be performed before the formation of the insulating film 253A, without the microwave treatment performed after the formation of the insulating film 253A.

After the microwave treatment following the formation of the insulating film 253A, heat treatment may be performed with the reduced pressure being maintained. Such treatment enables hydrogen in the insulating film 253A, the oxide 230b, and the oxide 230a to be removed efficiently. Part of hydrogen is gettered by the conductor 242 (the conductor 242a and the conductor 242b) in some cases. Alternatively, the step of performing microwave treatment and then performing heat treatment with the reduced pressure being maintained may be repeated a plurality of cycles. The repetition of the heat treatment enables hydrogen in the insulating film 253A, the oxide 230b, and the oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

Furthermore, the microwave treatment improves the film quality of the insulating film 253A, thereby inhibiting diffusion of hydrogen, water, impurities, and the like. Accordingly, hydrogen, water, impurities, and the like can be inhibited from diffusing into the oxide 230b, the oxide 230a, and the like through the insulator 253 in a later step such as formation of a conductive film to be the conductor 260 or later treatment such as heat treatment.

Next, an insulating film to be the insulator 254 is formed. The insulating film can be formed by a sputtering method, a CVD method, an MBE method, a PLD method, an ALD method, or the like. The insulating film is preferably formed by an ALD method like the insulating film 253A. By an ALD method, the insulating film can be formed to have a small thickness and good coverage. In this embodiment, as the insulating film, a silicon nitride film is formed by a PEALD method.

Next, a conductive film to be the conductor 260a and a conductive film to be the conductor 260b are formed in this order. The conductive film to be the conductor 260a and the conductive film to be the conductor 260b can be formed by a sputtering method, a CVD method, an MBE method, a PLD method, an ALD method, or the like. In this embodiment, a film of titanium nitride is formed by an ALD method as the conductive film to be the conductor 260a, and a film of tungsten is formed by a CVD method as the conductive film to be the conductor 260b.

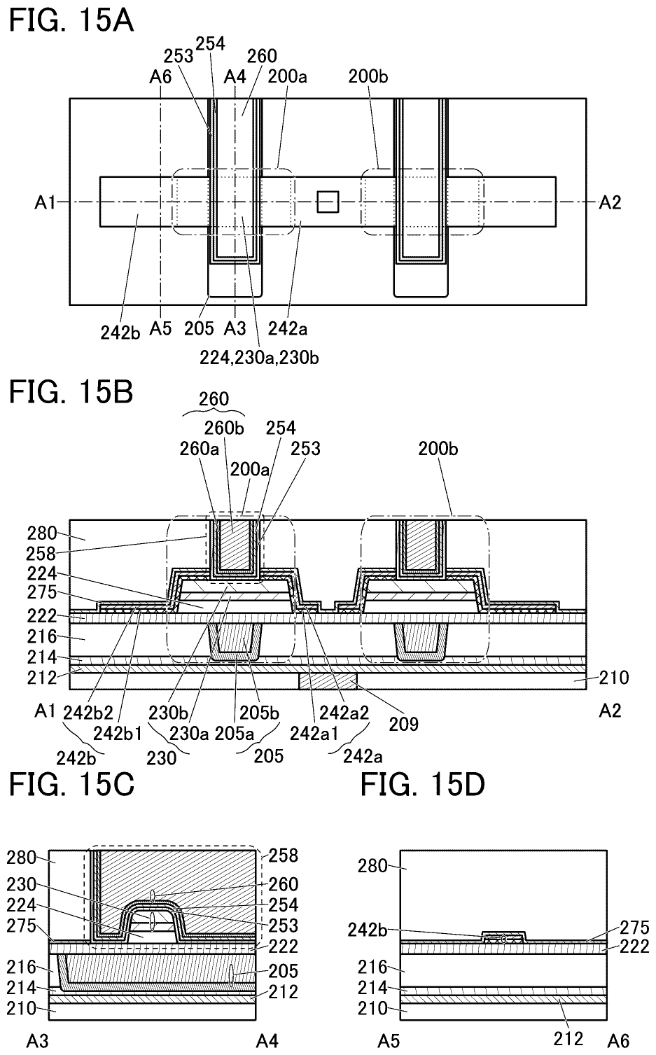

Then, the insulating film 253A, the insulating film to be the insulator 254, the conductive film to be the conductor 260a, and the conductive film to be the conductor 260b are polished by CMP treatment until the insulator 280 is exposed. That is, a portion of the insulating film 253A, a portion of the insulating film to be the insulator 254, a portion of the conductive film to be the conductor 260a, and a portion of the conductive film to be the conductor 260b that are exposed from the opening 258 are removed. Thus, the insulator 253, the insulator 254, and the conductor 260 (the conductor 260a and the conductor 260b) are formed in the opening 258 (see FIG. 15A to FIG. 15D).

Accordingly, the insulator 253 is provided in contact with the inner wall and the side surface of the opening 258 overlapping with the oxide 230b. The conductor 260 is located to fill the opening 258 with the insulator 253 and the insulator 254 therebetween. In this manner, the transistor 200 is formed.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 280. After the heat treatment, the insulator 282 may be successively formed without exposure to the air.

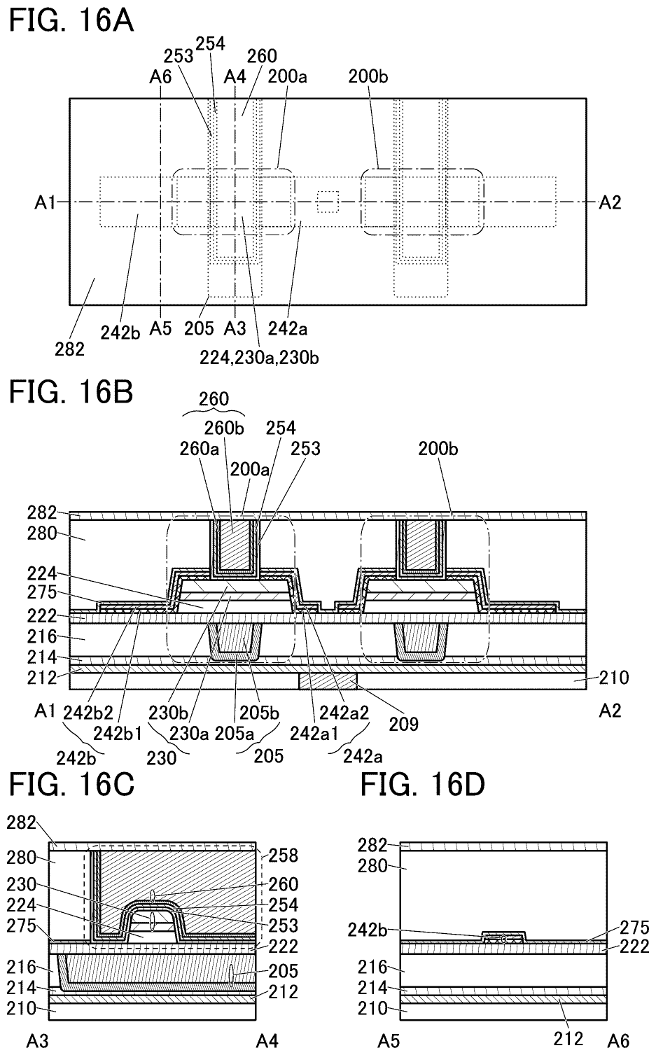

Next, the insulator 282 is formed over the insulator 253, the insulator 254, the conductor 260, and the insulator 280 (see FIG. 16A to FIG. 16D). The insulator 282 can be formed by a sputtering method, a CVD method, an MBE method, a PLD method, an ALD method, or the like. The insulator 282 is preferably formed by a sputtering method. By using a sputtering method that does not need to use a molecule containing hydrogen as a film formation gas, the hydrogen concentration in the insulator 282 can be reduced.

In this embodiment, as the insulator 282, a film of aluminum oxide is formed by a pulsed DC sputtering method using an aluminum target in an atmosphere containing an oxygen gas. The use of a pulsed DC sputtering method can achieve more uniform film thickness and improve the sputtering rate and film quality. The RF power applied to the substrate is lower than or equal to 1.86 W/cm², preferably higher than or equal to 0 W/cm² and lower than or equal to 0.62 W/cm². With low RF power, the amount of oxygen implanted into the insulator 280 can be reduced. Alternatively, the insulator 282 may be formed to have a stacked-layer structure of two layers. In that case, the lower layer of the insulator 282 is formed with the RF power applied to the substrate being 0 W/cm², and the upper layer of the insulator 282 is formed with the RF power applied to the substrate being 0.62 W/cm².

When the insulator 282 is formed by a sputtering method in an oxygen-containing atmosphere, oxygen can be added to the insulator 280 during the formation. Thus, excess oxygen can be included in the insulator 280. At this time, the insulator 282 is preferably formed while the substrate is being heated.

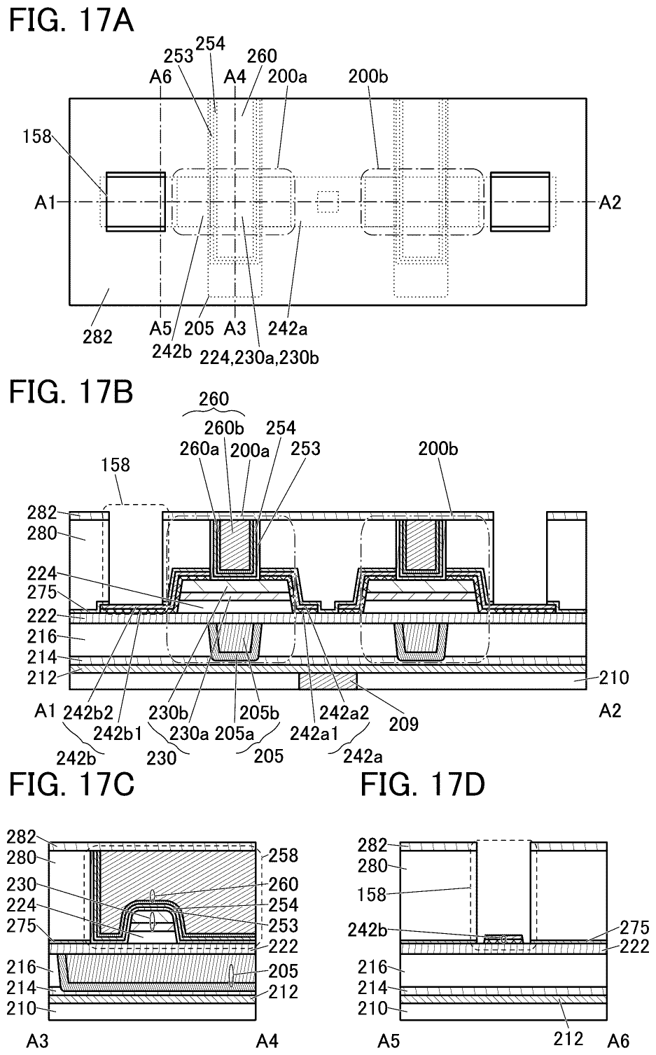

Next, part of the insulator 282, part of the insulator 280, and part of the insulator 275 are processed to form the opening 158 reaching the conductor 242b (see FIG. 17A to FIG. 17D). The opening 158 is formed by a lithography method. Note that the opening 158 in the top view in FIG. 17A has a quadrangular shape; however, the shape of the opening is not limited thereto. For example, the opening in the top view may have a circular shape, a substantially circular shape such as an elliptical shape, a polygonal shape such as a quadrangular shape, or a polygonal shape such as a quadrangular shape with rounded corners.

The width of the opening 158 in the X direction is preferably small. For example, the width of the opening 158 in the X direction is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm. In order to process the opening 158 such minutely, a lithography method using an electron beam or short-wavelength light such as EUV light is preferably employed.

Since the opening 158 has a high aspect ratio, the part of the insulator 282, the part of the insulator 280, and the part of the insulator 275 are preferably processed by anisotropic etching. Processing by a dry etching method is particularly preferable because it is suitable for microfabrication. The processing may be performed under different conditions.

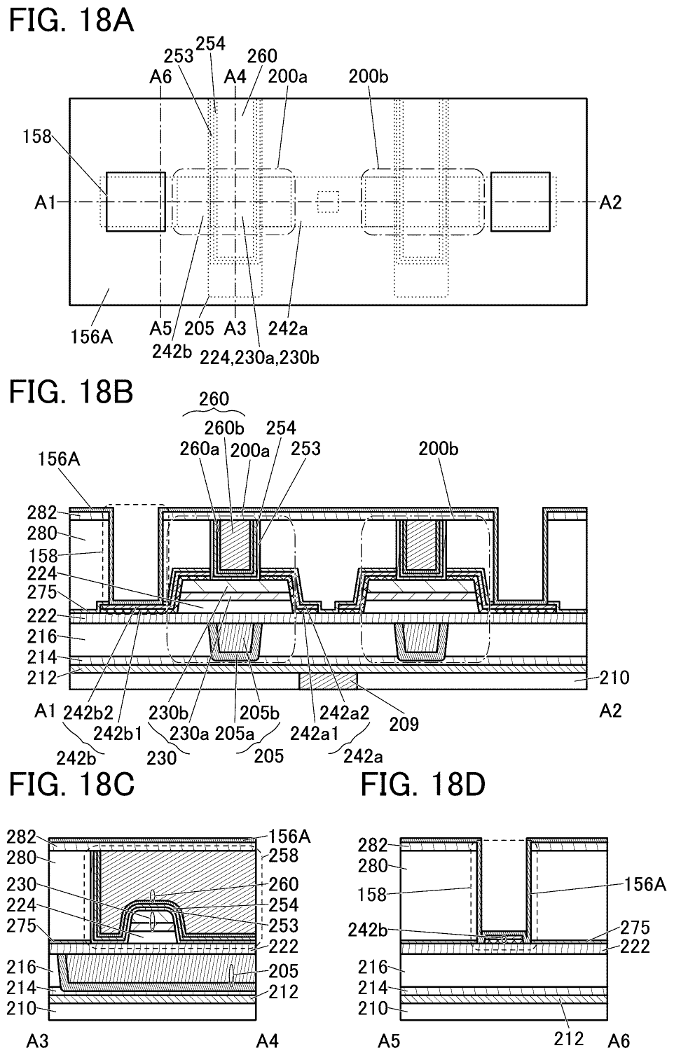

Next, a conductive film 156A is formed to cover the opening 158 and the insulator 282 (see FIG. 18A to FIG. 18D). The conductive film 156A is a conductive film to be the conductor 156 in a later step. The conductive film 156A is preferably formed in contact with the side surface and the bottom surface of the opening 158 having a high aspect ratio. Thus, the conductive film 156A is preferably formed by a film formation method that enables favorable coverage, such as an ALD method or a CVD method. For example, a film of titanium nitride or tantalum nitride may be formed by an ALD method.

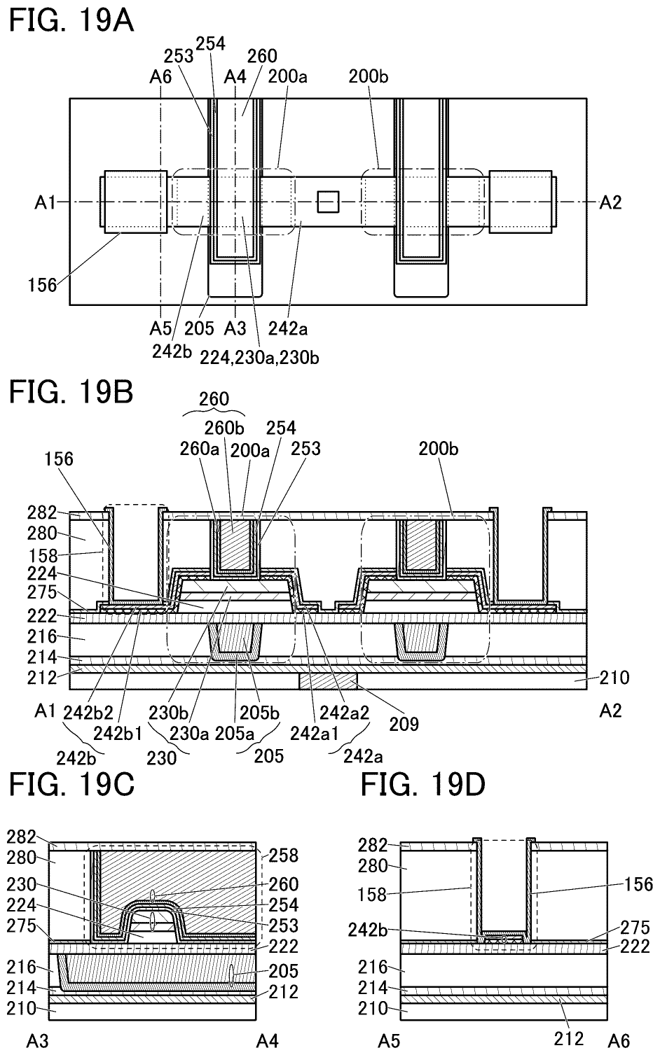

Next, the conductive film 156A is processed by a lithography method to form the conductor 156 (see FIG. 19A to FIG. 19D). Accordingly, part of the conductor 156 is formed over the opening 158 and is in contact with part of the top surface of the insulator 282.

The conductive film 156A may be processed by a CMP method. In that case, the opening 158 may be filled with a filler, and CMP treatment may be performed on the filler and the conductive film 156A until the insulator 282 is exposed. Accordingly, as in FIG. 5A and FIG. 5B, a shape such that the uppermost portion of the conductor 156 is substantially level with the top surface of the insulator 282 can be obtained. The filler may be removed after the formation of the conductor 156.

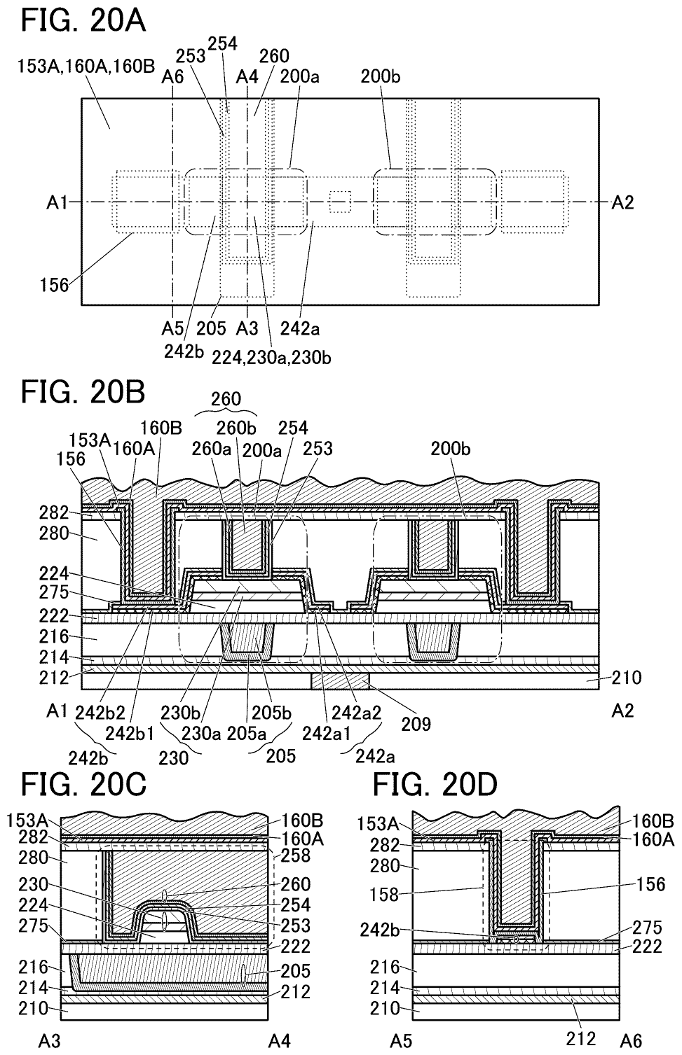

Next, an insulating film 153A is formed over the conductor 156 (see FIG. 20A to FIG. 20D). The insulating film 153A is an insulating film to be the insulator 153 in a later step. The insulating film 153A is preferably formed in contact with the conductor 156 that is provided inside the opening 158 having a high aspect ratio. Thus, the insulating film 153A is preferably formed by a film formation method that enables favorable coverage, such as an ALD method or a CVD method. For the insulating film 153A, any of the above-described high-k materials can be used.

Next, a conductive film 160A to be the conductor 160a and a conductive film 160B to be the conductor 160b are formed in this order (see FIG. 20A to FIG. 20D). The conductive film 160A is to be the conductor 160a in a later step, and the conductive film 160B is to be the conductor 160b in a later step. The conductive film 160A is preferably formed in contact with the insulating film 153A provided inside the opening 158 having a high aspect ratio, and the conductive film 160B is preferably formed to fill the opening 158. It is thus preferable that the conductive film 160A and the conductive film 160B be formed by a film formation method that enables favorable coverage, such as an ALD method or a CVD method. For example, a film of titanium nitride is formed by an ALD method as the conductive film 160A, and a film of tungsten is formed by a CVD method as the conductive film 160B.

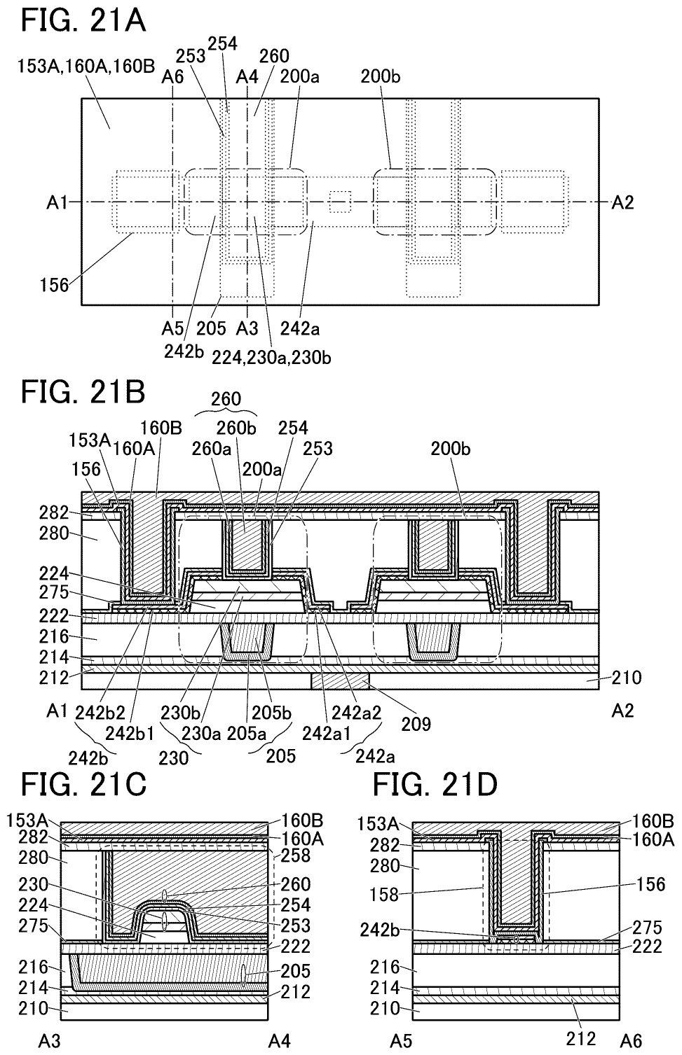

When the conductive film 160B is formed by a CVD method, the average surface roughness of the top surface of the conductive film 160B is sometimes large as illustrated in FIG. 20B to FIG. 20D. In that case, the conductive film 160B is preferably planarized by a CMP method (see FIG. 21A to FIG. 21D). At this time, before the CMP treatment, a silicon oxide film or a silicon oxynitride film may be formed over the conductive film 160B and the CMP treatment may be performed until the silicon oxide film or the silicon oxynitride film is removed.

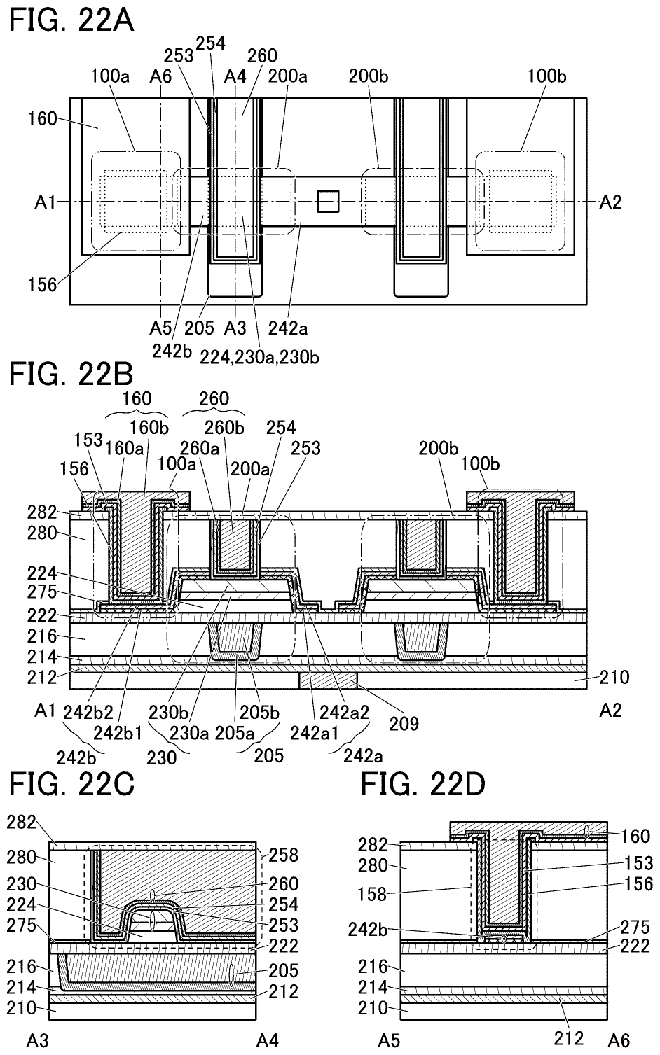

Next, the insulating film 153A, the conductive film 160A, and the conductive film 160B are processed by a lithography method to form the insulator 153, the conductor 160a, and the conductor 160b (see FIG. 22A to FIG. 22D). At this time, the insulator 153, the conductor 160a, and the conductor 160b are preferably formed to cover the side end portion of the conductor 156. With such a structure, the conductor 160 and the conductor 156 can be separated by the insulator 153; thus, a short circuit between the conductor 160 and the conductor 156 can be inhibited.

As illustrated in FIG. 22A and FIG. 22D, the conductor 160 is preferably provided to extend in the A5-A6 direction. In this case, the insulator 153 can also be provided to extend together with the conductor 160.

Although the insulating film 153A is also processed into the insulator 153 in the above-described example, the present invention is not limited thereto. A structure may be employed where only the conductive film 160A and the conductive film 160B are processed with the insulating film 153A remaining. In that case, as illustrated in FIG. 5A and FIG. 5B, part of the insulator 153 is provided to be exposed from the conductor 160. This eliminates the need for processing the insulator 153; thus, the number of manufacturing steps of the storage device can be reduced and the productivity can be improved.

In this manner, the capacitor 100 in which at least part of the conductor 156, at least part of the insulator 153, and at least part of the conductor 160 are formed in the opening 158 can be formed.

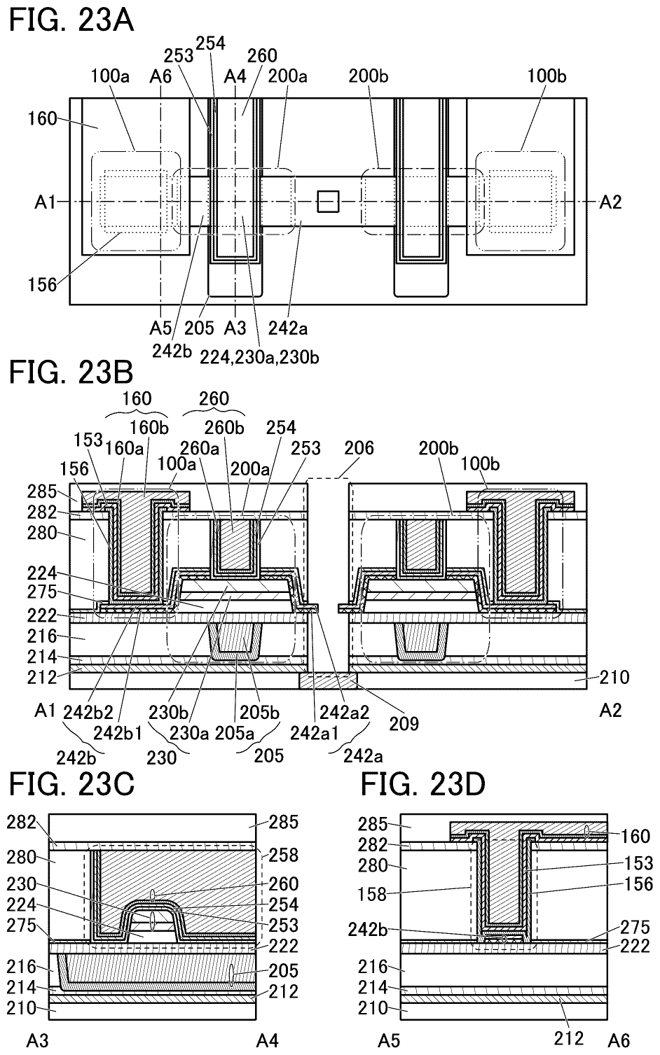

Next, the insulator 285 is formed over the insulator 282 and the conductor 160 (see FIG. 23A to FIG. 23D). The insulator 285 can be formed by a sputtering method, a CVD method, an MBE method, a PLD method, an ALD method, or the like. The insulator 285 is preferably formed by a sputtering method. By using a sputtering method that does not need to use a molecule containing hydrogen as a film formation gas, the hydrogen concentration in the insulator 285 can be reduced.

In this embodiment, as the insulator 285, a film of silicon oxide is formed by a sputtering method.

Subsequently, the opening 206 reaching the conductor 209 is formed in the insulator 212, the insulator 214, the insulator 216, the insulator 222, the insulator 275, the insulator 280, the insulator 282, and the insulator 285 (see FIG. 23A and FIG. 23B). The opening is formed by a lithography method. Note that the opening in the top view in FIG. 23A has a quadrangular shape; however, the shape of the opening is not limited thereto. For example, the opening in the top view may have a circular shape, a substantially circular shape such as an elliptical shape, a polygonal shape such as a quadrangular shape, or a polygonal shape such as a quadrangular shape with rounded corners.

The opening 206 may be formed in the following manner, for example: the top surface of the conductor 209 is exposed by anisotropic etching, and then, isotropic etching is performed to make the side surfaces of the insulator 212, the insulator 214, the insulator 216, the insulator 222, the insulator 275, the insulator 280, the insulator 282, and the insulator 285 recede from the side surface of the conductor 242a. Here, the isotropic etching is performed under conditions where the conductor 242 is not easily etched.

The anisotropic etching and the isotropic etching are preferably performed successively without exposure to the air under different conditions with the same etching apparatus. For example, in the case where a dry etching method is used for both the anisotropic etching and the isotropic etching, switching from the anisotropic etching to the isotropic etching can be performed by changing one or more of the power supply, the bias power, the flow rate of an etching gas, the etching gas species, the pressure, and other conditions.

Alternatively, different etching methods may be used for the anisotropic etching and the isotropic etching. For example, a dry etching method can be used for the anisotropic etching and a wet etching method can be used for the isotropic etching.

Next, a conductive film to be the conductor 240a and a conductive film to be the conductor 240b are formed in this order. These conductive films can be formed by a sputtering method, a CVD method, an MBE method, a PLD method, an ALD method, or the like.

The conductive film to be the conductor 240a preferably has a function of inhibiting passage of impurities such as water and hydrogen. The conductive film to be the conductor 240a is preferably formed by a film formation method that enables favorable coverage, such as an ALD method. For the conductive film to be the conductor 240a, tantalum nitride, titanium nitride, or the like can be used, for example.

The conductive film to be the conductor 240b is preferably formed by a film formation method that enables favorable embeddability, such as a CVD method. For the conductive film to be the conductor 240b, tungsten, molybdenum, copper, or the like can be used, for example.

Next, by performing CMP treatment, the conductive film to be the conductor 240a and the conductive film to be the conductor 240b are partly removed to expose the top surface of the insulator 285. As a result, these conductive films remain only in the opening 206, so that the conductor 240 (the conductor 240a and the conductor 240b) having a flat top surface can be formed (see FIG. 1A to FIG. 1D). Note that the top surface of the insulator 285 is partly removed by the CMP treatment in some cases.

Through the above process, the semiconductor device with the transistor 200 and the capacitor 100 illustrated in FIG. 1A to FIG. 1D can be manufactured. The number of the manufacturing steps of the semiconductor device with the capacitor 100 and the transistor 200 can be reduced when the method for manufacturing the semiconductor device described in this embodiment is used as illustrated in FIG. 8A to FIG. 23D.

Note that the insulator 224, the oxide 230a, the oxide 230b, the conductive layer 242A, and the conductive layer 242B are not necessarily formed by the above-described method. A different method for forming the insulator 224, the oxide 230a, the oxide 230b, the conductive layer 242A, and the conductive layer 242B is described below.

The steps up to and including the formation of the insulating film 224Af, the oxide film 230Af, and the oxide film 230Bf are performed as described above.

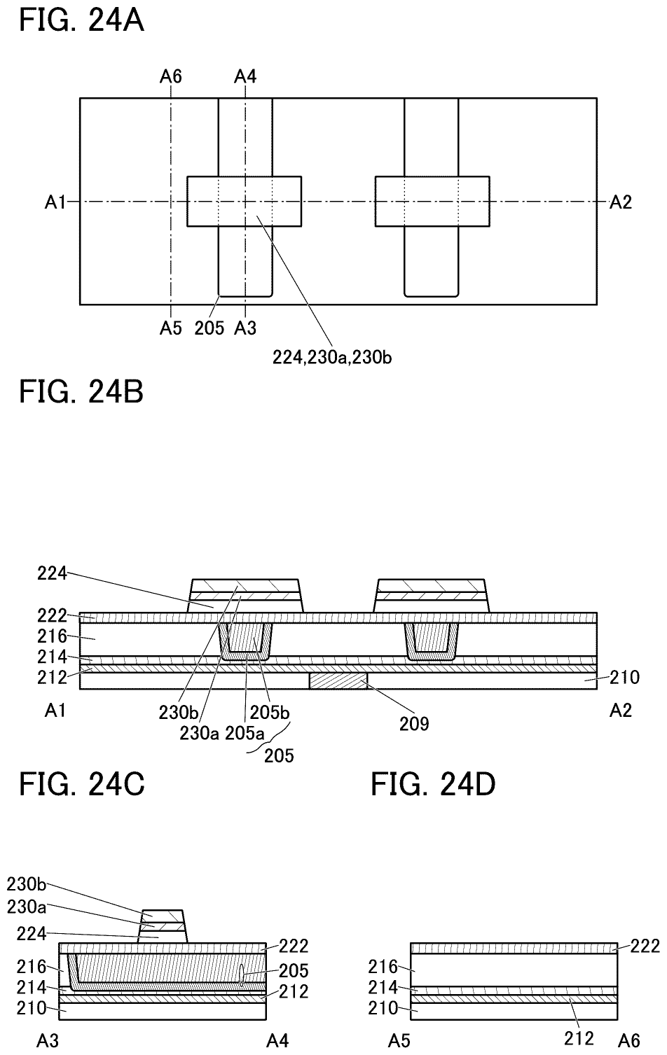

Next, the insulating film 224Af, the oxide film 230Af, and the oxide film 230Bf are processed into island shapes by a lithography method to form the insulator 224, the oxide 230a, and the oxide 230b (see FIG. 24A to FIG. 24D). Here, the insulator 224, the oxide 230a, and the oxide 230b are formed to at least partly overlap with the conductor 205. A dry etching method or a wet etching method can be used for the processing. Processing by a dry etching method is suitable for microfabrication. The insulating film 224Af, the oxide film 230Af, and the oxide film 230Bf may be processed under different conditions.

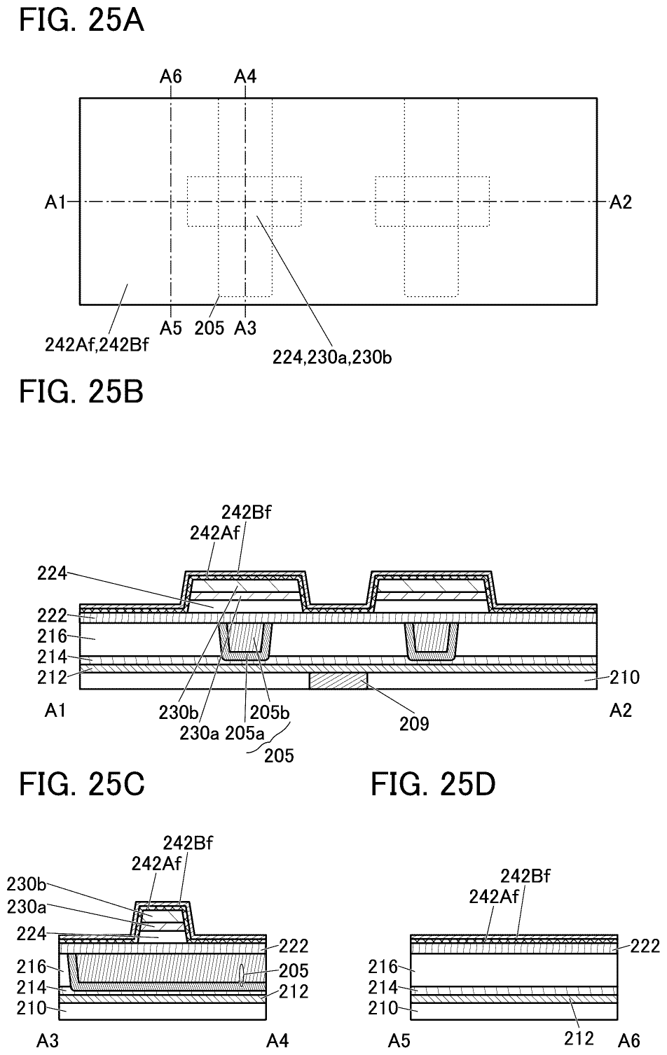

Next, the conductive film 242Af and the conductive film 242Bf are formed in this order over the insulator 222 and the oxide 230b (see FIG. 25A to FIG. 25D). For the formation methods of the conductive film 242Af and the conductive film 242Bf, the description of FIG. 10A to FIG. 10D can be referred to.

Next, the conductive film 242Af and the conductive film 242Bf are processed by a lithography method to form the conductive layer 242A and the conductive layer 242B each having an island shape (see FIG. 11A to FIG. 11D). Note that an opening may be formed at the time of processing of the conductive film 242Af and the conductive film 242Bf into island shapes.

When the above method is employed, processing of the insulator 224, the oxide 230a, and the oxide 230b and processing of the conductive layer 242A and the conductive layer 242B can be performed independently.

The above is the description of the different method for forming the insulator 224, the oxide 230a, the oxide 230b, the conductive layer 242A, and the conductive layer 242B.

### <Microwave Treatment Apparatus>

A microwave treatment apparatus that can be used for the above method for manufacturing the semiconductor device is described below.

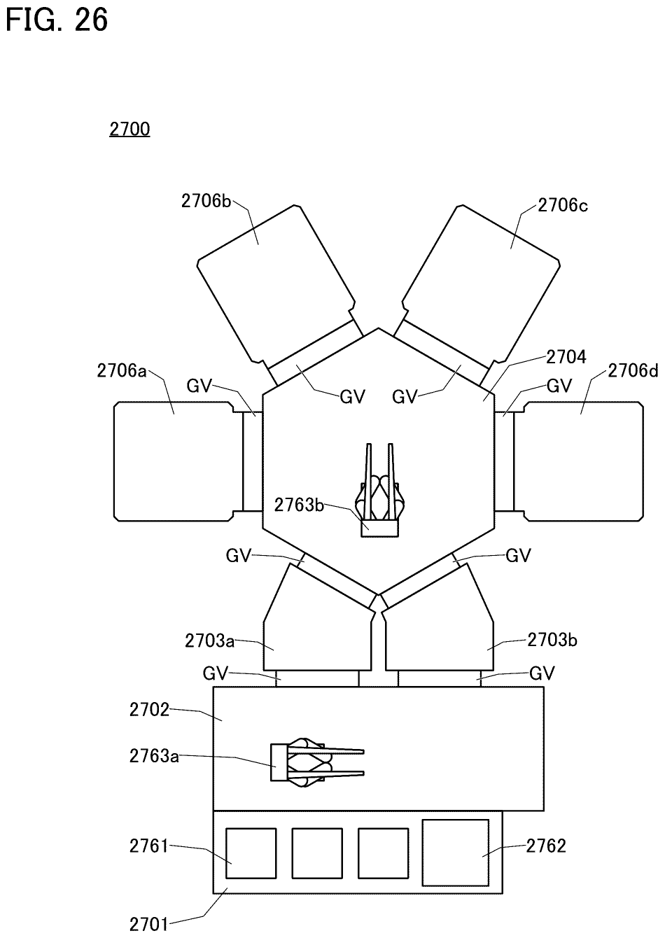

First, a structure of a manufacturing apparatus that hardly allows entry of impurities in manufacturing a semiconductor device or the like is described with reference to FIG. 26 to FIG. 29.

FIG. 26 schematically illustrates a top view of a single wafer multi-chamber manufacturing apparatus 2700. The manufacturing apparatus 2700 includes an atmosphere-side substrate supply chamber 2701 including a cassette port 2761 for storing a substrate and an alignment port 2762 for performing alignment of a substrate; an atmosphere-side substrate transfer chamber 2702 for transferring a substrate from the atmosphere-side substrate supply chamber 2701; a load lock chamber 2703a for carrying in a substrate and switching the pressure inside the chamber from atmospheric pressure to reduced pressure or from reduced pressure to atmospheric pressure; an unload lock chamber 2703b for carrying out a substrate and switching the pressure inside the chamber from reduced pressure to atmospheric pressure or from atmospheric pressure to reduced pressure; a transfer chamber 2704 for transferring a substrate in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that the chambers other than the atmosphere-side substrate supply chamber 2701 and the atmosphere-side substrate transfer chamber 2702 can be each independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in the transfer chamber 2704 and each of the chambers can be measured using an ionization vacuum gauge, a mass analyzer, or the like.

Furthermore, the transfer chamber 2704 and the chambers each desirably have a structure in which the amount of external leakage or internal leakage is small. For example, the leakage rate in the transfer chamber 2704 is less than or equal to 1×10⁰ Pa/min, preferably less than or equal to 5×10⁻¹ Pa/min. Furthermore, the leakage rate in each chamber is less than or equal to 1×10⁻¹ Pa/min, preferably less than or equal to 5×10⁻² Pa/min.

Note that a leakage rate is derived from the total pressure and partial pressure measured using the ionization vacuum gauge, the mass analyzer, or the like. For example, the leakage rate is preferably derived from the total pressure at the time when 10 minutes have passed from the start of evacuation to a vacuum using a vacuum pump such as a turbo molecular pump and the total pressure at the time when 10 minutes have passed from the operation of closing the valve. Note that the total pressure at the time when 10 minutes have passed from the start of evacuation to a vacuum is preferably an average value of the total pressures measured a plurality of times.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, a metal covered with iron fluoride, aluminum oxide, or chromium oxide is preferably used. The metal gasket achieves higher adhesion than an O-ring and can reduce the external leakage. Furthermore, with the use of a passive metal covered with iron fluoride, aluminum oxide, chromium oxide, or the like, the release of gas containing impurities released from the metal gasket is inhibited, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing any of iron, chromium, nickel, and the like and covered with the above-described metal, which releases a small amount of gas containing impurities, may be used. The alloy containing any of iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only metal when possible, and in the case where a viewing window formed of quartz or the like is provided, for example, the surface is preferably thinly covered with iron fluoride, aluminum oxide, chromium oxide, or the like to inhibit release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with the use of a pump having high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a noble gas is preferably used as the inert gas.

Alternatively, treatment for evacuating the transfer chamber 2704 and each of the chambers is preferably performed after a certain period of time after a heated inert gas such as a noble gas, heated oxygen, or the like is introduced to increase the pressure in the transfer chamber 2704 and each of the chambers. The introduction of the heated gas can desorb the adsorbed substance in the transfer chamber 2704 and each of the chambers, and impurities present in the transfer chamber 2704 and each of the chambers can be reduced. Note that this treatment is effective when repeated more than or equal to 2 times and less than or equal to 30 times, preferably more than or equal to 5 times and less than or equal to 15 times. Specifically, an inert gas, oxygen, or the like at a temperature higher than or equal to 40° C. and lower than or equal to 400° C., preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, further preferably higher than or equal to 5 Pa and lower than or equal to 100 Pa within the time range of 1 minute to 300 minutes, preferably 5 minutes to 120 minutes. After that, the transfer chamber 2704 and each of the chambers are evacuated within the time range of 5 minutes to 300 minutes, preferably 10 minutes to 120 minutes.

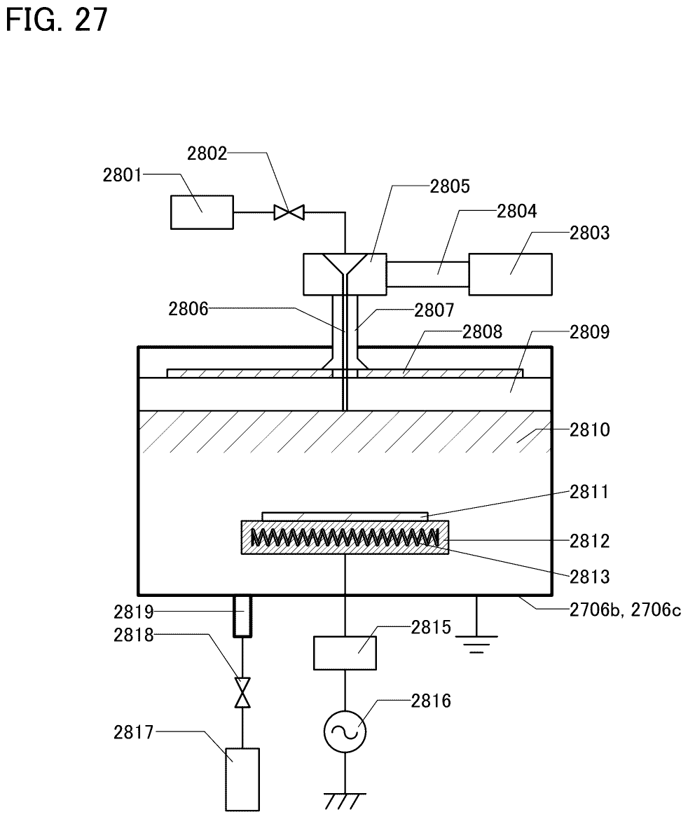

Next, the chamber 2706b and the chamber 2706c are described with reference to a schematic cross-sectional view in FIG. 27.

The chamber 2706b and the chamber 2706c are chambers in which microwave treatment can be performed on an object, for example. Note that the chamber 2706b is different from the chamber 2706c only in the atmosphere in performing the microwave treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is located in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 2818 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function of an electrostatic chuck or a mechanical chuck for holding the substrate 2811. Furthermore, the substrate holder 2812 has a function of an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2817, a cryotrap may be used. The cryopump and the cryotrap are particularly preferably used, in which case water can be efficiently exhausted.

Furthermore, for example, the heating mechanism 2813 is a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is lower than or equal to −80° C., preferably lower than or equal to −100° C. is preferably used. For example, an oxygen gas, a nitrogen gas, or a noble gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high-density region of high-density plasma 2810 described later; thus, provision of the protective layer can reduce the damage. Consequently, an increase in the number of particles or the like during the treatment can be suppressed.

The high-frequency generator 2803 has a function of generating a microwave at, for example, higher than or equal to 0.3 GHz and lower than or equal to 3.0 GHz, higher than or equal to 0.7 GHZ and lower than or equal to 1.1 GHZ, or higher than or equal to 2.2 GHz and lower than or equal to 2.8 GHz. The microwave generated by the high-frequency generator 2803 is propagated to the mode converter 2805 through the waveguide 2804. The mode converter 2805 converts the microwave propagated in the TE mode into the microwave in the TEM mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF (Radio Frequency) power source with a frequency of 13.56 MHz, 27.12 MHz, or the like is used, for example. The application of a bias to the substrate side allows ions in the high-density plasma 2810 to efficiently reach a deep portion of an opening portion of the film or the like over the substrate 2811.

For example, in the chamber 2706b or the chamber 2706c, oxygen radical treatment using the high-density plasma 2810 can be performed by introducing oxygen from the gas supply source 2801.

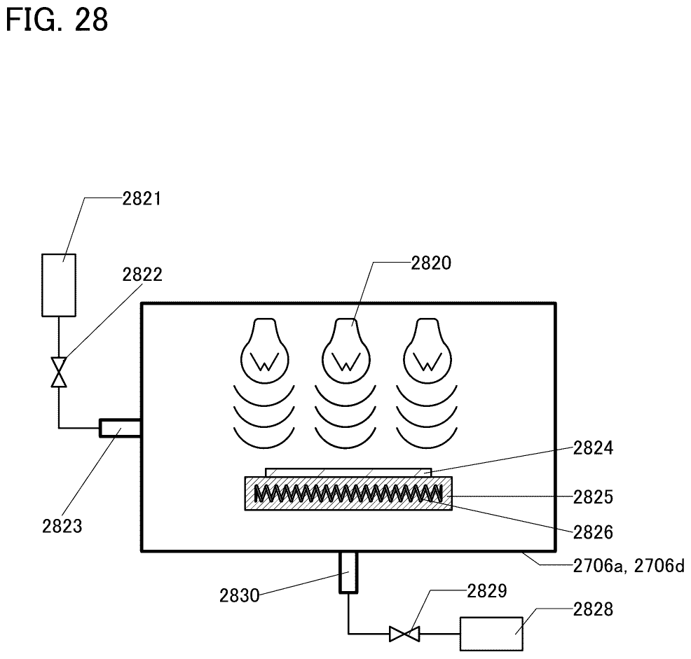

Next, the chamber 2706a and the chamber 2706d are described with reference to a schematic cross-sectional view in FIG. 28.

The chamber 2706a and the chamber 2706d are chambers in which an object can be irradiated with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or more lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is located to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light is used, for example. For example, a light source having a function of emitting an electromagnetic wave which has a peak at a wavelength longer than or equal to 10 nm and shorter than or equal to 2500 nm, longer than or equal to 500 nm and shorter than or equal to 2000 nm, or longer than or equal to 40 nm and shorter than or equal to 340 nm is used.

As the lamp 2820, a light source such as a halogen lamp, a metal halide lamp, a xenon arc lamp, a carbon arc lamp, a high-pressure sodium lamp, or a high-pressure mercury lamp is used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may allow the substrate holder 2825 to generate heat for heating the substrate 2824. In that case, the substrate holder 2825 does not need to include the heating mechanism 2826 therein.

For the vacuum pump 2828, refer to the description of the vacuum pump 2817. Furthermore, for the heating mechanism 2826, refer to the description of the heating mechanism 2813. Furthermore, for the gas supply source 2821, refer to the description of the gas supply source 2801.

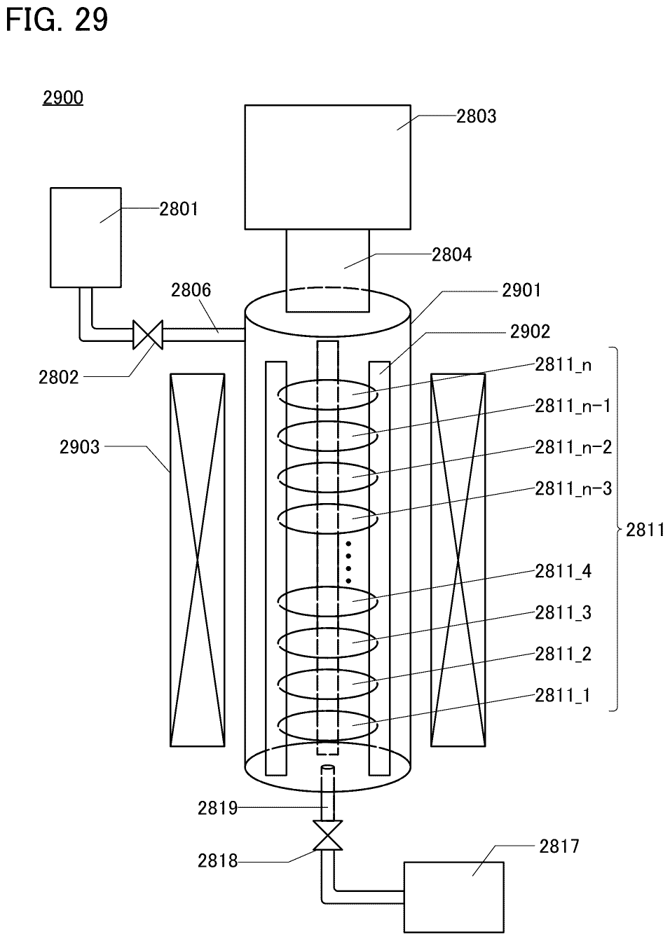

A microwave treatment apparatus that can be used in this embodiment is not limited to the above. A microwave treatment apparatus 2900 illustrated in FIG. 29 can be used. The microwave treatment apparatus 2900 includes a quartz tube 2901, the exhaust port 2819, the gas supply source 2801, the valve 2802, the high-frequency generator 2803, the waveguide 2804, the gas pipe 2806, the vacuum pump 2817, and the valve 2818. Furthermore, the microwave treatment apparatus 2900 includes a substrate holder 2902 that holds a plurality of substrates 2811 (2811_1 to 2811_n, n is an integer greater than or equal to 2) in the quartz tube 2901. The microwave treatment apparatus 2900 may further include a heating means 2903 outside the quartz tube 2901.

The substrate provided in the quartz tube 2901 is irradiated with the microwave generated by the high-frequency generator 2803, through the waveguide 2804. The vacuum pump 2817 is connected to the exhaust port 2819 through the valve 2818 and can adjust the pressure inside the quartz tube 2901. The gas supply source 2801 is connected to the gas pipe 2806 through the valve 2802 and can introduce a desired gas into the quartz tube 2901. The heating means 2903 can heat the substrate 2811 in the quartz tube 2901 to a desired temperature. Alternatively, the heating means 2903 may heat the gas which is supplied from the gas supply source 2801. With the use of the microwave treatment apparatus 2900, the substrate 2811 can be subjected to heat treatment and microwave treatment at the same time. Alternatively, the substrate 2811 can be heated and then subjected to microwave treatment. Alternatively, the substrate 2811 can be subjected to microwave treatment and then heat treatment.

All of the substrate 2811_1 to the substrate 2811_n may be substrates to be treated where a semiconductor device or a storage device is to be formed, or some of the substrates may be dummy substrates. For example, the substrate 2811_1 and the substrate 2811_n may be dummy substrates, and the substrate 2811_2 to the substrate 2811_n−1 may be substrates to be treated. Alternatively, the substrate 2811_1, the substrate 2811_2, the substrate 2811_n−1, and the substrate 2811_n may be dummy substrates, and the substrate 2811_3 to the substrate 2811_n−2 may be substrates to be treated. A dummy substrate is preferably used, in which case a plurality of substrates to be treated can be uniformly treated at the time of microwave treatment or heat treatment and a variation between the substrates to be treated can be reduced. For example, a dummy substrate is preferably placed over the substrate to be treated which is the closest to the high-frequency generator 2803 and the waveguide 2804, in which case the substrate to be treated is inhibited from being directly exposed to a microwave.

With the use of the above-described manufacturing apparatus, the quality of a film or the like can be modified while the entry of impurities into an object is inhibited.

### <Modification Example of Semiconductor Device>

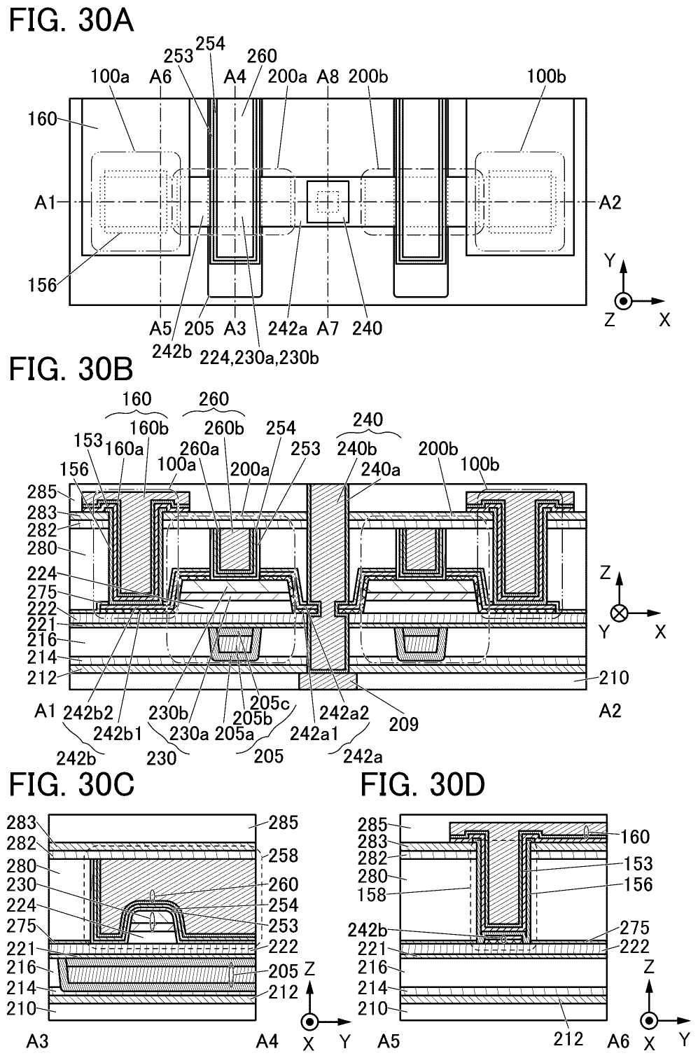

Examples of the semiconductor device of one embodiment of the present invention are described below with reference to FIG. 30A to FIG. 30D.

FIG. 30A is a top view of the semiconductor device. FIG. 30B is a cross-sectional view corresponding to a portion indicated by the dashed-dotted line A1-A2 in FIG. 30A. FIG. 30C is a cross-sectional view corresponding to a portion indicated by the dashed-dotted line A3-A4 in FIG. 30A. FIG. 30D is a cross-sectional view corresponding to a portion indicated by the dashed-dotted line A5-A6 in FIG. 30A. For clarity of the drawing, some components are omitted in the top view of FIG. 30A.

Note that in the semiconductor device illustrated in FIG. 30A to FIG. 30D, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

The semiconductor device illustrated in FIG. 30A to FIG. 30D is a modification example of the semiconductor device illustrated in FIG. 1A to FIG. 1D. The semiconductor device illustrated in FIG. 30A to FIG. 30D differs from the semiconductor device illustrated in FIG. 1A to FIG. 1D in including an insulator 283 and an insulator 221.

The insulator 283 is provided between the insulator 282 and the insulator 285. In this case, part of the conductor 156 and part of the insulator 153 are in contact with the top surface of the insulator 283. As the insulator 283, an insulator having a function of inhibiting diffusion of hydrogen is preferably used. This can inhibit diffusion of hydrogen into the transistor 200 from above the insulator 283. As the insulator 283, an insulator that can be used as the insulator 275 described above may be used. For example, a film of silicon nitride formed by a sputtering method is used for the insulator 283. When the insulator 283 is formed by a sputtering method, a high-density silicon nitride film can be formed. As the insulator 283, a film of silicon nitride formed by a PEALD method or a CVD method may be stacked over a film of silicon nitride formed by a sputtering method.

When the insulator 282, which has a function of capturing impurities such as hydrogen, is provided in contact with the insulator 280 in a region sandwiched between the insulator 212 and the insulator 283, impurities such as hydrogen included in the insulator 280 and the like can be captured and the amount of hydrogen in the region can be constant. Aluminum oxide having an amorphous structure is particularly preferably used for the insulator 282, in which case hydrogen can sometimes be captured or fixed more effectively. Accordingly, the transistor 200 and the semiconductor device which have favorable characteristics and high reliability can be manufactured.

Although FIG. 30A to FIG. 30D illustrate the transistor 200 having a structure in which the insulator 283 is provided to have a single-layer structure, the present invention is not limited thereto. For example, the insulator 283 may be provided to have a stacked-layer structure of two or more layers.

For example, in the case where the insulator 283 has a stacked-layer structure of two layers, a film of silicon nitride may be formed by a sputtering method as the lower layer of the insulator 283, and a film of silicon nitride may be formed by an ALD method as the upper layer of the insulator 283. By using a sputtering method that does not need to use a molecule containing hydrogen as a film formation gas, the hydrogen concentration in the lower layer of the insulator 283 can be reduced. Furthermore, in the case where a pinhole, disconnection, or the like is formed in the film formed by a sputtering method, a portion overlapping with the pinhole, the disconnection, or the like can be filled with the film formed by an ALD method with excellent coverage.

Note that in the case where the insulator 283 has a stacked-layer structure of two layers, part of the top surface of the upper layer of the insulator 283 is removed in some cases. The boundary between the upper layer and the lower layer of the insulator 283 is difficult to detect clearly in some cases.

The insulator 221 is provided between the insulator 222 and each of the insulator 216 and the conductor 205. The insulator 221 preferably has a function of inhibiting diffusion of hydrogen. This can inhibit diffusion of hydrogen into the transistor 200 from below the insulator 221. Note that the insulator 221 can also function as the insulator 212. In such a case, the structure without the insulator 212 enables simplification of the manufacturing process and the improvement in productivity of the semiconductor device.

As the insulator 221, an insulator that can be used as the insulator 275 described above may be used. For the insulator 221, a film of silicon nitride formed by an ALD method (especially a PEALD method) is preferably used, for example. When formed by an ALD method, the insulator 221 can have favorable coverage even when unevenness is formed by the insulator 216 and the conductor 205. This can inhibit formation of a pinhole, disconnection, or the like in the insulator 222 formed over the insulator 221.

An insulator having a function of inhibiting diffusion of hydrogen may be provided between the insulator 222 and the insulator 224. This can inhibit diffusion of hydrogen into the transistor 200 from below the insulator.

As illustrated in FIG. 30B and FIG. 30C, the conductor 205 may have a three-layer structure of the conductor 205a, the conductor 205b, and a conductor 205c. The conductor 205c is provided in contact with the top surface of the conductor 205b. The side surface of the conductor 205c may be in contact with the conductor 205a. The top surface of the conductor 205c and the uppermost portion of the conductor 205a may be level or substantially level with each other.

Like the conductor 205a, the conductor 205c is preferably formed using a conductive material having a function of inhibiting diffusion of hydrogen. In that case, since the conductor 205b can be surrounded by the conductor 205a and the conductor 205c, impurities such as hydrogen included in the conductor 205b can be prevented from diffusing into the oxide 230 through the insulator 216, the insulator 224, and the like. When a conductive material having a function of inhibiting diffusion of oxygen is used for the conductor 205a and the conductor 205c, the conductivity of the conductor 205b can be inhibited from being lowered because of oxidation.

A change in electrical characteristics of an OS transistor such as the transistor 200 due to exposure to radiation is small, i.e., an OS transistor is highly resistant to radiation; thus, an OS transistor can be suitably used even in an environment where radiation might enter. For example, OS transistors can be suitably used in outer space. Specifically, OS transistors can be used as transistors included in semiconductor devices provided in a space shuttle, an artificial satellite, a space probe, and the like. Examples of radiation include X-rays and a neutron beam. Outer space refers to, for example, space at an altitude greater than or equal to 100 km, and outer space in this specification may also include thermosphere, mesosphere, and stratosphere.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in semiconductor devices provided in remote control robots that are controlled remotely in demolishment of a reactor facility, taking out of a nuclear fuel or a fuel debris, a field investigation on a space with a large amount of radioactive substance, and the like.

According to one embodiment of the present invention, a novel transistor can be provided. Alternatively, a semiconductor device that can be miniaturized or highly integrated can be provided. Alternatively, a semiconductor device with favorable frequency characteristics can be provided. Alternatively, a semiconductor device with high operation speed can be provided. Alternatively, a semiconductor device with a small variation in transistor characteristics can be provided. Alternatively, a semiconductor device having favorable electrical characteristics can be provided. Alternatively, a semiconductor device with favorable reliability can be provided. Alternatively, a semiconductor device with a high on-state current can be provided. Alternatively, a semiconductor device with a high field-effect mobility can be provided. Alternatively, a semiconductor device with low power consumption can be provided.

The semiconductor device including the transistor 200 and the capacitor 100 and described in this embodiment can be used as a memory cell of a storage device. The transistor 200 is an OS transistor. Since the transistor 200 has a low off-state current, a storage device that uses the transistor 200 can retain stored contents for a long time. In other words, the storage device does not require refresh operation or has extremely low frequency of the refresh operation, which leads to a sufficient reduction in power consumption of the storage device. The transistor 200 has high frequency characteristics and thus enables the storage device to perform reading and writing at high speed.

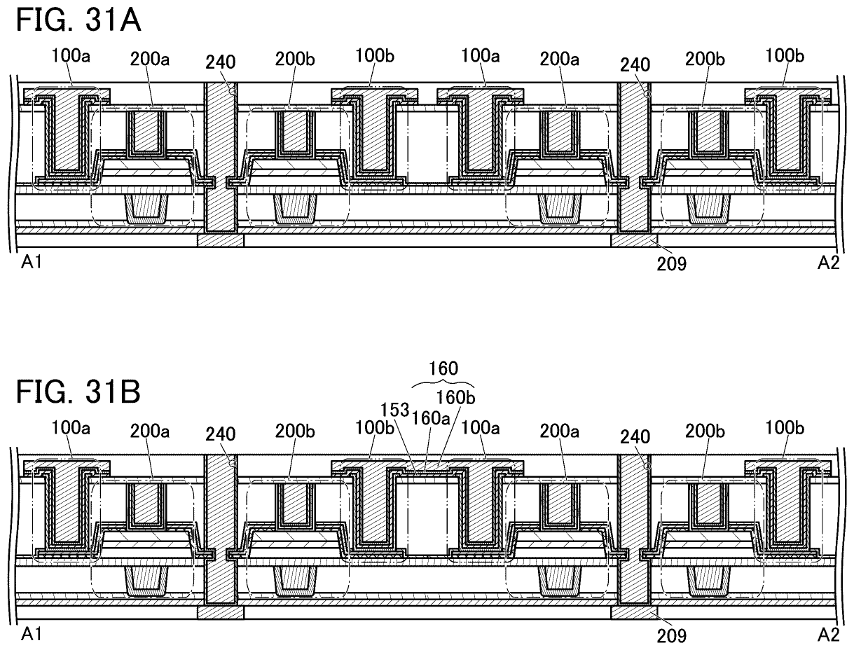

When the semiconductor devices each of which includes the transistor 200 and the capacitor 100 and each of which can be used as a memory cell are arranged in a matrix, a memory cell array can be formed. As an example of the memory cell array, FIG. 31A illustrates an example in which a plurality of the memory cells are arranged in the A1-A2 direction.

Although FIG. 31A illustrates a structure in which the conductor 160 of the capacitor 100a and the conductor 160 of the capacitor 100b that are adjacent to each other are separated, the present invention is not limited thereto. For example, as illustrated in FIG. 31B, a structure may be employed in which the conductor 160 of the capacitor 100a and the conductor 160 of the capacitor 100b that are adjacent to each other are integrated. In that case, the insulator 153 of the capacitor 100a and the insulator 153 of the capacitor 100b that are adjacent to each other may be integrated.

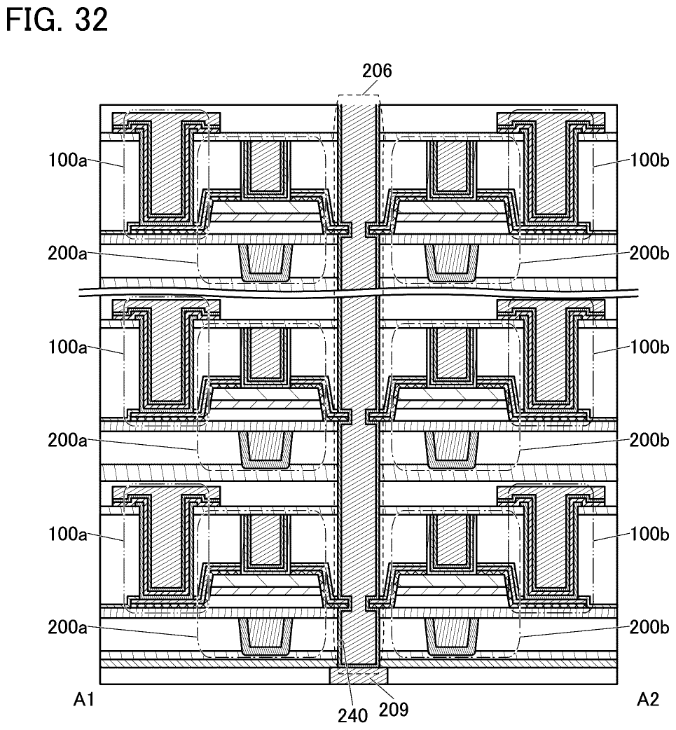

Furthermore, the memory cells may be stacked instead of being arranged over a plane. FIG. 32 is a cross-sectional view of a structure in which a plurality of layers each including the above memory cells are stacked. In this case, it can be said that the storage device includes a plurality of layers each including the memory cells, the memory cells each include the transistor 200 and the capacitor 100, and the plurality of layers are stacked. Alternatively, it can be said that the storage device includes a plurality of layers each including at least two memory cells and the plurality of layers are stacked. Here, the memory cell including the transistor 200a and the capacitor 100a is referred to as a first memory cell, and the memory cell including the transistor 200b and the capacitor 100b is referred to as a second memory cell in some cases.

Although FIG. 32 illustrates the structure in which the plurality of layers each including the memory cells are stacked, one embodiment of the present invention is not limited thereto. For example, a plurality of layers each including the memory cell array illustrated in FIG. 31A or FIG. 31B may be stacked. In that case, it can be said that the storage device includes a plurality of layers each including the memory cell array, the memory cell array is provided with memory cells each including the transistor 200 and the capacitor 100, and the plurality of layers are stacked.

As illustrated in FIG. 32, each of the plurality of layers included in the storage device includes the opening 206. Specifically, each of the plurality of layers included in the storage device includes the opening 206 between the first memory cell and the second memory cell. More specifically, each of the plurality of layers included in the storage device includes the opening 206 between the transistor 200a and the transistor 200b. The openings 206 included in the plurality of layers include a region where the openings 206 overlap with each other. Since the openings 206 included in the plurality of layers include the region where the openings 206 overlap with each other, the openings 206 included in the plurality of layers can be formed at a time. Accordingly, the manufacturing process of the storage device can be simplified, and the productivity can be improved.

The conductor 240 is located in the opening 206 included in each of the plurality of layers. Here, the conductor 240 is electrically connected to the transistor 200a and the transistor 200b included in each of the plurality of layers. Note that in this embodiment, the conductor 242a is shared by the transistor 200a and the transistor 200b. Thus, it can be said that the conductor 240 is electrically connected to the conductor 242a included in each of the plurality of layers. When the contact area between the conductor 240 and the conductor 242 is increased as described above in each of the plurality of layers, the contact resistance can be reduced. As a result, the storage device of the present invention can have increased operation speed and reduced power consumption.

Although not illustrated, an insulator is preferably provided over the conductor 240 in the uppermost one of the plurality of layers. As the insulator, for example, an insulator that can be used as the insulator 285, the insulator 282, or the like may be provided.

When a plurality of memory cells are stacked as illustrated in FIG. 32, cells can be integrally placed without increasing the footprint of the memory cell arrays. In other words, a 3D memory cell array can be formed.

The storage device including the memory cell array will be described in detail in a later embodiment.

At least part of the structure, method, and the like described in this embodiment can be implemented in an appropriate combination with any of those in the other embodiments described in this specification.

### Embodiment 2

In this embodiment, specific structure examples of storage devices using the semiconductor device described in the above embodiment as memory cells are described. In this embodiment, structure examples of storage devices in which a layer including a functional circuit having functions of amplifying and outputting a data potential retained in a memory cell is provided between stacked layers including memory cells are described.

### [Structure Example of Storage Device]

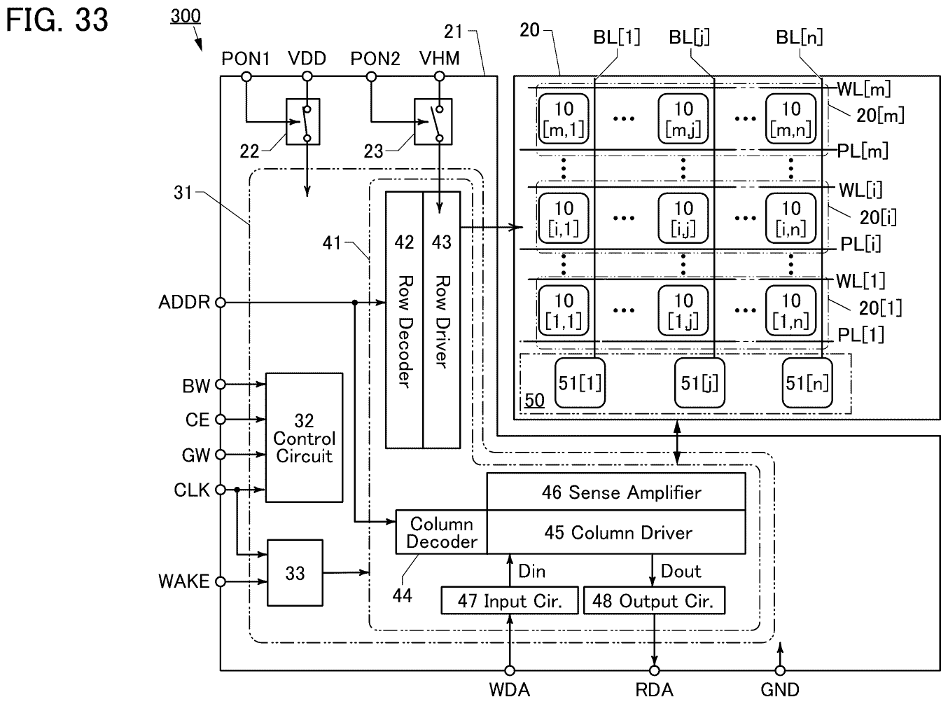

FIG. 33 is a block diagram illustrating a structure example of a storage device 300 of one embodiment of the present invention. The storage device 300 illustrated in FIG. 33 includes a driver circuit 21 and a memory array 20. The memory array 20 includes a functional layer 50 including a plurality of memory cells 10 and a plurality of functional circuits 51.

FIG. 33 illustrates an example in which the memory array 20 includes the plurality of memory cells 10 arranged in a matrix of m rows and n columns (each of m and n is an integer greater than or equal to 2). The functional circuit 51 is provided for each of the wirings BL functioning as bit lines, for example. The plurality of functional circuits 51 corresponding to n of the wirings BL are provided in the example illustrated in FIG. 33.

In FIG. 33, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is referred to as a memory cell 10[i,j]. Note that in this embodiment and the like, “i+a” (a is a positive or negative integer) is not below 1 and does not exceed m. Similarly, “j+a” is not below 1 and does not exceed n.

The memory array 20 includes m of the wirings WL extending in the row direction, m of the wirings PL extending in the row direction, and the n wirings BL extending in the column direction. In this embodiment and the like, the first (first row) wiring WL is referred to as a wiring WL[1] and the m-th (m-th row) wiring WL is referred to as a wiring WL[m]. Similarly, the first (first row) wiring PL is referred to as a wiring PL[1] and the m-th (m-th row) wiring PL is referred to as a wiring PL[m]. Similarly, the first (first column) wiring BL is referred to as a wiring BL[1] and the n-th (n-th column) wiring BL is referred to as a wiring BL[n].

The plurality of memory cells 10 provided in the i-th row are electrically connected to the wiring WL in the i-th row (wiring WL[i]) and the wiring PL in the i-th row (wiring PL[i]). The plurality of memory cells 10 provided in the j-th column are electrically connected to the wiring BL in the j-th column (wiring BL[j]).

A DOSRAM (registered trademark) (Dynamic Oxide Semiconductor Random Access Memory) can be used for the memory array 20. A DOSRAM is a RAM including a 1T (transistor) 1C (capacitor) type memory cell and refers to a memory in which an access transistor is an OS transistor. An OS transistor has an extremely low current that flows between a source and a drain in an off state, that is, a leakage current. A DOSRAM can retain charge corresponding to data retained in a capacitor for a long time by turning off an access transistor (a non-conduction state). For this reason, the refresh operation frequency of a DOSRAM can be lower than that of a DRAM formed with a transistor containing silicon in its channel formation region (hereinafter also referred to as “Si transistor”). As a result, power consumption can be reduced.

The memory cells 10 can be provided in stacked layers by stacking OS transistors as described in Embodiment 1 and the like. For example, in the memory array 20 illustrated in FIG. 33, a plurality of memory arrays 20[1] to 20[m] can be provided in stacked layers. When the memory arrays 20[1] to 20[m] included in the memory array 20 are provided in a direction perpendicular to a surface of the substrate provided with the driver circuit 21, the memory density of the memory cells 10 can be increased. The memory array 20 can be formed by repeating the same manufacturing process in the perpendicular direction. The manufacturing cost of the memory array 20 in the storage device 300 can be reduced.

The wiring BL functions as a bit line for writing and reading data. The wiring WL functions as a word line for controlling on and off states (conduction and non-conduction states) of an access transistor serving as a switch. The wiring PL has a function of supplying a back gate potential to a back gate of the OS transistor, which is an access transistor, in addition to a function of a constant potential line connected to a capacitor. Note that a wiring CL (not illustrated) can be separately provided as a wiring for transmitting the back gate potential.

The memory cell 10 included in each of the memory arrays 20[1] to 20[m] is connected to the functional circuit 51 through the wiring BL. The wiring BL can be provided in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced, so that power consumption and signal delays can be reduced. Moreover, even when the capacitance of the capacitors included in the memory cells 10 is reduced, operation is possible.

The functional circuit 51 has functions of amplifying a data potential retained in the memory cell 10 and outputting the amplified data potential to a sense amplifier 46 included in the driver circuit 21 through a wiring GBL (not illustrated) described later. With this structure, a slight difference in the potential of the wiring BL can be amplified at the time of data reading. Like the wiring BL, the wiring GBL can be provided in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced, so that power consumption and signal delays can be reduced.

Note that the wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductor provided in contact with the region functioning as the source or the drain in the semiconductor layer of the transistor included in the memory cell 10. In other words, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, the resistance and parasitic capacitance between the driver circuit 21 and the memory array 20 are reduced, so that power consumption and signal delays can be reduced. In addition, the storage device 300 can be downsized.

The functional circuit 51 can be provided in any desired position, e.g., over a circuit that is formed using Si transistors, in a manner similar to that of the memory arrays 20[1] to 20[m] when the functional circuit 51 is formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized, so that the storage device 300 can be downsized.

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the storage device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 300. For example, the control circuit performs a logical operation on the signal CE, the signal GW, and the signal BW to determine an operation mode (e.g., a writing operation or a reading operation) of the storage device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 is a circuit that outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the storage device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 300, a high power supply voltage is VDD and a low power supply voltage is GND (a ground potential). In addition, VHM is a high power supply voltage used to set a word line at a high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 33 but can be more than one. In that case, a power switch is provided for each power domain.

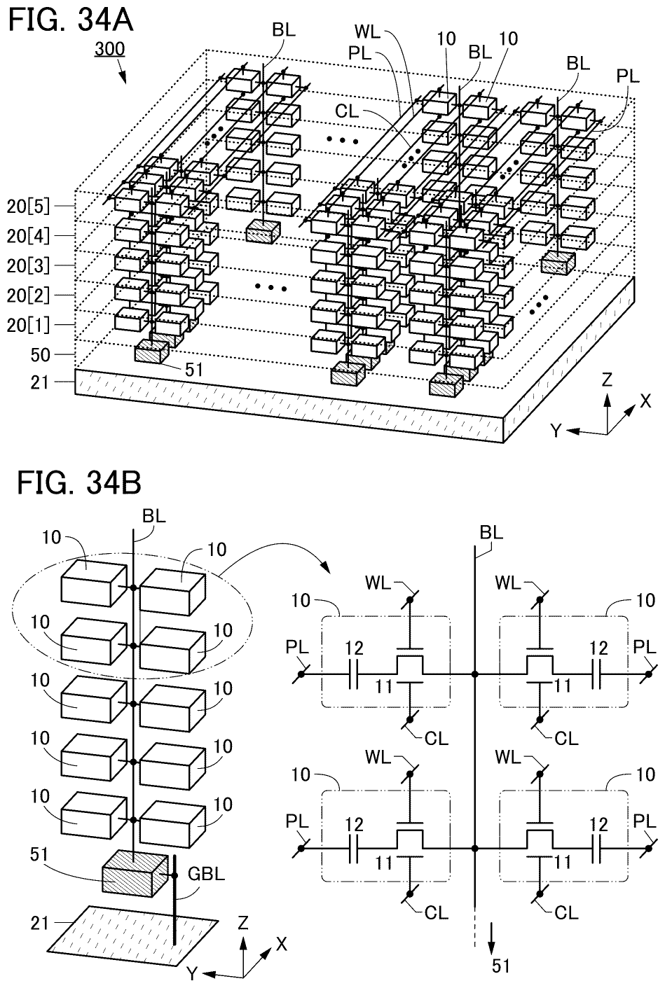

In the memory array 20 including the memory arrays 20[1] to 20[m] (m is an integer greater than or equal to 2) and the functional layer 50, a plurality of layers of the memory arrays can be provided over the driver circuit 21 to overlap with the driver circuit 21. Stacking the plurality of layers of the memory arrays 20 can increase the memory density of the memory cells 10. FIG. 34A is a perspective view of the storage device 300 in which five layers of the memory arrays 20[1] to 20[5] (m=5) and the functional layer 50 are provided over the driver circuit 21 to overlap with the driver circuit 21.

In FIG. 34A, the memory array 20 provided in the first layer is denoted as the memory array 20[1], the memory array 20 provided in the second layer is denoted as the memory array 20[2], and the memory array 20 provided in the fifth layer is denoted as the memory array 20[5]. FIG. 34A also illustrates the wiring WL, the wiring PL, and the wiring CL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not illustrated.

FIG. 34B is a schematic view for describing a structure example of the functional circuit 51, which is connected to the wiring BL, and the memory cells 10 included in the memory arrays 20[1] to 20[5], which are connected to the wiring BL, illustrated in FIG. 34A. FIG. 34B illustrates the wiring GBL provided between the functional circuit 51 and the driver circuit 21. Note that a structure in which a plurality of memory cells (memory cells 10) are electrically connected to one of the wirings BL is also referred to as “memory string”. In the drawings, the wiring GBL in some cases is represented by a bold line for increasing visibility.

FIG. 34B illustrates an example of a circuit structure of the memory cell 10 connected to the wiring BL. The memory cell 10 includes a transistor 11 and a capacitor 12. As for the transistor 11, the capacitor 12, and the wirings (e.g., BL and WL), for example, the wiring BL[1] and the wiring WL[1] are referred to as the wiring BL and the wiring WL in some cases.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL. A back gate of the transistor 11 is connected to the wiring CL.

The wiring PL is a wiring for supplying a constant potential for retaining the potential of the capacitor 12. The wiring CL is a constant potential for controlling the threshold voltage of the transistor 11. The wiring PL and the wiring CL may have the same potential. In that case, the number of wirings connected to the memory cell 10 can be reduced by connecting the two wirings.

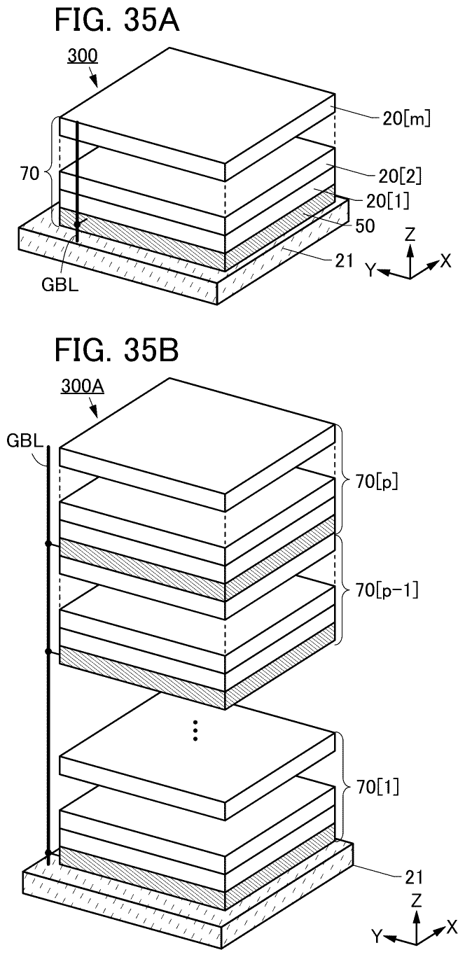

The wiring GBL illustrated in FIG. 34B is provided to electrically connect the driver circuit 21 and the functional layer 50. FIG. 35A is a schematic view of the storage device 300 in which the functional circuit 51 and the memory arrays 20[1] to 20[m] are regarded as a repeating unit 70. Note that although FIG. 35A illustrates one of the wirings GBL, the wiring GBL is provided as appropriate depending on the number of functional circuits 51 provided in the functional layer 50.

Note that the wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. In other words, the wiring GBL is a wiring for electrically connecting the driver circuit 21 and one of the source and the drain of the transistor included in the functional circuit 51 in the functional layer 50 in the perpendicular direction.

The repeating unit 70 including the functional circuit 51 and the memory arrays 20[1] to 20[m] may have a stacked-layer structure. A storage device 300A of one embodiment of the present invention can include repeating units 70[1] to 70[p] (p is an integer greater than or equal to 2) as illustrated in FIG. 35B. The wiring GBL is connected to the functional layers 50 included in the repeating units 70. The wiring GBL is provided as appropriate depending on the number of functional circuits 51.

In one embodiment of the present invention, OS transistors are provided in stacked layers and a wiring functioning as a bit line is provided in the direction perpendicular to the surface of the substrate provided with the driver circuit 21. Since the wiring provided to extend from the memory array 20 and function as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the storage device 300 can be downsized. Moreover, even when the capacitance of the capacitors 12 included in the memory cells 10 is reduced, operation is possible.

### [Structure Examples of Memory Array 20 and Functional Circuit 51]

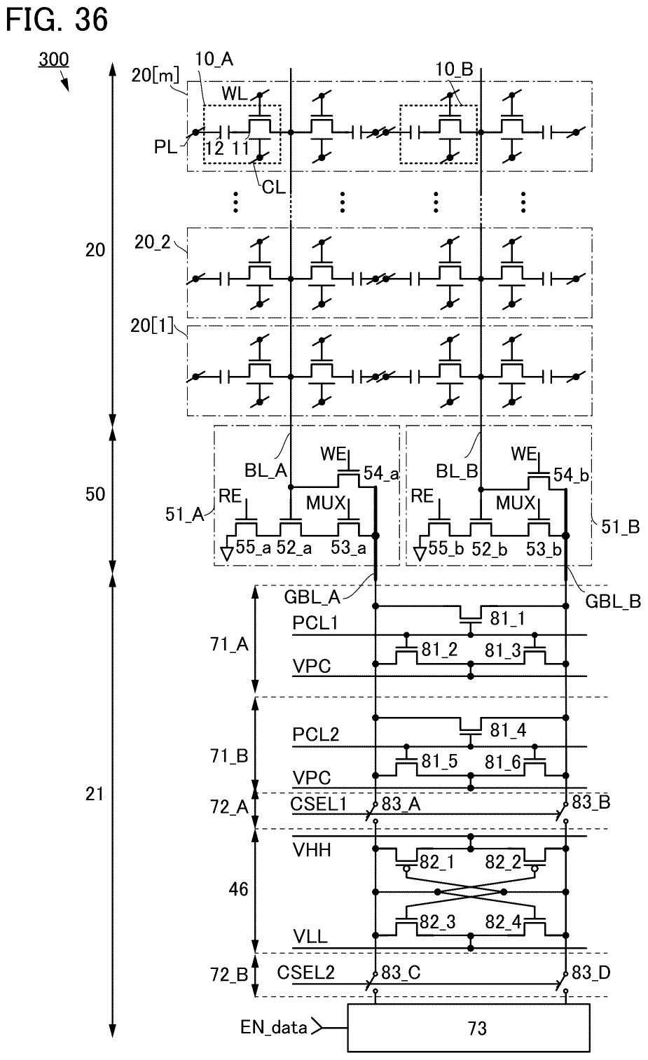

A structure example of the functional circuit 51 and structure examples of the memory array 20 and the sense amplifier 46 included in the driver circuit 21, which are described with reference to FIG. 33 to FIG. 35, are described with reference to FIG. 36. FIG. 36 illustrates the driver circuit 21 connected to the wirings GBL (GBL_A and GBL_B) connected to the functional circuits 51 (51_A and 51_B) connected to the memory cells 10 (10_A and 10_B) connected to different wirings BL (BL_A and BL_B). FIG. 36 also illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuits 51_A and 51_B, transistors 52_a, 52_b, 53_a, 53_b, 54_a, 54_b, 55_a, and 55_b are illustrated. The transistors 52_a, 52_b, 53_a, 53_b, 54_a, 54_b, 55_a, and 55_b illustrated in FIG. 36 are OS transistors like the transistor 11 included in the memory cell 10. The functional layer 50 including the functional circuits 51 can be provided in stacked layers like the memory arrays 20[1] to 20[m].

The wirings BL_A and BL_B are connected to gates of the transistors 52_a and 52_b. Ones of sources and drains of the transistors 53_a, 53_b, 54_a, and 54_b are connected to the wirings GBL_A and GBL_B. The wirings GBL_A and GBL_B are provided in the perpendicular direction like the wirings BL_A and BL_B and connected to the transistors included in the driver circuit 21. As illustrated in FIG. 36, control signals WE, RE, and MUX are supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 36 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to 81_3. The precharge circuit 71_A is a circuit for precharging the wirings BL_A and BL_B with an intermediate potential VPC corresponding to a potential VDD/2 between VDD and VSS in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistors 82_1 and 82_2 and the n-channel transistors 82_3 and 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged by selecting the memory cells 10_A and 10_B are changed, and the potentials of the wiring GBL_A and the wiring GBL_B are set to the high power supply potential VDD or the low power supply potential VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on and off states of the switch circuit 72_A are switched under the control of a switch signal CSEL1. In the case where the switches 83_A and 83_B are n-channel transistors, the switches 83_A and 83_B are turned on and off when the switch signal CSEL1 is at a high level and a low level, respectively. The switch circuit 72_B is a circuit for controlling electrical continuity between the write/read circuit 73 and the bit line pair connected to the sense amplifier 46. The on and off states of the switch circuit 72_B are switched under the control of a switching signal CSEL2. The switches 83_C and 83_D are similar to the switches 83_A and 83_B.

As illustrated in FIG. 36, the storage device 300 can have a structure where the memory cell 10, the functional circuit 51, and the sense amplifier 46 are connected to each other through the wiring BL and the wiring GBL provided in the perpendicular direction which is the shortest distance. Even with addition of the functional layer 50 including transistors included in the functional circuit 51, the load of the wiring BL is reduced, whereby the writing time can be shortened and data reading can be facilitated.

As illustrated in FIG. 36, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can function as a sense amplifier formed with OS transistors. With this structure, a slight difference in the potential of the wiring BL can be amplified at the time of reading to drive the sense amplifier 46 formed using Si transistors.

### [Operation Example of Memory Cell 20, Functional Circuit 51, and Sense Amplifier 46]

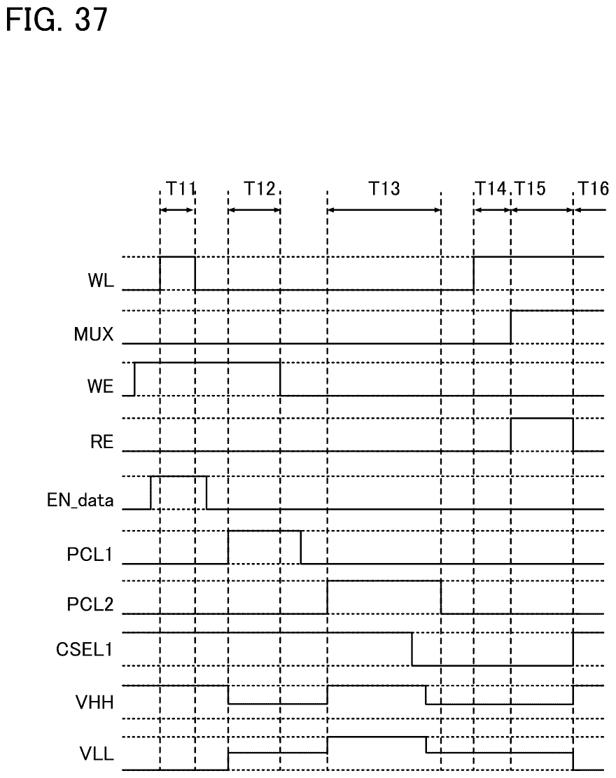

FIG. 37 is a timing chart for describing the operation of the circuit diagram in FIG. 36. In the timing chart in FIG. 37, a period T11 corresponds to a period for describing write operation, a period T12 corresponds to a period for describing precharge operation of the wiring BL, a period T13 corresponds to a period for describing precharge operation of the wiring GBL, a period T14 corresponds to a period for describing charge sharing operation, a period T15 corresponds to a period for describing standby operation for reading, and a period T16 corresponds to a period for describing read operation.

In the period T11, the potential of the wiring WL connected to the gate of the transistor 11 included in the memory cell 10 to which a data signal is desired to be written is set to a high level. At this time, the control signal WE and the signal EN_data are set to a high level, and the data signal is written to the memory cell through the wiring GBL and the wiring BL.

In the period T12, in order to precharge the wiring BL, the precharge line PCL1 is set to a high level in a state where the control signal WE is at a high level. The wiring BL is precharged with a precharge potential. In the period T12, the wiring VHH and the wiring VLL through which a power supply voltage is supplied to the sense amplifier 46 are both preferably set to VDD/2 in order to suppress power consumption due to a flow-through current.

In the period T13, in order to precharge the wiring GBL, the precharge line PCL2 is set to a high level. The wiring GBL is precharged with a precharge potential. In the period T13, the potentials of the wiring VHH and the wiring VLL are both set to VDD, so that the wiring GBL with a large load can be precharged in a short time.

In the period T14, in order to cause charge sharing for balancing charge retained in the memory cell 10 and charge with which the bit line BL is precharged, the potential of the wiring WL is set to a high level. In the period T14, the potentials of the wiring VHH and the wiring VLL through which a power supply voltage is supplied to the sense amplifier 46 are both preferably set to VDD/2 in order to suppress power consumption due to a flow-through current.

In the period T15, the control signal RE and the control signal MUX are set to a high level. A current flows through the transistor 52 in accordance with the potential of the wiring BL, and the potential of the wiring GBL varies in accordance with the current amount. The switch signal CSEL1 is set to a low level so that the variation in the potential of the wiring GBL is not affected by the sense amplifier 46. The wiring VHH or the wiring VLL is similar to that in the period T14.

In the period T16, the switch signal CSEL1 is set to a high level and the variation in the potential of the wiring GBL is amplified by the bit line pair connected to the sense amplifier 46; thus, the data signal written to the memory cell is read.

### [Structure Example of Functional Circuit]

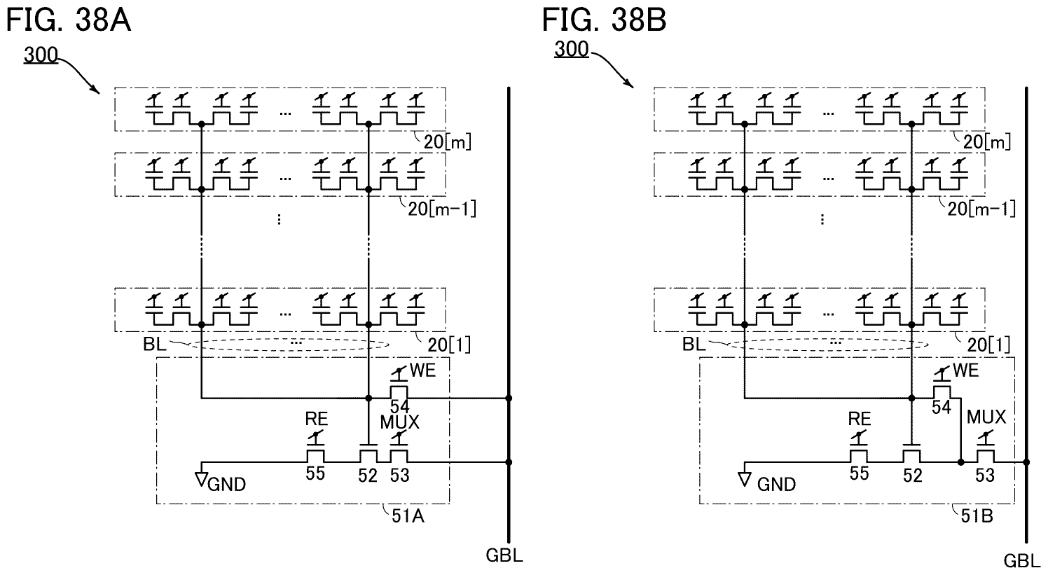

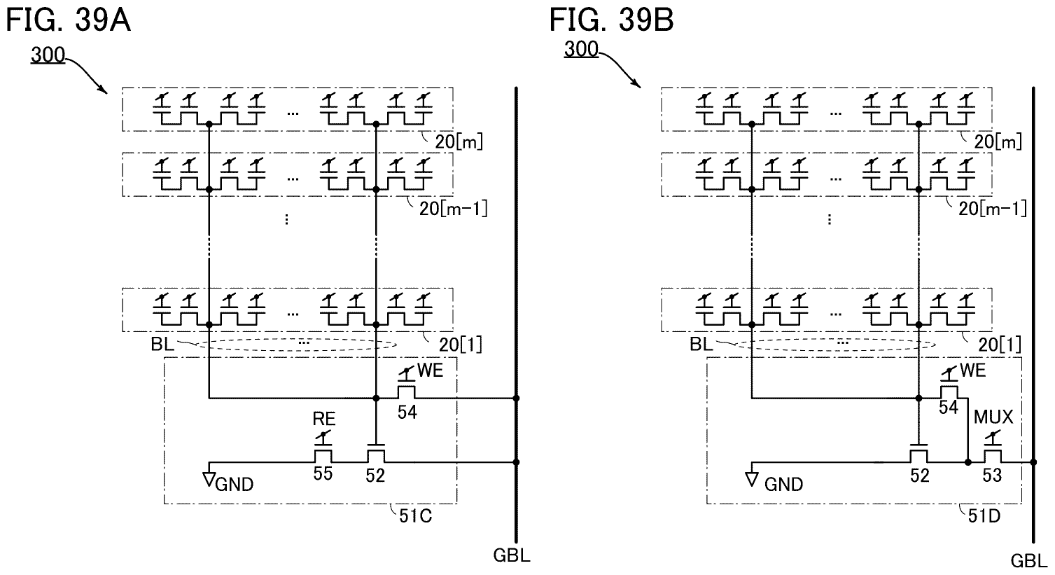

Next, specific structure examples of the functional circuit 51 functioning as the sense amplifier formed with OS transistors included in the functional layer 50 are described with reference to FIG. 38A, FIG. 38B, FIG. 39A, and FIG. 39B.

FIG. 38A illustrates a functional circuit 51A corresponding to the functional circuit 51_A or 51_B illustrated in FIG. 36. The functional circuit 51A illustrated in FIG. 38A includes transistors 52 to 55. Each of the transistors 52 to 55 can be an OS transistor and is illustrated as an n-channel transistor.

The transistor 52 is a transistor forming a source follower for amplifying the potential of the wiring GBL to a potential corresponding to the potential of the wiring BL in a period when the data signals are read from the memory cells 10. The transistor 53 is a transistor functioning as a switch where the selection signal MUX is input to a gate and electrical continuity between a source and a drain is controlled in accordance with the selection signal MUX. The transistor 54 is a transistor functioning as a switch where the write control signal WE is input to a gate and electrical continuity between a source and a drain is controlled in accordance with the write control signal WE. The transistor 55 is a transistor functioning as a switch where the read control signal RE is input to a gate and electrical continuity between a source and a drain is controlled in accordance with the read control signal RE. Note that the ground potential GND, which is a fixed potential, is supplied to the source side of the transistor 55, for example.

Note that modification examples illustrated in FIG. 38B, FIG. 39A, and FIG. 39B can be applied to the structure of the functional circuit 51A illustrated in FIG. 38A. A functional circuit 51B in FIG. 38B has a structure where one of the source and the drain of the transistor 54 is connected to not the wiring GBL but one of a source and a drain of the transistor 52. A functional circuit 51C in FIG. 39A corresponds to a structure where the function of the transistor 53 is performed by the driver circuit 21 and thus the transistor 53 is omitted. A functional circuit 51D in FIG. 39B corresponds to a structure where the transistor 55 is omitted.

In the semiconductor device of one embodiment of the present invention, OS transistors with an extremely low off-state current are used as the transistors provided in the memory array 20. OS transistors can be provided in stacked layers over the substrate provided with the driver circuit 21 provided with Si transistors. Therefore, OS transistors can be manufactured in the perpendicular direction by repeating the same manufacturing process, and manufacturing cost can be reduced. Furthermore, in one embodiment of the present invention, the memory density can be increased by arranging the transistors included in the memory cells 10 in not a plane direction but the perpendicular direction, whereby the storage device can be downsized.

In addition, one embodiment of the present invention is provided with the functional layer 50 including the functional circuit 51. In the functional circuit, the wiring BL is connected to the gate of the transistor 52; therefore, the transistor 52 can function as an amplifier. With this structure, a slight difference in the potential of the wiring BL can be amplified at the time of reading to drive the sense amplifier 46 formed using Si transistors. The circuit such as the sense amplifier 46 formed using Si transistors can be downsized, so that the storage device can be downsized. Moreover, even when the capacitance of the capacitors 12 included in the memory cells 10 is reduced, operation is possible.

### [Arrangement Example of Memory Cell Array]

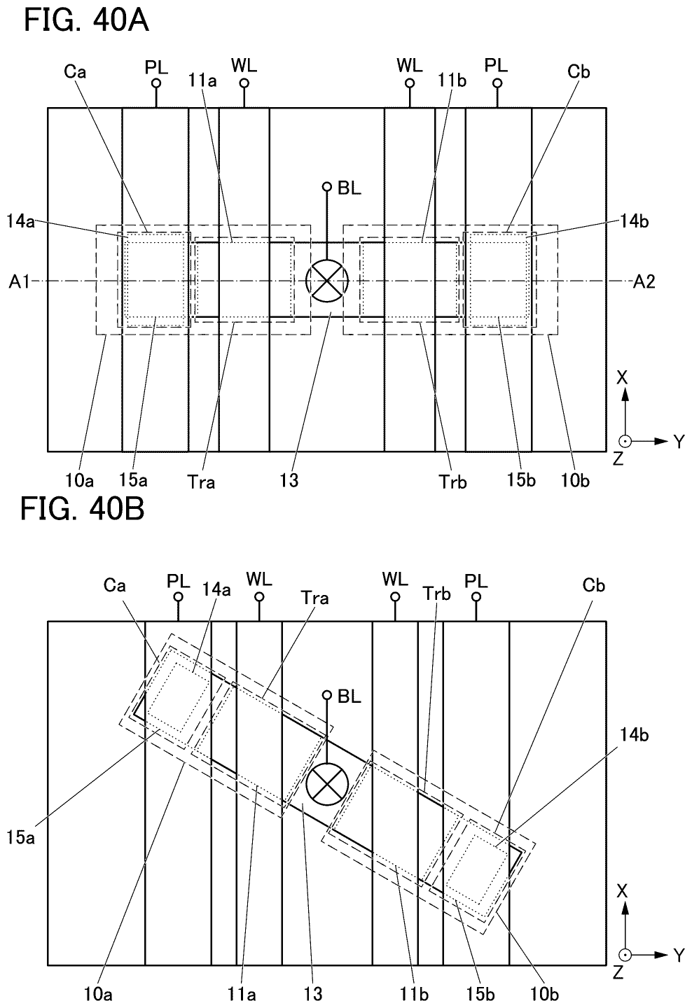

FIG. 40A is a layout diagram illustrating an arrangement example of the wirings and the semiconductor layers in the memory cells 10 described above. FIG. 40A illustrates the wiring WL and the wiring PL provided to extend in the X direction; a semiconductor layer 11a and a semiconductor layer 11b; a conductive layer 13; a conductive layer 14a and a conductive layer 14b; a conductive layer 15a and a conductive layer 15b; and the wiring BL provided to extend in the Z direction. FIG. 40A illustrates a state where each of the semiconductor layer 11a and the semiconductor layer 11b is provided to intersect with one of the wirings WL, each of the conductive layer 14a and the conductive layer 14b is provided to overlap with one of the wirings PL, and the semiconductor layer 11a and the semiconductor layer 11b are connected to one of the wirings BL through the conductive layer 13, whereby two of the memory cells 10 are arranged. Note that the semiconductor layer 11a is electrically connected to the conductive layer 14a through the conductive layer 15a. The semiconductor layer 11b is electrically connected to the conductive layer 14b through the conductive layer 15b.

For easy understanding of the invention, in some cases, the memory cell 10 including the semiconductor layer 11a is referred to as a memory cell 10a and the memory cell 10 including the semiconductor layer 11b is referred to as a memory cell 10b to distinguish the two memory cells 10 from each other.

In the memory cell 10a, the wiring WL and the conductive layer 13 are provided over the semiconductor layer 11a to overlap with the semiconductor layer 11a, and the wiring PL is provided over the conductive layer 14a, which is electrically connected to the semiconductor layer 11a, to overlap with the conductive layer 14a. The transistor Tra is provided in a region where the wiring WL and the semiconductor layer 11a overlap with each other. The capacitor Ca is provided in a region where the wiring PL and the conductive layer 14a overlap with each other. The conductive layer 13 is a conductive layer for connecting the transistor Tra to the wiring BL. Similarly, in the memory cell 10b, the wiring WL and the conductive layer 13 are provided over the semiconductor layer 11b to overlap with the semiconductor layer 11b, and the wiring PL is provided over the conductive layer 14b, which is electrically connected to the semiconductor layer 11b, to overlap with the conductive layer 14b. The transistor Trb is provided in a region where the wiring WL and the semiconductor layer 11b overlap with each other. The capacitor Cb is provided in a region where the wiring PL and the conductive layer 14b overlap with each other. The conductive layer 13 is a conductive layer for connecting the transistor Trb to the wiring BL.

Note that the transistor Tra, the transistor Trb, the capacitor Ca, and the capacitor Cb respectively correspond to the transistor 200a, the transistor 200b, the capacitor 100a, and the capacitor 100b described in Embodiment 1. The semiconductor layer 11a and the semiconductor layer 11b correspond to the oxide 230 described in Embodiment 1. The conductive layer 13 corresponds to the conductor 242a described in Embodiment 1. The conductive layer 15a and the conductive layer 15b correspond to the conductor 242b described in Embodiment 1. The conductive layer 14a and the conductive layer 14b correspond to the conductor 156 described in Embodiment 1. The wiring WL and the wiring PL respectively correspond to the conductor 260 and the conductor 160 described in Embodiment 1. Therefore, detailed description of the cross-sectional view of the memory cell 10 is similar to the description in Embodiment 1, and accordingly, the above description is to be referred to.

In the case where the memory arrays 20 with the memory cells 10 illustrated in FIG. 40A are stacked, it is preferable that the wiring PL in an upper layer and the wiring PL in a lower layer overlap with each other and the wiring WL in an upper layer and the wiring WL in a lower layer overlap with each other. That is, the layout diagrams of two layers of the memory arrays 20 that are provided to overlap with each other preferably overlap with each other. With this structure, the manufacturing process of the storage device can be simplified, and the productivity can be improved.

Although FIG. 40A illustrates a structure in which the semiconductor layer 11a, the semiconductor layer 11b, the conductive layer 13, the conductive layer 15a, and the conductive layer 15b extending in the Y direction are provided to intersect with the wiring WL and the wiring PL at right angles, one embodiment of the present invention is not limited thereto. For example, as illustrated in FIG. 40B, one end portion of the semiconductor layer 11a and one end portion of the semiconductor layer 11b that are provided to extend in the Y direction may be located to be inclined in the X direction, and the semiconductor layer 11a, the semiconductor layer 11b, the conductive layer 13, the conductive layer 15a, and the conductive layer 15b may be provided to intersect with the wiring WL and the wiring PL. With this structure, the memory density of the memory cells 10 can be further increased.

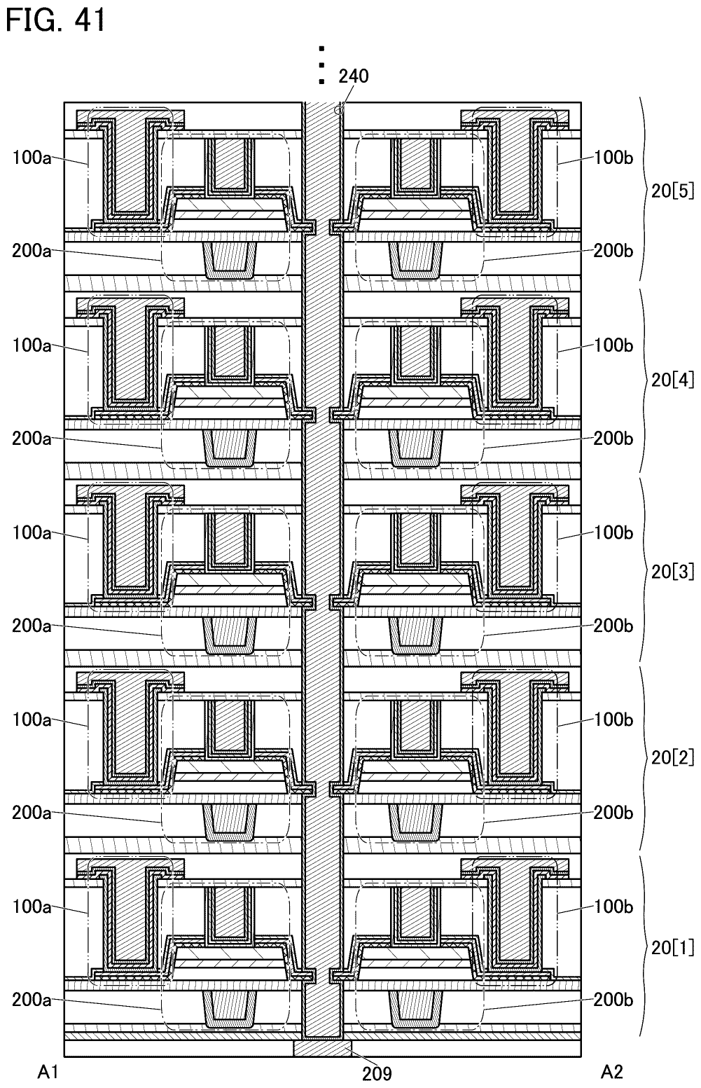

FIG. 41 is a cross-sectional view in which a cut plane including a portion along the dashed-dotted line A1-A2 in FIG. 40A is expanded to form the memory array 20[1] to the memory array 20[5], and the transistor 200 and the capacitor 100 described in the above embodiment are provided in each memory cell array.

In FIG. 41, the combination of the transistor 200a and the capacitor 100a corresponds to the memory cell 10a, and the combination of the transistor 200b and the capacitor 100b corresponds to the memory cell 10b. The conductor 260 corresponds to the wiring WL, and the conductor 160 corresponds to the wiring PL. The oxide 230 corresponds to the semiconductor layer 11a and the semiconductor layer 11b.

As illustrated in FIG. 41, the conductor 160 of the capacitor 100a in an upper layer is provided over the conductor 160 of the capacitor 100a in a lower layer such that the conductors 160 overlap with each other, and the conductor 260 of the transistor 200a in an upper layer is provided over the conductor 260 of the transistor 200a in a lower layer such that the conductors 260 overlap with each other.

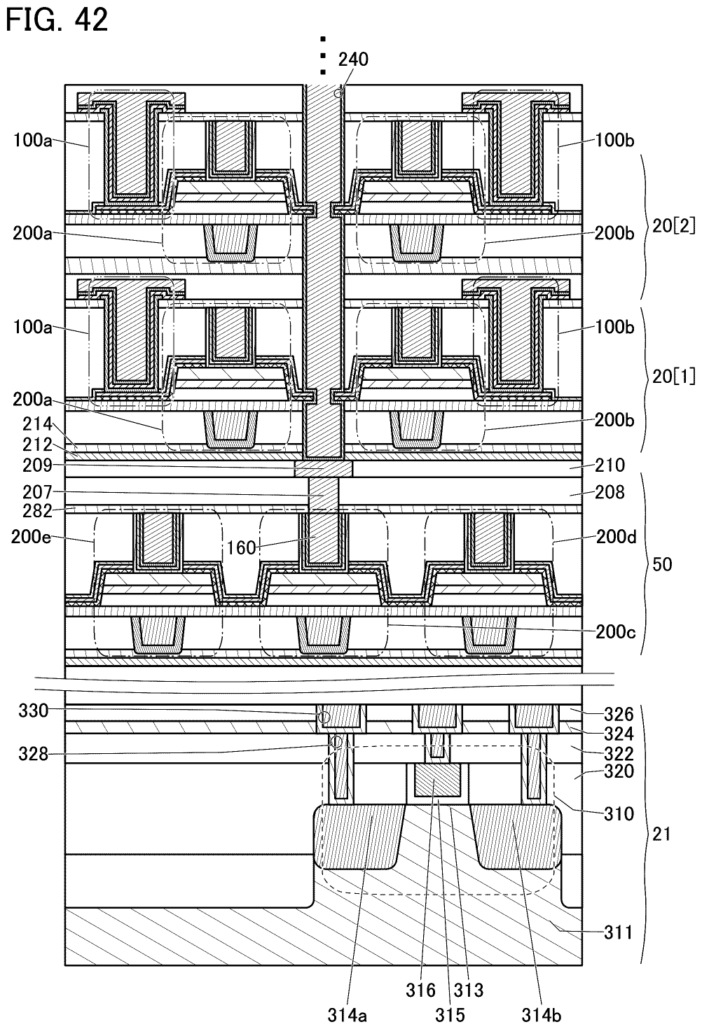

As illustrated in FIG. 42, a transistor 310 can be provided in the driver circuit 21 provided under the memory array 20[1].

The transistor 310 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 310 may be a p-channel transistor or an n-channel transistor.

Here, in the transistor 310 illustrated in FIG. 42, the semiconductor region 313 (part of the substrate 311) where a channel is formed has a protruding shape. In addition, the conductor 316 is provided to cover the side surface and the top surface of the semiconductor region 313 with the insulator 315 therebetween. Note that a material adjusting the work function may be used for the conductor 316. Such a transistor 310 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 310 illustrated in FIG. 42 is an example and the structure is not limited thereto; an appropriate transistor is used in accordance with a circuit structure or a driving method.

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 310 as interlayer films. A conductor 328, a conductor 330, and the like that are electrically connected to the capacitor 100, the transistor 200, or the conductor 240 are embedded in the insulator 320, the insulator 322, the insulator 324, and the insulator 326. Note that the conductor 328 and the conductor 330 function as plugs or wirings.

The insulators functioning as interlayer films may also function as planarization films that cover uneven shapes therebelow. For example, the top surface of the insulator 322 may be planarized by planarization treatment using a chemical mechanical polishing (CMP) method or the like to improve planarity.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material with a low relative permittivity is used for the insulator functioning as an interlayer film, parasitic capacitance generated between wirings can be reduced. Thus, a material is preferably selected depending on the function of the insulator.

For example, as the insulator 320, the insulator 322, the insulator 326, and the like, an insulator with a low relative permittivity is preferably included. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

When a transistor including an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen is used for the insulator 324, the insulator 212, the insulator 214, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 209, and the like, a single layer or stacked layers of a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

As illustrated in FIG. 35A, FIG. 35B, and the like, the functional layer 50 is provided under a plurality of the memory arrays 20. In FIG. 42, the functional layer 50 is provided between the memory array 20[1] and the driver circuit 21.

FIG. 42 illustrates transistors 200c, 200d, and 200e included in the plurality of functional circuits 51 provided in the functional layer 50. Here, the transistors 200c, 200d, and 200e have a structure similar to that of the transistor 200 described in the above embodiment. The transistors 200c, 200d, and 200e correspond to the transistors 52, 53, and 55 illustrated in FIG. 38A and the like. Like the transistors 52, 53, and 55, sources and drains of the transistors 200c, 200d, and 200e are connected in series. Note that the transistor 54 illustrated in FIG. 38A and the like is not illustrated.

An insulator 208 is provided over the insulator 280 of the functional layer 50, and a conductor 207 is provided in an opening formed in the insulator 208. An insulator similar to the insulator 210 can be provided as the insulator 208, and a conductor similar to the conductor 209 can be provided as the conductor 207.

The bottom surface of the conductor 207 is provided in contact with the top surface of the conductor 160 of the transistor 200c. The top surface of the conductor 207 is provided in contact with the bottom surface of the conductor 209. With such a structure, the conductor 240 that corresponds to the wiring BL functioning as a bit line can be electrically connected to a gate of the transistor 200c corresponding to the transistor 52.

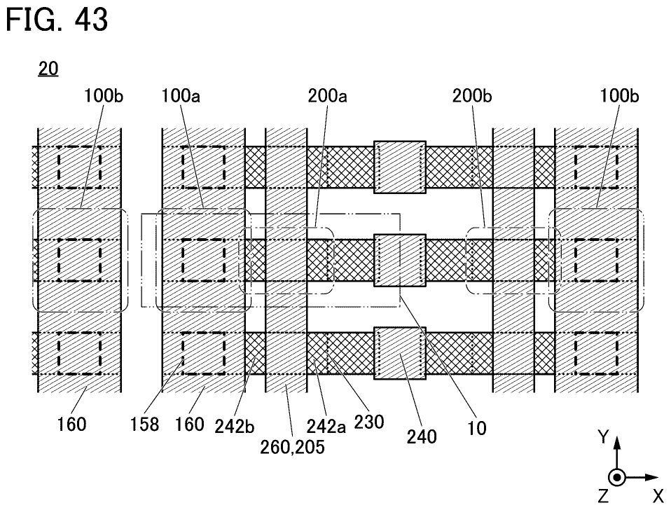

FIG. 43 illustrates an example of a layout in which the memory cells 10 are arranged in a matrix to form the memory array 20. The reference numerals in FIG. 43 correspond to the reference numerals shown in FIG. 1B and the like. In the case where the minimum feature size is nm, the size of the memory cell 10 in FIG. 43 can be 45 nm×125 nm. Since the footprint of the memory cell 10 is 0.0054 μm², the density of the memory cells 10 in the storage device of this embodiment can be 185 cells/μm².

When a plurality of the memory cell arrays and the driver circuit are stacked as described above, the storage device can be highly integrated and have a high storage capacity.

This embodiment can be combined as appropriate with any of the other embodiments and the like described in this specification.

### Embodiment 3

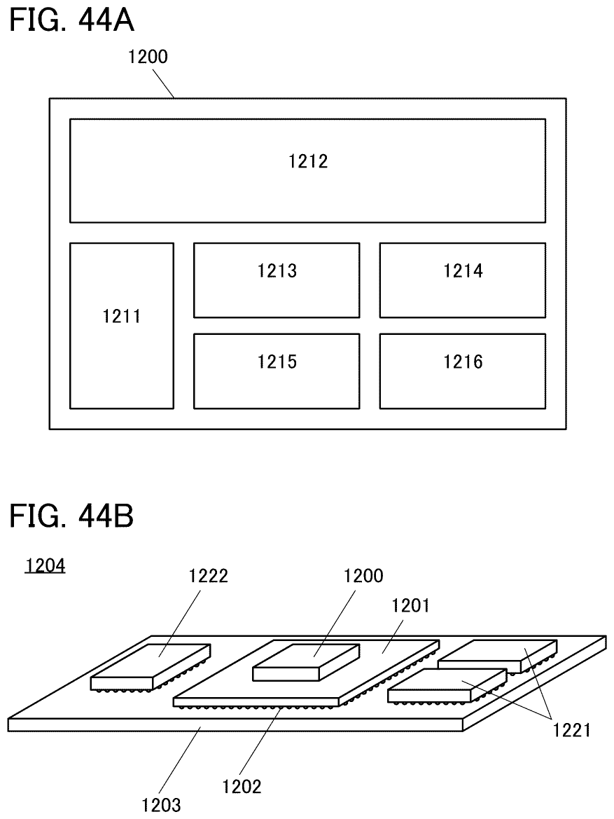

In this embodiment, an example of a chip 1200 on which the semiconductor device of the present invention is mounted is described with reference to FIG. 44A and FIG. 44B. A plurality of circuits (systems) are mounted on the chip 1200. A technique for integrating a plurality of circuits (systems) into one chip is referred to as system on chip (SoC) in some cases.

As illustrated in FIG. 44A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 44B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In that case, the DRAMs 1221 can have lower power consumption, higher speed, and higher capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a large number of pieces of data and thus can be used for image processing or product-sum operation. When an image processing circuit or a product-sum operation circuit including an oxide semiconductor of the present invention is provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in an appropriate combination with any of those in the other embodiments and the like described in this specification.

### Embodiment 4

In this embodiment, examples of electronic components and electronic appliances in which the storage device or the like described in the above embodiment is incorporated are described. When the storage device described in the above embodiment is used for the following electronic components and electronic appliances, the electronic components and electronic appliances can have lower power consumption and higher speed.

### <Electronic Component>

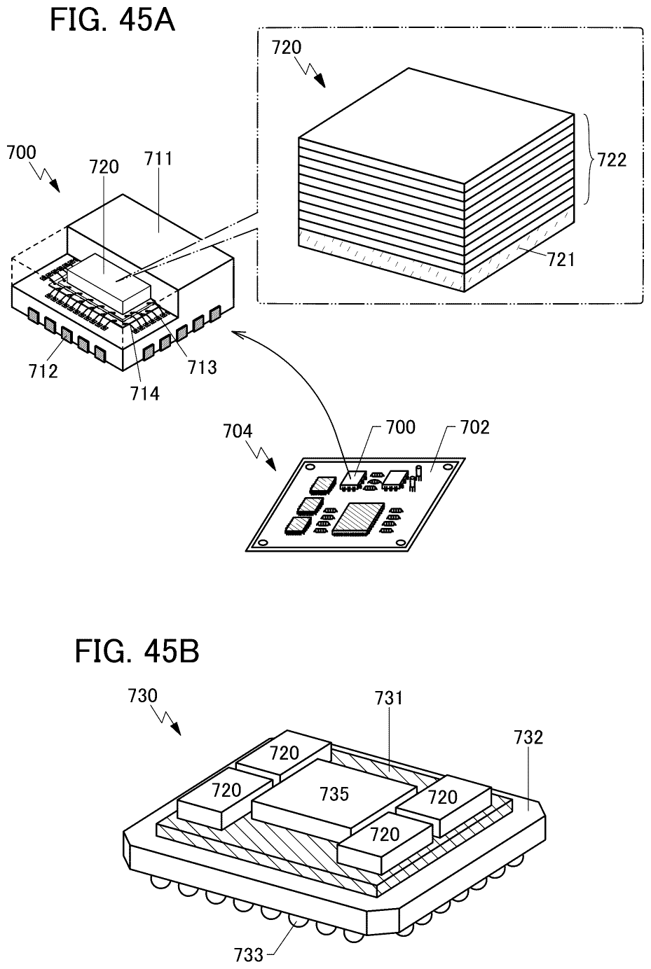

First, examples of an electronic component including a storage device 720 are described with reference to FIG. 45A and FIG. 45B.

FIG. 45A is a perspective view of an electronic component 700 and a substrate (mounting board 704) on which the electronic component 700 is mounted. The electronic component 700 illustrated in FIG. 45A includes the storage device 720 in a mold 711. FIG. 45A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the mounting board 704.

The storage device 720 includes a driver circuit layer 721 and a storage circuit layer 722.

FIG. 45B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because the silicon interposer does not need to be provided with an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package substrate 732 to mount the electronic component 730 on another substrate. FIG. 45B illustrates an example where the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods other than BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of other structures, methods, and the like described in this embodiment or any of structures, methods, and the like described in the other embodiments.

### Embodiment 5

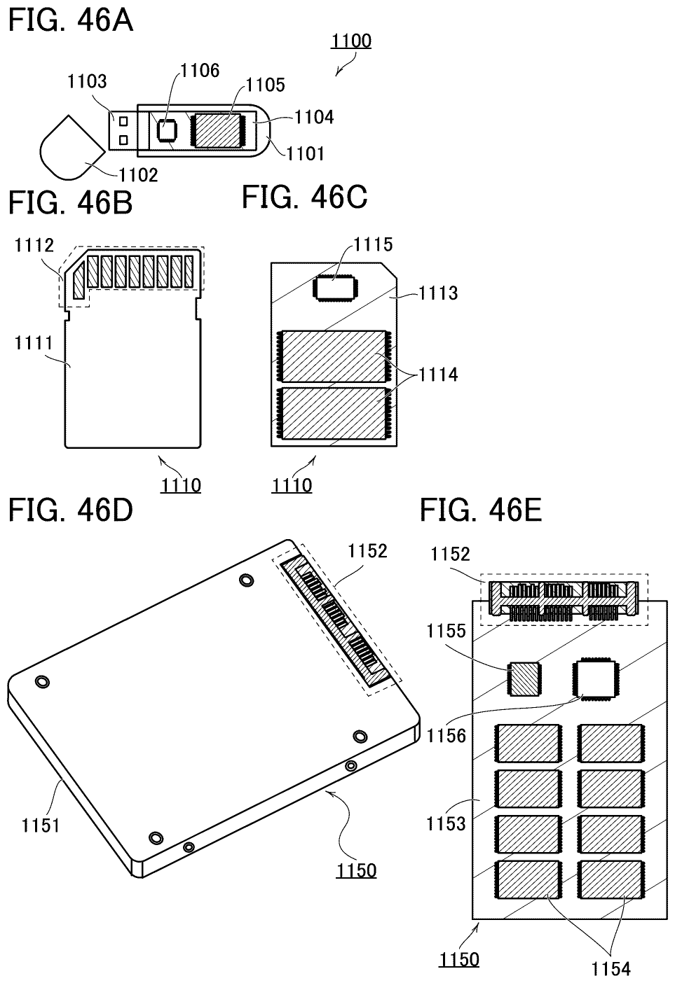

In this embodiment, application examples of the storage device using the storage device described in the above embodiment are described. The storage device described in the above embodiment can be applied to, for example, storage devices of a variety of electronic appliances (e.g., information terminals, computers, smartphones, e-book readers, digital cameras (including video cameras), video recording/reproducing devices, and navigation systems). When the storage device described in the above embodiment is used for the storage devices of the above electronic appliances, the electronic appliances can have lower power consumption and higher speed. Here, the computers refer not only to tablet computers, notebook computers, and desktop computers, but also to large computers such as server systems. Alternatively, the storage device described in the above embodiment is applied to a variety of removable storage devices such as memory cards (e.g., SD cards), USB memories, and SSDs (solid state drives). FIG. 46A to FIG. 46E schematically illustrate some structure examples of removable storage devices. The storage device described in the above embodiment is processed into a packaged memory chip and used in a variety of storage devices and removable memories, for example.

FIG. 46A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The storage device described in the above embodiment can be incorporated in the memory chip 1105 or the like.

FIG. 46B is a schematic external view of an SD card, and FIG. 46C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The storage device described in the above embodiment can be incorporated in the memory chip 1114 or the like.

FIG. 46D is a schematic external view of an SSD, and FIG. 46E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The storage device described in the above embodiment can be incorporated in the memory chip 1154 or the like.

At least part of the structure, method, and the like described in this embodiment can be implemented in an appropriate combination with any of those in the other embodiments and the like described in this specification.

### Embodiment 6

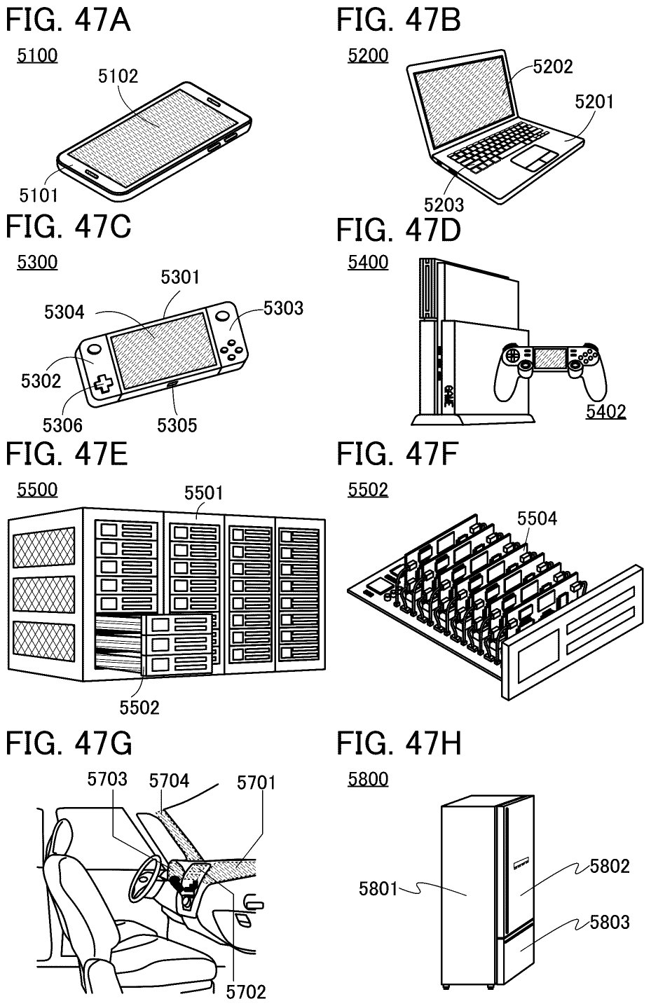

The storage device of one embodiment of the present invention can be used as a processor, e.g., a CPU or a GPU, or a chip. When such a processor, e.g., a CPU or a GPU, or such a chip is used for an electronic appliance, the electronic appliance can have lower power consumption and higher speed. FIG. 47A to FIG. 47H illustrate specific examples of the electronic appliance provided with the processor, e.g., the CPU or the GPU, or the chip that includes the storage device.

### <Electronic Appliance and System>

The GPU or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic appliance of one embodiment of the present invention can have a variety of functions. For example, the electronic appliance can have a function of displaying a variety of data (a still image, a moving image, a text image, and the like) on the display portion, a touch panel function, a function of displaying a calendar, date, time, or the like, a function of executing a variety of software (programs), a wireless communication function, and a function of reading out a program or data stored in a recording medium. FIG. 47A to FIG. 47H illustrate examples of electronic appliances.

### [Information Terminal]

FIG. 47A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the contents of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like. FIG. 47B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with the use of the notebook information terminal 5200, novel artificial intelligence can be developed.

Note that although FIG. 47A and FIG. 47B illustrate a smartphone and a notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 47C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, a plurality of players can play a game at the same time. The chip described in the above embodiment can be incorporated into the chip provided on a substrate in the housing 5301, the housing 5302, and the housing 5303.

FIG. 47D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated as examples of game machines in FIG. 47C and FIG. 47D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 47E is a diagram illustrating a supercomputer 5500 as an example of a large computer. FIG. 47F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, on which the GPU or the chip described in the above embodiment can be mounted.

The supercomputer 5500 is a large computer mainly used for scientific computation. In scientific computation, an enormous amount of arithmetic operation needs to be processed at high speed; hence, power consumption is high and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is illustrated as an example of a large computer in FIG. 47E and FIG. 47F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 47G is a diagram illustrating an area around a windshield inside an automobile, which is an example of a moving vehicle. FIG. 47G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an image capturing device (not illustrated) provided for the automobile. That is, displaying an image taken by the image capturing device provided outside the automobile leads to compensation for the blind spot and an increase in safety. In addition, displaying an image to compensate for a portion that cannot be seen makes it possible for the driver to confirm the safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 47H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in an appropriate combination with any of those in the other embodiments and the like described in this specification.

### Embodiment 7

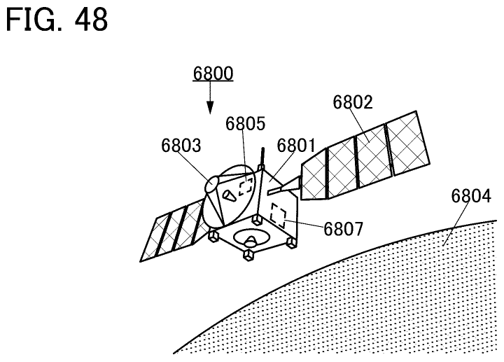

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, OS transistors can be suitably used in outer space. In this embodiment, a specific example of using the semiconductor device of one embodiment of the present invention in a device for space will be described with reference to FIG. 48.

FIG. 48 illustrates an artificial satellite 6800 as an example of a device for space. The artificial satellite 6800 includes a body 6801, a solar panel 6802, an antenna 6803, a secondary battery 6805, and a control device 6807. In FIG. 48, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device that is one embodiment of the present invention and that includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### REFERENCE NUMERALS

ADDR: signal, BL[1]: wiring, BL[j]: wiring, BL[n]: wiring, BL_A: wiring, BL_B: wiring, BL: wiring, BW: signal, Ca: capacitor, Cb: capacitor, CE: signal, CL: wiring, CLK: signal, EN_data: signal, GBL_A: wiring, GBL_B: wiring, GBL: wiring, GND: ground potential, GV: gate valve, GW: signal, MUX: selection signal, PL[1]: wiring, PL[m]: wiring, PL: wiring, RDA: signal, RE: control signal, T11: period, T12: period, T13: period, T14: period, T15: period, T16: period, Tra: transistor, Trb: transistor, VDD: high power supply potential, VHH: wiring, VLL: wiring, VPC: intermediate potential, WAKE: signal, WDA: signal, WE: control signal, WL[1]: wiring, WL[m]: wiring, WL: wiring, 10[1,1]: memory cell, 10[i,j]: memory cell, 10[m,n]: memory cell, 10_A: memory cell, 10_B: memory cell, 10a: memory cell, 10b: memory cell, 10: memory cell, 11a: semiconductor layer, 11b: semiconductor layer, 11: transistor, 12: capacitor, 13: conductive layer, 14a: conductive layer, 14b: conductive layer, 15a: conductive layer, 15b: conductive layer, 20[1]: memory array, 20[2]: memory array, 20[5]: memory array, 20[m]: memory array, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51A: functional circuit, 51B: functional circuit, 51C: functional circuit, 51D: functional circuit, 51: functional circuit, 52_a: transistor, 52_b: transistor, 52: transistor, 53_a: transistor, 53_b: transistor, 53: transistor, 54_a: transistor, 54_b: transistor, 54: transistor, 55_a: transistor, 55_b: transistor, 55: transistor, 70[1]: repeating unit, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 100a: capacitor, 100b: capacitor, 100: capacitor, 153A: insulating film, 153: insulator, 156A: conductive film, 156: conductor, 158: opening, 160a: conductor, 160A: conductive film, 160b: conductor, 160B: conductive film, 160: conductor, 200a: transistor, 200b: transistor, 200c: transistor, 200d: transistor, 200e: transistor, 200: transistor, 205a: conductor, 205b: conductor, 205c: conductor, 205: conductor, 206: opening, 207: conductor, 208: insulator, 209: conductor, 210: insulator, 212: insulator, 214: insulator, 216: insulator, 221: insulator, 222: insulator, 224A: insulating layer, 224Af: insulating film, 224: insulator, 230a: oxide, 230A: oxide layer, 230Af: oxide film, 230b: oxide, 230B: oxide layer, 230ba: region, 230bb: region, 230bc: region, 230Bf: oxide film, 230: oxide, 240a: conductor, 240b: conductor, 240: conductor, 242a: conductor, 242A: conductive layer, 242Af: conductive film, 242b: conductor, 242B: conductive layer, 242Bf: conductive film, 242: conductor, 253A: insulating film, 253: insulator, 254: insulator, 258: opening, 260a: conductor, 260b: conductor, 260: conductor, 275: insulator, 280: insulator, 282: insulator, 283: insulator, 285: insulator, 300A: storage device, 300: storage device, 310: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: mounting board, 711: mold, 712: land, 713: electrode pad, 714: wire, 720: storage device, 721: driver circuit layer, 722: storage circuit layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 2700: manufacturing apparatus, 2701: atmosphere-side substrate supply chamber, 2702: atmosphere-side substrate transfer chamber, 2703a: load lock chamber, 2703b: unload lock chamber, 2704: transfer chamber, 2706a: chamber, 2706b: chamber, 2706c: chamber, 2706d: chamber, 2761: cassette port, 2762: alignment port, 2763a: transfer robot, 2763b: transfer robot, 2801: gas supply source, 2802: valve, 2803: high-frequency generator, 2804: waveguide, 2805: mode converter, 2806: gas pipe, 2807: waveguide, 2808: slot antenna plate, 2809: dielectric plate, 2810: high-density plasma, 2811_1: substrate, 2811_2: substrate, 2811_3: substrate, 2811_n: substrate, 2811: substrate, 2812: substrate holder, 2813: heating mechanism, 2815: matching box, 2816: high-frequency power source, 2817: vacuum pump, 2818: valve, 2819: exhaust port, 2820: lamp, 2821: gas supply source, 2822: valve, 2823: gas inlet, 2824: substrate, 2825: substrate holder, 2826: heating mechanism, 2828: vacuum pump, 2829: valve, 2830: exhaust port, 2900: microwave treatment apparatus, 2901: quartz tube, 2902: substrate holder, 2903: heating means, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door, 6800: artificial satellite, 6801: body, 6802: solar panel, 6803: antenna, 6804: planet, 6805: secondary battery, 6807: control device

1. A storage device comprising:
a first insulator, a second insulator over the first insulator, and a memory cell comprising a first transistor and a first capacitor,
wherein the first transistor comprises:
an oxide over the first insulator;
a first conductor and a second conductor over the oxide;
a third insulator over the oxide; and
a third conductor over the third insulator,
wherein the second insulator is located over the first conductor and the second conductor,
wherein the second insulator comprises a first opening comprising a region overlapping with the oxide and a second opening comprising a region overlapping with the second conductor,
wherein the third insulator and the third conductor are located in the first opening,
wherein the first capacitor comprises a fourth conductor in contact with a top surface of the second conductor, a fourth insulator over the fourth conductor, and a fifth conductor over the fourth insulator,
wherein the fourth conductor, the fourth insulator and the fifth conductor are located in the second opening,
wherein a third opening is located in the first insulator, the second insulator, and the first conductor,
wherein a sixth conductor is located in the third opening, and
wherein the sixth conductor is in contact with a top surface and a side surface of the first conductor.

2. A storage device comprising:
a plurality of layers each comprising a first insulator, a second insulator over the first insulator, and a memory cell comprising a first transistor and a first capacitor,
wherein the plurality of layers are stacked,
wherein the first transistor comprises:
an oxide over the first insulator;
a first conductor and a second conductor over the oxide;
a third insulator over the oxide; and
a third conductor over the third insulator,
wherein the second insulator is over the first conductor and the second conductor,
wherein the second insulator comprises a first opening comprising a region overlapping with the oxide and a second opening comprising a region overlapping with the second conductor,
wherein the third insulator and the third conductor are located in the first opening,
wherein the first capacitor comprises a fourth conductor in contact with a top surface of the second conductor, a fourth insulator over the fourth conductor, and a fifth conductor over the fourth insulator,
wherein the fourth conductor, the fourth insulator, and the fifth conductor are located in the second opening,
wherein a third opening is provided in the plurality of layers,
wherein each part of the third opening in the plurality of layers overlaps with the other parts,
wherein a sixth conductor is located in the third opening, and
wherein, in each of the plurality of layers, the sixth conductor is in contact with a top surface of and a side surface of the first conductor.

3. The storage device according to claim 2,
wherein each of the plurality of layers further comprises a second transistor and a second capacitor,
wherein the first transistor and the second transistor are line-symmetric with respect to the sixth conductor as a symmetric axis,
wherein the first transistor and the second transistor have a same structure,
wherein the first capacitor and the second capacitor are line-symmetric with respect to the sixth conductor as a symmetric axis, and
wherein the first capacitor and the second capacitor have a same structure.

4. A storage device comprising:
a layer comprising a first insulator, a second insulator over the first insulator, and a memory cell comprising a first transistor and a first capacitor;
a substrate provided with a driver circuit configured to drive the memory cell;
a functional layer comprising a functional circuit, the functional layer over the driver circuit; and
a wiring,
wherein the layer is over the functional layer,
wherein the first transistor comprises:
an oxide over the first insulator;
a first conductor and a second conductor over the oxide;
a third insulator over the oxide; and
a third conductor over the third insulator,
wherein the second insulator is located over the first conductor and the second conductor,
wherein the second insulator comprises a first opening comprising a region overlapping with the oxide and a second opening comprising a region overlapping with the second conductor,
wherein the third insulator and the third conductor are located in the first opening,
wherein the first capacitor comprises a fourth conductor in contact with a top surface of the second conductor, a fourth insulator over the fourth conductor, and a fifth conductor over the fourth insulator,
wherein the fourth conductor, the fourth insulator, and the fifth conductor are located in the second opening,
wherein the layer comprises a third opening,
wherein a sixth conductor is located in the third opening,
wherein the sixth conductor is in contact with a top surface and a side surface of the first conductor in the layer,
wherein the sixth conductor is electrically connected to the memory cell,
wherein the driver circuit is electrically connected to the functional circuit via the wiring,
wherein the functional circuit further comprises a second transistor,
wherein a gate of the second transistor is electrically connected to the sixth conductor,
wherein the functional circuit is configured to transmit a signal to the wiring, and
wherein the signal corresponds to a potential of the sixth conductor.

5. The storage device according to claim 4,
wherein the layer further comprises a third transistor and a second capacitor,
wherein the first transistor and the third transistor are line-symmetric with respect to the sixth conductor as a symmetric axis,
wherein the first transistor and the third transistor have a same structure,
wherein the first capacitor and the second capacitor are line-symmetric with respect to the sixth conductor as a symmetric axis, and
wherein the first capacitor and the second capacitor have a same structure.

6. A storage device comprising:
a plurality of layers each comprising a first insulator, a second insulator over the first insulator, and a memory cell comprising a first transistor and a first capacitor;
a substrate provided with a driver circuit configured to drive the memory cell;
a functional layer comprising a functional circuit, the functional layer over the driver circuit; and
a wiring,
wherein the plurality of layers are stacked over the functional layer,
wherein the first transistor comprises:
an oxide over the first insulator;
a first conductor and a second conductor over the oxide;
a third insulator over the oxide; and
a third conductor over the third insulator,
wherein the second insulator is over the first conductor and the second conductor,
wherein the second insulator comprises a first opening comprising a region overlapping with the oxide and a second opening comprising a region overlapping with the second conductor,
wherein the third insulator and the third conductor are located in the first opening,
wherein the first capacitor comprises:
a fourth conductor in contact with a top surface of the second conductor;
a fourth insulator over the fourth conductor; and
a fifth conductor over the fourth insulator,
wherein the fourth conductor, the fourth insulator, and the fifth conductor are located in the second opening,
wherein a third opening is provided in the plurality of layers,
wherein each part of the third opening in the plurality of layers overlaps with the other parts,
wherein a sixth conductor is located in the third opening,
wherein, in each of the plurality of layers, the sixth conductor is in contact with a top surface a side surface of the first conductor,
wherein the sixth conductor is electrically connected to the memory cell,
wherein the driver circuit is electrically connected to the functional circuit via the wiring,
wherein the functional circuit further comprises a second transistor,
wherein a gate of the second transistor is electrically connected to the sixth conductor,
wherein the functional circuit is configured to transmit a signal to the wiring, and
wherein the signal corresponds to a potential of the sixth conductor.

7. The storage device according to claim 6,
wherein each of the plurality of layers further comprises a third transistor and a second capacitor,
wherein the first transistor and the third transistor are line-symmetric with respect to the sixth conductor as a symmetric axis,
wherein the first transistor and the second transistor have a same structure,
wherein the first capacitor and the second capacitor are line-symmetric with respect to the sixth conductor as a symmetric axis, and
wherein the first capacitor and the second capacitor have a same structure.

8. The storage device according to claim 1, wherein a part of the fourth conductor, a part of the fourth insulator and a part of the fifth conductor are located above a top surface of the third conductor.

9. The storage device according to claim 8, wherein the third insulator is in contact with a top surface and a side surface of the oxide and a sidewall of the first opening in the second insulator.

10. The storage device according to claim 8, wherein each of the first conductor and the second conductor is in contact with a top surface and a side surface of the oxide.

11. The storage device according to claim 8, wherein the fourth conductor is in contact with a sidewall of the second opening in the second insulator.

12. The storage device according to claim 8,
wherein in the third opening, the side surface of the first conductor protrudes from a side surface of the first insulator and a side surface of the second insulator.

13. The storage device according to claim 8, further comprising a seventh conductor between the sixth conductor and the third opening,
wherein the sixth conductor comprises tungsten, and
wherein the seventh conductor comprises titanium and nitrogen.

14. The storage device according to claim 8, further comprising a fifth insulator in contact with a top surface of the second insulator and the top surface of the third conductor,
wherein the second opening is further formed in the fifth insulator, and
wherein each of a part of the fourth conductor and a part of the fourth insulator is in contact with a top surface of the fifth insulator.
